(19) United States
(12) Patent Application Publication
(10) Pub. No.: US 2025/0107334 A1
(43) Pub. Date: Mar. 27, 2025

(54) DISPLAY SUBSTRATE AND MANUFACTURING METHOD THEREFOR, AND DISPLAY DEVICE

(71) Applicants: Chengdu BOE Optoelectronics Technology Co., Ltd., Chengdu (Sichuan) (CN); BOE TECHNOLOGY GROUP CO., LTD., Beijing (CN)

(72) Inventors: Xiaoliang GUO, Beijing (CN); Wuyang ZHAO, Beijing (CN); Yi ZHANG, Beijing (CN); Zhongfei DONG, Beijing (CN); Chengbao QIN, Beijing (CN); Li XIONG, Beijing (CN); Wei ZHANG, Beijing (CN); Donghua JIANG, Beijing (CN); Liang SONG, Beijing (CN); Long JIANG, Beijing (CN); Jianbo YANG, Beijing (CN); Yanwei LU, Beijing (CN)

(73) Assignees: Chengdu BOE Optoelectronics Technology Co., Ltd., Chengdu (Sichuan) (CN); BOE TECHNOLOGY GROUP CO., LTD., Beijing (CN)

(21) Appl. No.: 18/294,728

(22) PCT Filed: Sep. 23, 2022
(86) PCT No.: PCT/CN2022/120922

§ 371 Date: Feb. 2, 2024

(30) Foreign Application Priority Data
Nov. 30, 2021 (CN) 202111444192.1

(51) Int. Cl. H10K 59/122; H10K 59/12; H10K 59/131

(52) U.S. Cl. CPC H10K 59/122; H10K 59/1201; H10K 59/131

(57) ABSTRACT

A display substrate and a manufacturing method therefor, and a display device. In the display substrate at least one of a plurality of sub-functional film layers in a light-emitting functional layer is disconnected at the positions where the pixel partition structures are located. Each pixel partition structure includes a first subpixel partition part, a second subpixel partition part, and a third subpixel partition part that are stacked in a direction perpendicular to the base substrate. The second subpixel partition part includes a plurality of sub-partition layers stacked in the direction perpendicular to the base substrate. The first subpixel partition part is provided, in an arrangement direction of two adjacent subpixels, with a first protrusion going beyond at least one sub-partition layer. The third subpixel partition part is provided, in the arrangement direction of two adjacent subpixels, with a second protrusion going beyond at least one sub-partition layer.

This patent application claims priority to the Chinese Patent Application No. 202111444192.1 filed on Nov. 30, 2021, for all purposes, the disclosure of which is incorporated herein by reference in its entirety as part of the embodiment of the present disclosure.

### TECHNICAL FIELD

At least one embodiment of the present disclosure relates to a display substrate, a manufacturing method thereof, and a display device.

### BACKGROUND

With the continuous development of display technology, organic light emitting diode display devices (OLED) have become the current research focus and technology development direction of major manufacturers due to their advantages such as wide color gamut, high contrast, thin and light design, self-illumination, and wide viewing angles.

At present, organic light emitting diode display devices (OLED) have been widely used in various electronic products, ranging from small electronic products such as smart bracelets, smart watches, smart phones and tablet computers to large electronic products such as notebook computers, desktop computers, and televisions. Therefore, the market demand for active matrix organic light emitting diode display devices is also increasing.

### SUMMARY

Embodiments of the present disclosure provide a display substrate, a manufacturing method thereof, and a display device. The display substrate can set isolation structure between adjacent sub-pixels, so that at least one of a plurality of sub-functional film layers in a light-emitting functional layer is disconnected at a position where a pixel isolation structure is located, and thus crosstalk among adjacent sub-pixels caused by the film layer with higher conductivity among the plurality of sub-functional film layers is avoided.

At least one embodiment of the present disclosure provides a display substrate, which includes: a base substrate; a plurality of sub-pixels, located on the base substrate, wherein each of the plurality of sub-pixels includes a light-emitting element, the light-emitting element includes a light-emitting functional layer, a first electrode and a second electrode located on two sides of the light-emitting functional layer respectively, the first electrode is located between the light-emitting functional layer and the base substrate, and the light-emitting functional layer includes a plurality of sub-functional film layers; and a pixel isolation structure, located between adjacent sub-pixels of the plurality of sub-pixels, at least one of the plurality of sub-functional film layers in the light-emitting functional layer is disconnected at a position where the pixel isolation structure is located, the pixel isolation structure includes a first sub-pixel isolation part, a second sub-pixel isolation part and a third sub-pixel isolation part that are stacked in a direction perpendicular to the base substrate, the second sub-pixel isolation part is located on a side of the first sub-pixel isolation part away from the base substrate, and the third sub-pixel isolation part is located on a side of the second sub-pixel isolation part away from the first sub-pixel isolation part, and the second sub-pixel isolation part includes a plurality of sub-isolation layers stacked in the direction perpendicular to the base substrate, the first sub-pixel isolation part has a first protruding part beyond at least one of the plurality of sub-isolation layers in an arrangement direction of two adjacent sub-pixels of the plurality of sub-pixels, and the third sub-pixel isolation part has a second protruding part beyond at least one of the plurality of sub-isolation layers in the arrangement direction of the two adjacent sub-pixels.

For example, in the display substrate provided by an embodiment of the present disclosure, an orthographic projection of at least one of the plurality of sub-isolation layers on the base substrate respectively falls within an orthographic projection of the first sub-pixel isolation part and an orthographic projection of the third sub-pixel isolation part on the base substrate.

For example, in the display substrate provided by an embodiment of the present disclosure, an orthographic projection of the second sub-pixel isolation part on the base substrate respectively falls within the orthographic projection of the first sub-pixel isolation part and the orthographic projection of the third sub-pixel isolation part on the base substrate.

For example, in the display substrate provided by an embodiment of the present disclosure, the plurality of sub-isolation layers of the second sub-pixel isolation part include a first sub-isolation layer, a second sub-isolation layer and a third sub-isolation layer that are stacked in the direction perpendicular to the base substrate, and an orthographic projection of the second sub-isolation layer on the base substrate respectively falls within an orthographic projection of the first sub-isolation layer and an orthographic projection of the third sub-isolation layer on the base substrate.

For example, in the display substrate provided by an embodiment of the present disclosure, the plurality of sub-functional layers include a charge generation layer and a first light emitting layer and a second light emitting layer located on two sides of the charge generation layer respectively, the charge generation layer is disconnected at the position where the pixel isolation structure is located.

For example, in the display substrate provided by an embodiment of the present disclosure, in the arrangement direction of the two adjacent sub-pixels, an average size of the second sub-pixel isolation part is smaller than an average size of the first sub-pixel isolation part and an average size of the third sub-pixel isolation part.

For example, in the display substrate provided by an embodiment of the present disclosure, a material of the third sub-pixel isolation part includes a first metal, and a material of the second sub-pixel isolation part includes a second metal.

For example, in the display substrate provided by an embodiment of the present disclosure, a material of the first sub-pixel isolation includes the first metal, the first metal is titanium, and the second metal is aluminum.

For example, in the display substrate provided by an embodiment of the present disclosure, materials of the first sub-pixel isolation part and the third sub-pixel isolation part include a first inorganic non-metal material, and a material of the second sub-pixel isolation part includes a second inorganic non-metal material.

For example, in the display substrate provided by an embodiment of the present disclosure, the first inorganic non-metal material includes silicon oxide, and the second inorganic non-metal material includes silicon nitride.

For example, in the display substrate provided by an embodiment of the present disclosure, a plurality of pixel isolation structures are arranged between two adjacent sub-pixels of the plurality of sub-pixels.

For example, the display substrate provided by an embodiment of the present disclosure further includes: a pixel defining layer, located on the base substrate, the pixel defining layer is partially located on a side of the first electrode away from the base substrate, the pixel defining layer includes a plurality of pixel openings, the plurality of pixel openings are in one-to-one correspondence with the plurality of sub-pixels to define light-emitting areas of the plurality of sub-pixels, and each of the plurality of pixel openings is configured to expose the first electrode, and the pixel isolation structure is located between adjacent pixel openings of the plurality of pixel openings, and is located on a side of the pixel defining layer away from the base substrate.

For example, the display substrate provided by an embodiment of the present disclosure further includes: a pixel defining layer, located on the base substrate, the pixel defining layer is partially located on a side of the first electrode away from the base substrate, the pixel defining layer includes a plurality of pixel openings and a pixel spacing opening, the plurality of pixel openings are in one-to-one correspondence with the plurality of sub-pixels to define light-emitting areas of the plurality of sub-pixels, and each of the plurality of pixel openings is configured to expose the first electrode, the pixel spacing opening is located between adjacent first electrodes, and the pixel isolation structure is at least partially located in the pixel spacing opening.

For example, the display substrate provided by an embodiment of the present disclosure further includes: a planarization layer, located between the base substrate and the first electrode, the pixel isolation structure is in direct contact with the planarization layer.

For example, the display substrate provided by an embodiment of the present disclosure further includes: a planarization layer, located between the base substrate and the first electrode; and a protection structure, located on the planarization layer and arranged in a same layer as the first electrode, the pixel isolation structure is located on a side of the protection structure away from the base substrate, and is in direct contact with the protection structure.

For example, the display substrate provided by an embodiment of the present disclosure further includes: a pixel defining layer, located on the base substrate, the pixel defining layer is partially located on a side of the first electrode away from the base substrate, the pixel defining layer includes a plurality of pixel openings, the plurality of pixel openings are in one-to-one correspondence with the plurality of sub-pixels to define light-emitting areas of the plurality of sub-pixels, each of the plurality of pixel openings is configured to expose the first electrode, and at least a part of the pixel isolation structure is located in the plurality of pixel openings.

For example, in the display substrate provided by an embodiment of the present disclosure, the pixel isolation structure is located at an edge of the first electrode, a surface of the pixel isolation structure away from the base substrate is at least partially covered by a material of the first electrode, an orthographic projection of the pixel isolation structure on the base substrate is at least partially overlapped with an orthographic projection of the pixel defining layer on the base substrate.

For example, in the display substrate provided by an embodiment of the present disclosure, the base substrate includes a display region and a peripheral region surrounding the display region, the display region includes an opening region, and an opening isolation structure is arranged at an edge of the opening region, a cross-sectional structure of the opening isolation structure in the direction perpendicular to the base substrate is the same as a cross-sectional structure of the pixel isolation structure, and a material of the opening isolation structure is the same as a material of the pixel isolation structure.

For example, in the display substrate provided by an embodiment of the present disclosure, the second electrode is disconnected at a position where the pixel isolation structure is located.

At least one embodiment of the present disclosure further provides a display device, which includes any one of the abovementioned display substrates.

At least one embodiment of the present disclosure further provides a manufacturing method of a display substrate, which includes: forming a plurality of first electrodes on the base substrate; forming a pixel isolation structure on the base substrate; forming a light-emitting functional layer on a side of the pixel isolation structure and the plurality of first electrodes away from the base substrate, the light-emitting functional layer includes a plurality of sub-functional layers; and forming a second electrode on a side of the light-emitting functional layer away from the base substrate, the second electrode, the light-emitting functional layer and the plurality of first electrodes form light-emitting elements of a plurality of sub-pixels, the pixel isolation structure is located between adjacent sub-pixels of the plurality of sub-pixels, the pixel isolation structure includes a first sub-pixel isolation part, a second sub-pixel isolation part and a third sub-pixel isolation part that are stacked, the second sub-pixel isolation part is located on a side of the first sub-pixel isolation part away from the base substrate, the third sub-pixel isolation part is located on a side of the second sub-pixel isolation part away from the first sub-pixel isolation part, and the second sub-pixel isolation part includes a plurality of sub-isolation layers stacked in a direction perpendicular to the base substrate, the first sub-pixel isolation part has a first protruding part beyond at least one of the plurality of sub-isolation layers in an arrangement direction of two adjacent sub-pixels of the plurality of sub-pixels, and the third sub-pixel isolation part has a second protruding part beyond at least one of the plurality of sub-isolation layers in the arrangement direction of the two adjacent sub-pixels.

For example, in the manufacturing method of the display substrate provided by an embodiment of the present disclosure, an orthographic projection of at least one of the plurality of sub-isolation layers on the base substrate respectively falls within an orthographic projection of the first sub-pixel isolation part and an orthographic projection the third sub-pixel isolation part on the base substrate.

For example, in the manufacturing method of the display substrate provided by an embodiment of the present disclosure, an orthographic projection of the second sub-pixel isolation part on the base substrate respectively falls within an orthographic projection of the first sub-pixel isolation part and an orthographic projection of the third sub-pixel isolation part on the base substrate.

For example, in the manufacturing method of the display substrate provided by an embodiment of the present disclosure, the plurality of sub-isolation layers of the second sub-pixel isolation part include a first sub-isolation layer, a second sub-isolation layer and a third sub-isolation layer that are stacked in the direction perpendicular to the base substrate, and an orthographic projection of the second sub-isolation layer on the base substrate respectively falls within an orthographic projection of the first sub-isolation layer and an orthographic projection the third sub-isolation layer on the base substrate.

For example, in the manufacturing method of the display substrate provided by an embodiment of the present disclosure, the forming an isolation structure on the base substrate includes: forming a stacked structure on the base substrate before forming the plurality of first electrodes on the base substrate, the stacked structure includes a first sub-layer, a second sub-layer and a third sub-layer that are stacked; and etching the stacked structure to remove a part of the second sub-layer, so that the stacked structure forms the pixel isolation structure, the first sub-layer forms a first sub-pixel isolation part, the second sub-layer forms a second sub-pixel isolation part, and the third sub-layer forms a third sub-pixel isolation part.

For example, the manufacturing method of the display substrate provided by an embodiment of the present disclosure further includes: before forming the plurality of first electrodes on the base substrate, forming a stacked structure on the base substrate, wherein the stacked structure includes a first sub-layer, a second sub-layer and a third sub-layer that are stacked; after forming the plurality of first electrodes on the base substrate, forming a pixel defining layer on a side of the stacked structure and the plurality of first electrodes away from the base substrate; patterning the pixel defining layer to form a plurality of pixel openings and a pixel spacing opening on the pixel defining layer; and etching the stacked structure to remove a part of the second sub-layer, so that the stacked structure forms the pixel isolation structure, the first sub-layer forms a first sub-pixel isolation part, the second sub-layer forms a second sub-pixel isolation part, and the third sub-layer forms a third sub-pixel isolation part, the plurality of pixel openings are arranged corresponding to the plurality of first electrodes, and are configured to expose the plurality of first electrodes, the pixel spacing opening is located between adjacent first electrodes, and at least a part of the stacked structure is located in the pixel spacing opening.

For example, the manufacturing method of the display substrate provided by an embodiment of the present disclosure further includes: before forming the plurality of first electrodes on the base substrate, forming a stacked structure on the base substrate, the stacked structure includes a first sub-layer, a second sub-layer and a third sub-layer that are stacked; etching the stacked structure to remove a part of the second sub-layer, so that the stacked structure forms the pixel isolation structure, the first sub-layer forms a first sub-pixel isolation part, the second sub-layer forms a second sub-pixel isolation part, and the third sub-layer forms a third sub-pixel isolation part; after forming the plurality of first electrodes on the base substrate, forming a pixel defining layer on a side of the stacked structure and the first electrodes away from the base substrate; and patterning the pixel defining layer to form a plurality of pixel openings on the pixel defining layer, the plurality of pixel openings are arranged corresponding to the plurality of first electrodes, and are configured to expose the plurality of first electrodes, and the pixel isolation structure is at least partially located in the plurality of pixel openings.

### BRIEF DESCRIPTION OF DRAWINGS

In order to clearly illustrate the technical solution of the embodiments of the present disclosure, the drawings of the embodiments will be briefly described. It is obvious that the described drawings in the following are only related to some embodiments of the present disclosure and thus are not construed as any limitation to the present disclosure.

FIG. 1 is a planar schematic diagram of a display substrate provided by an embodiment of the present disclosure;

FIG. 2 is a cross-sectional schematic diagram of a display substrate along line GH in FIG. 1 provided by an embodiment of the present disclosure;

FIG. 3 is a schematic diagram of a pixel isolation structure in a display substrate provided by an embodiment of the present disclosure;

FIG. 4 is a structural schematic diagram of a light-emitting functional layer of a sub-pixel in a display substrate provided by an embodiment of the present disclosure;

FIG. 5 is a cross-sectional schematic diagram of a display substrate provided by an embodiment of the present disclosure;

FIG. 6 is a cross-sectional schematic diagram of another display substrate provided by an embodiment of the present disclosure;

FIG. 7 is a cross-sectional schematic diagram of still another display substrate provided by an embodiment of the present disclosure;

FIG. 8 is a cross-sectional schematic diagram of still another display substrate provided by an embodiment of the present disclosure;

FIG. 9 is a planar schematic diagram of a display substrate provided by an embodiment of the present disclosure;

FIG. 10 is a schematic diagram of a display device provided by an embodiment of the present disclosure;

FIGS. 11A to 11F are schematic diagrams of steps of a display substrate provided by an embodiment of the present disclosure;

FIGS. 12A to 12D are schematic diagrams of steps of another display substrate provided by an embodiment of the present disclosure;

FIGS. 13A to 13F are schematic diagrams of steps of still another display substrate provided by an embodiment of the present disclosure;

FIGS. 14A to 14D are schematic diagrams of steps of still another display substrate provided by an embodiment of the present disclosure;

FIG. 15 is a structural schematic diagram of another display substrate provided by an embodiment of the present disclosure;

FIG. 16 is a partial cross-sectional structural schematic diagram of a display substrate provided according to another example of an embodiment of the present disclosure;

FIG. 17A is a partial cross-sectional structural schematic diagram of a display substrate provided according to another example of an embodiment of the present disclosure;

FIG. 17B is a partial cross-sectional structural schematic diagram of a display substrate provided according to still another example of an embodiment of the present disclosure;

FIGS. 18A to 18D are flow schematic diagrams of a manufacturing method of the display substrate before forming the display substrate shown in FIG. 15;

FIG. 19 is a partial cross-sectional structural schematic diagram of a display substrate provided according to another example of an embodiment of the present disclosure;

FIGS. 20A to 20D are flow schematic diagrams of the manufacturing method of the display substrate before forming the display substrate shown in FIG. 19;

FIG. 21 is a partial cross-sectional structural schematic diagram of a display substrate provided according to another example of an embodiment of the present disclosure;

FIG. 22 is a structural schematic diagram of still another display substrate provided by an embodiment of the present disclosure;

FIG. 23 is a structural schematic diagram of still another display substrate provided by an embodiment of the present disclosure;

FIG. 24 is a structural schematic diagram of still another display substrate provided by an embodiment of the present disclosure;

FIG. 25 is a structural schematic diagram of still another display substrate provided by an embodiment of the present disclosure;

FIGS. 26A to 26C are schematic diagrams of steps of another manufacturing method of a display substrate provided by an embodiment of the present disclosure;

FIG. 27 is a structural schematic diagram of another display substrate provided by an embodiment of the present disclosure;

FIGS. 28A to 28D are schematic diagrams of steps of another manufacturing method of a display substrate provided by an embodiment of the present disclosure;

FIG. 29 is a partial planar schematic diagram of a display substrate provided by an embodiment of the present disclosure;

FIG. 30 is a partial planar schematic diagram of a display substrate provided by an embodiment of the present disclosure;

FIG. 31 is a partial planar schematic diagram of a display substrate provided by an embodiment of the present disclosure;

FIG. 32 is a partial planar schematic diagram of a display substrate provided by an embodiment of the present disclosure;

FIG. 33 is a partial planar schematic diagram of a display substrate provided by an embodiment of the present disclosure;

FIG. 34 is a partial planar schematic diagram of a display substrate provided by an embodiment of the present disclosure;

FIG. 35 is a partial planar schematic diagram of a display substrate provided by an embodiment of the present disclosure;

FIG. 36 is a partial planar schematic diagram of a display substrate provided by an embodiment of the present disclosure;

FIG. 37 is a partial planar schematic diagram of a display substrate provided by an embodiment of the present disclosure;

FIG. 38 is a partial planar schematic diagram of a display substrate provided by an embodiment of the present disclosure;

FIG. 39 is a planar schematic diagram of a display substrate provided by an embodiment of the present disclosure;

FIG. 40 is a cross-sectional schematic diagram of a display substrate along an AB direction in FIG. 39 provided by an embodiment of the present disclosure;

FIG. 41 is a planar schematic diagram of another display substrate provided by an embodiment of the present disclosure;

FIG. 42 is a planar schematic diagram of another display substrate provided by an embodiment of the present disclosure;

FIG. 43 is a cross-sectional schematic diagram of a display substrate along a CD direction in FIG. 42 provided by an embodiment of the present disclosure;

FIG. 44 is a planar schematic diagram of another display substrate provided by an embodiment of the present disclosure;

FIG. 45 is a planar schematic diagram of another display substrate provided by an embodiment of the present disclosure;

FIG. 46 is a planar schematic diagram of another display substrate provided by an embodiment of the present disclosure;

FIG. 47 is a planar schematic diagram of another display substrate provided by an embodiment of the present disclosure;

FIG. 48 is a planar schematic diagram of another display substrate provided by an embodiment of the present disclosure;

FIG. 49 is a planar schematic diagram of another display substrate provided by an embodiment of the present disclosure;

FIG. 50 is a planar schematic diagram of another display substrate provided by an embodiment of the present disclosure;

FIG. 51 is a partial cross-sectional schematic diagram of a display substrate provided by an embodiment of the present disclosure;

FIG. 52 is a schematic diagram of a display device provided by an embodiment of the present disclosure;

FIG. 53 is a planar schematic diagram of another display substrate provided by an embodiment of the present disclosure;

FIG. 54 is a cross-sectional schematic diagram of a display substrate along line EF in FIG. 53 according to an embodiment of the present disclosure;

FIG. 55A is a partial cross-sectional schematic diagram of another display substrate provided by an embodiment of the present disclosure;

FIG. 55B is a cross-sectional electron microscope diagram of a display substrate provided by an embodiment of the present disclosure; and

FIG. 56 is a schematic diagram of a display device provided by an embodiment of the present disclosure.

### DETAILED DESCRIPTION

In order to make objectives, technical details, and advantages of the embodiments of the present disclosure more clear, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first”, “second”, etc., which are used in the present disclosure, are not intended to indicate any sequence, amount or importance, but distinguish various components. Also, the terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly.

The features such as “parallel”, “perpendicular” and “identical” used in the embodiments of the present disclosure include a strict meaning of “parallel”, “perpendicular”, “identical” and other features, as well as “roughly parallel”, “roughly perpendicular”, “roughly the same” and other situations that contain certain errors, measurements and errors associated with a measurement of specific quantities (for example, limitations of a measurement system) are taken into account, which means within an acceptable deviation range for a specific value as determined by one of ordinary skill in the art. For example, “approximately” can mean within one or more standard deviations, or within 10% or 5% of the stated value. When a quantity of a component is not specified in the following embodiments of the present disclosure, it means that the component can be one or more, or it can be understood as at least one. “At least one” means one or more, and “plurality” means at least two. “Same layer” in the embodiment of the present disclosure refers to a relationship among a plurality of film layers formed of a same material after going through a same step (such as a one-step patterning process). “Same layer” herein does not always mean that thicknesses of a plurality of film layers are the same or that the heights of the plurality of film layers in the cross-sectional schematic diagrams are the same.

With the continuous development of display technology, people's pursuit of display quality is getting higher and higher. In order to further reduce power consumption and achieve high brightness, a single-layer light-emitting layer in a light-emitting element in OLED can be replaced with two-layer light-emitting layers, and a charge generation layer (CGL) is added between double-layer light-emitting layers to achieve a double-layer light-emitting (Tandem EL) design. because a display device using a double-layer light-emitting (Tandem EL) design has two light-emitting layers, its light emitting brightness can be approximately twice that of a single light-emitting layer. In this way, the display device using the double-layer light-emitting design has the advantages of long life, low power consumption, and high brightness.

However, the inventors of the present application noticed that for high-resolution products, because the charge generation layer has strong conductivity, and the light-emitting functional layers of adjacent sub-pixels (here refers to a film layer including two light-emitting layers and a charge generation layer) are connected, the charge generation layer easily causes crosstalk among adjacent sub-pixels, so that display quality is seriously affected.

In this regard, embodiments of the present disclosure provide a display substrate, manufacturing method thereof, and a display device. The display substrate includes a base substrate, a plurality of sub-pixels and a pixel isolation structure located on the base substrate; each of the plurality of sub-pixels includes a light-emitting element, the light-emitting element includes a light-emitting functional layer and a first electrode and a second electrode located on two sides of the light-emitting functional layer respectively, the first electrode is located between the light-emitting functional layer and the base substrate, the light-emitting functional layer includes a plurality of sub-functional film layers; the pixel isolation structure is located between adjacent sub-pixels, at least one of the plurality of sub-functional film layers in the light-emitting functional layer is disconnected at a position where the pixel isolation structure is located, the pixel isolation structure includes a first sub-pixel isolation part, a second sub-pixel isolation part and a third sub-pixel isolation part that are stacked in a direction perpendicular to the base substrate, the second sub-pixel isolation part is located on a side of the first sub-pixel isolation part away from the base substrate, the third sub-pixel isolation part is located on a side of the second sub-pixel isolation part away from the first sub-pixel isolation part, the second sub-pixel isolation part includes a plurality of sub-isolation layers stacked in the direction perpendicular to the base substrate, the first sub-pixel isolation part has a first protruding part beyond at least one of the plurality of sub-isolation layers in an arrangement direction of two adjacent sub-pixels of the plurality of sub-pixels, and the third sub-pixel isolation part has a second protruding part beyond at least one of the plurality of sub-isolation layers in the arrangement direction of the two adjacent sub-pixels. Therefore, the display substrate can provide an isolation structure between two adjacent sub-pixels, so that at least one of the plurality of sub-functional film layers in the light-emitting functional layer is disconnected at the position where the pixel isolation structure is located, thus crosstalk among adjacent sub-pixels caused by the film layer with higher conductivity among the plurality of sub-functional film layers is avoided.

Hereinafter, the display substrate, the manufacturing method thereof and the display device provided by the embodiments of the present disclosure will be described in detail with reference to the accompanying drawings.

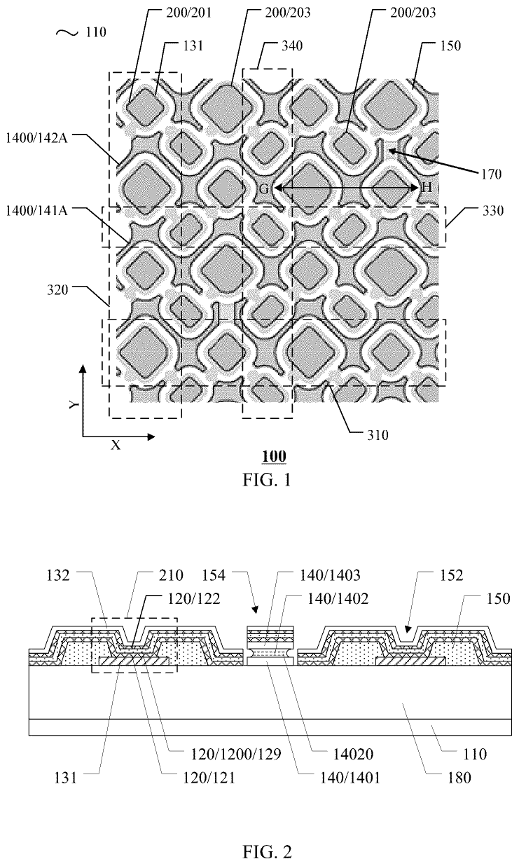

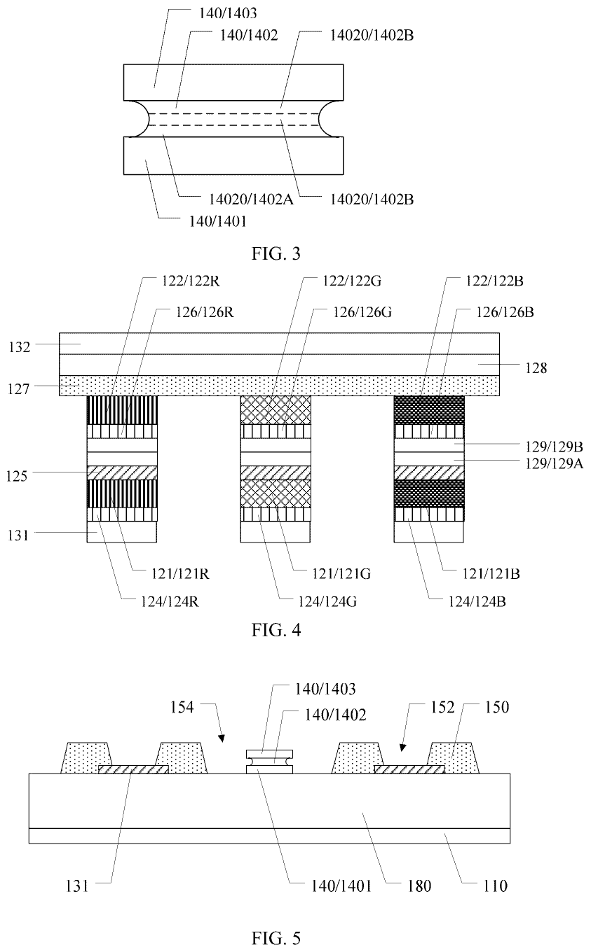

At least one embodiment of the present disclosure provides a display substrate. FIG. 1 is a planar schematic diagram of a display substrate provided by an embodiment of the present disclosure; FIG. 2 is a cross-sectional schematic diagram of a display substrate along line GH in FIG. 1 provided by an embodiment of the present disclosure; and FIG. 3 is a schematic diagram of a pixel isolation structure in a display substrate provided by an embodiment of the present disclosure. It should be noted that, FIG. 1 does not show the entire display substrate, but only a part of the display substrate; FIG. 2 does not show all the layer structures in the display substrate, and the layer structures not shown can be referred in the prior art.

As illustrated by FIGS. 1 and 2, the display substrate 100 includes a base substrate 110 and a plurality of sub-pixels 200; the plurality of sub-pixels 200 are located on the base substrate 110, and each of the plurality of sub-pixel 200 includes a light-emitting element 210; each of the light-emitting elements 210 includes a light-emitting functional layer 120, and a first electrode 131 and a second electrode 132 located on two sides of the light-emitting functional layer 120 respectively, the first electrodes 131 are located between the light-emitting functional layer 120 and the base substrate 110; the second electrode 132 is at least partially located on a side of the light-emitting functional layer 120 away from the first electrodes 131; that is, the first electrodes 131 and the second electrode 132 are located on two sides in a direction perpendicular to the light-emitting functional layer 120 respectively. The light-emitting functional layer 120 includes a plurality of sub-functional layers 1200. It should be noted that, the above-mentioned light-emitting functional layer does not only include film layers that directly emit light, also includes functional film layers used to assist light emitting, such as hole transport layers, electron transport layers, etc.

For example, each of the first electrodes 131 may be an anode, and each of the second electrodes 132 may be a cathode; the plurality of sub-pixels 200 may share a second electrode 132. For example, the cathode may be made of a material with high conductivity and low work function, for example, the cathode can be made of a metal material. For example, the anode may be made of a transparent conductive material with a high work function.

As illustrated by FIGS. 1 and 2, the display substrate 100 also includes a pixel isolation structure 140, the pixel isolation structure 140 is located on the base substrate 110 and is between adjacent sub-pixels 200; at least one of the plurality of sub-functional film layers 1200 in the light-emitting functional layer 120 is disconnected at a position where the pixel isolation structure 140 is located. The pixel isolation structure 140 includes a first sub-pixel isolation part 1401, a second sub-pixel isolation part 1402 and a third sub-pixel isolation part 1403 that are stacked in a direction perpendicular to the base substrate 110, the second sub-pixel isolation part 1402 is located on a side of the first sub-pixel isolation part 1401 away from the base substrate 110, and the third sub-pixel isolation part 1403 is located on a side of the second sub-pixel isolation part 1402 away from the first sub-pixel isolation part 1401.

As illustrated by FIGS. 2 and 3, the second sub-pixel isolation part 1402 includes a plurality of sub-isolation layers 14020 stacked in the direction perpendicular to the base substrate, the first sub-pixel isolation part 1401 has a first protruding part 411 beyond at least one of the plurality of sub-isolation layers 14020 in an arrangement direction of two adjacent sub-pixels 200 of the plurality of sub-pixels 200, and the third sub-pixel isolation part 1403 has a second protruding part 412 extending beyond at least one of the plurality of sub-isolation layers 14020 in the arrangement direction of the two adjacent sub-pixels 200. It should be noted that, the above arrangement direction may be an extending direction of a brightness center of the adjacent sub-pixels; the brightness center of each of the sub-pixels may be a geometric center of an effective light-emitting region of each of the sub-pixels. Of course, embodiments of the present disclosure include but are not limited thereto, the brightness center of each of the sub-pixels can also be a position where a maximum value of light emitting brightness of each of the sub-pixels is located. In addition, the above-mentioned sub-isolation layer may not be an actual layer structure, but a plurality of sub-parts of the second sub-pixel isolation part with different sizes in the direction perpendicular to the base substrate due to factors such as a manufacturing process; in this case, in order to better describe the relationship between the second sub-pixel isolation part and other sub-pixel isolation parts, the above-mentioned plurality of sub-parts with different sizes are divided into a plurality of sub-isolation layers stacked in the direction perpendicular to the base substrate.

In the display substrate provided by the embodiment of the present disclosure, because the first sub-pixel isolation part has a first protruding part beyond at least one of the plurality of sub-isolation layers in the arrangement direction of the two adjacent sub-pixels, and the third sub-pixel isolation part has a second protruding part beyond at least one of the plurality of sub-isolation layers in the arrangement direction of the two adjacent sub-pixels, therefore, a side of the pixel isolation structure in the arrangement direction of the two adjacent sub-pixels will form a concave structure, so that at least one sub-functional layer in the light-emitting functional layer subsequently formed on the pixel isolation structure can be disconnected. In this way, by arranging the above-mentioned pixel isolation structure between adjacent sub-pixels, the display substrate can avoid crosstalk among adjacent sub-pixels caused by the sub-functional layer with higher conductivity in the light-emitting functional layer.

On the other hand, because the display substrate can avoid crosstalk among adjacent sub-pixels through the pixel isolation structure, the display substrate can increase the pixel density while adopting a dual-layer luminescence (Tandem EL) design. Therefore, the display substrate can have the advantages of long life, low power consumption, high brightness, and high resolution.

In some examples, the above-mentioned “adjacent sub-pixels” refer to two sub-pixels with no other sub-pixels arranged between them.

In some examples, as illustrated by FIGS. 2 and 3, in the arrangement direction of the two adjacent sub-pixels 200, an average size of the second sub-pixel isolation part 1402 is smaller than an average size of the first sub-pixel isolation part 1401 and an average size of the third sub-pixel isolation part 1403.

In some examples, as illustrated by FIGS. 2 and 3, an orthographic projection of the at least one of the plurality of sub-isolation layers 1402 on the base substrate 110 respectively falls within an orthographic projection of the first sub-pixel isolation part 1401 and an orthographic projection of the third sub-pixel isolation part 1403 on the base substrate 110. In this way, the side of the pixel isolation structure in the arrangement direction of the two adjacent sub-pixels will form a concave structure, so that at least one sub-functional layer in the light-emitting functional layer subsequently formed on the pixel isolation structure can be disconnected.

In some examples, as illustrated by FIGS. 2 and 3, an orthographic projection of the second sub-pixel isolation part 1402 on the base substrate 110 falls within the orthographic projection of the first sub-pixel isolation part 1401 and the orthographic projection of the third sub-pixel isolation part 1403 on the base substrate 110 respectively. In this way, relative to the first sub-pixel isolation part and the third sub-pixel isolation part, the entire second sub-pixel isolation part shrinks inward, thus the side of the pixel isolation structure in the arrangement direction of the two adjacent sub-pixels will form a concave structure, so that at least one sub-functional layer in the light-emitting functional layer subsequently formed on the pixel isolation structure can be disconnected.

In some examples, as illustrated by FIGS. 2 and 3, the plurality of sub-isolation layers 14020 of the second sub-pixel isolation part 1402 include a first sub-isolation layer 1402A, a second sub-isolation layer 1402B and a third sub-isolation layer 1402C that are stacked in the direction perpendicular to the base substrate 110, and an orthographic projection of the second sub-isolation layer 1402B on the base substrate 110 falls within an orthographic projection of the first sub-isolation layer 1402A and an orthographic projection of the third sub-isolation layer 1402C on the base substrate 110 respectively. In this way, the side of the second sub-pixel isolation part in the arrangement direction of the two adjacent sub-pixels will also form a concave structure.

In some examples, as illustrated by FIGS. 2 and 3, the side of the second sub-pixel isolation part 1402 in the arrangement direction of the two adjacent sub-pixels is a concave surface.

In some examples, as illustrated by FIGS. 1 and 2, the second electrode 132 is disconnected at the position where the pixel isolation structure 140 is located. However, embodiments of the present disclosure include but are not limited thereto, and the second electrode is not disconnected at the position where the pixel isolation structure is located, the second electrode can be disconnected or not disconnected at the position where the pixel isolation structure is located through the height, depth or other parameters of the pixel isolation structure.

In some examples, as illustrated by FIG. 2, the plurality of sub-functional layers 1200 of the light-emitting functional layer 120 include a charge generation layer 129, and a first light-emitting layer 121 and a second light-emitting layer 122 on two sides of the charge generation layer 129 in the direction perpendicular to the base substrate 110 respectively; the charge generation layer 129 is disconnected at the position where the pixel isolation structure is located. because the charge generation layer is disconnected at the position where the pixel isolation structure is located, by arranging the above-mentioned pixel isolation structure between adjacent sub-pixels, the display substrate can avoid crosstalk among adjacent sub-pixels caused by the charge generation layer with higher conductivity in the light-emitting functional layer. In addition, the display substrate can realize a double-layer light emitting (Tandem EL) design, so the display substrate has the advantages of long life, low power consumption, and high brightness. It should be noted that the charge generation layer is configured to generate carriers, transport carriers, and inject carriers.

In some examples, as illustrated by FIG. 2, the first light-emitting layer 121 and the second light-emitting layer 122 in the light-emitting functional layer 120 are also disconnected at the position where the isolation structure 140 is located. However, embodiments of the present disclosure include but are not limited thereto, the first light-emitting layer and the second light-emitting layer in the light-emitting functional layer may not be disconnected at the position of the isolation structure, but only the charge generation layer may be disconnected at the position of the isolation structure.

In some examples, the conductivity of the charge generation layer 129 is greater than the conductivity of the first light-emitting layer 121 and the conductivity of the second light-emitting layer 122, and is less than the conductivity of the second electrode 132.

In some examples, as illustrated by FIG. 2, the first light-emitting layer 121 is located on a side of the charge generation layer 129 close to the base substrate 110; and the second light-emitting layer 122 is located on a side of the charge generation layer 129 away from the base substrate 110. It should be noted that the light-emitting functional layer may also include other sub-functional layers in addition to the charge generation layer, the first light-emitting layer and the second light-emitting layer, for example, a hole injection layer, a hole transport layer, an electron injection layer and an electron transport layer.

In some examples, as illustrated by FIGS. 1 and 2, a line connecting brightness centers of two adjacent sub-pixels 200 passes through the pixel isolation structure 140. because a size of the charge generation layer in an extending direction of the connection line is smaller, resistance of the charge generation layer in the extending direction of the connection line is also smaller, and charges are easily transferred from one of the two adjacent sub-pixels to the other of the two adjacent sub-pixels through the charge generation layer along the extending direction of the connection line. Therefore, the display substrate allows the connection line between the brightness centers of the two adjacent sub-pixels to pass through the isolation structure, the isolation structure can effectively block the shortest propagation path of charges, so that crosstalk among adjacent sub-pixels can be effectively avoided.

In some examples, a material of the third sub-pixel isolation part 1403 includes a first metal, and a material of the second sub-pixel isolation part 1402 includes a second metal. In this way, selectivity of the etching process can be used to select an etchant that only etch the second metal but not the first metal, the third sub-pixel isolation part has a second protruding part beyond at least one of the plurality of sub-isolation layers in the arrangement direction of the two adjacent sub-pixels through the etching process. It should be noted that because the side of the second sub-pixel isolation part is etched to different degrees, thus a plurality of sub-isolation layers with different sizes are formed.

In some examples, a material of the first sub-pixel isolation part 1401 includes a first metal. In this way, the first sub-pixel isolation part has a first protruding part beyond at least one of the plurality of sub-isolation layers in the arrangement direction of the two adjacent sub-pixels through an etching process, so that a concave structure located on a side of the pixel isolation structure can be formed through the above-mentioned etching process.

In some examples, the first metal is titanium, and the second metal is aluminum. Of course, embodiments of the present disclosure include but are not limited thereto, the first metal and the second metal can also be selected from other suitable metal materials. In addition, the pixel isolation structure is not limited to be made of metal materials, the pixel isolation structure can also be made of inorganic non-metallic materials.

In some examples, the materials of the first sub-pixel isolation part 1401 and third sub-pixel isolation part 1403 include a first inorganic non-metal material, and the material of the second sub-pixel part 14022 includes a second inorganic non-metal material. At this time, selectivity of the etching process can also be used, an etchant is selected that only etch the second microporous non-metal material, but does not etch the first inorganic non-metal material, the first sub-pixel isolation part has a first protruding part beyond at least one of the plurality of sub-isolation layers in the arrangement direction of the two adjacent sub-pixels through an etching process, and the third sub-pixel isolation part has a second protruding part beyond at least one of the plurality of sub-isolation layers in the arrangement direction of the two adjacent sub-pixels.

In some examples, the first inorganic non-metal material includes silicon oxide, and the second inorganic non-metal material includes silicon nitride. Of course, embodiments of the present disclosure include but are not limited thereto, the first inorganic non-metal material and the second inorganic non-metal material may also be other suitable inorganic non-metal materials.

In some examples, as illustrated by FIGS. 1 and 2, the display substrate 100 further includes a pixel defining layer 150 located on the base substrate 110; the pixel defining layer 150 is partially located on a side of the first electrodes 131 away from the base substrate 110; the pixel defining layer 150 includes a plurality of pixel openings 152 and a pixel spacing opening 154; the plurality of pixel openings 152 correspond to the plurality of sub-pixels 200 one-to-one to define the effective light-emitting areas of the plurality of sub-pixels 200; the plurality of pixel openings 152 are configured to expose the first electrodes 131, so that the first electrodes 131 are in contact with the subsequently formed light-emitting functional layer 120. The pixel spacing opening 154 are located between adjacent first electrodes 131, and at least a part of the isolation structure 140 is located in the pixel spacing opening 154. In this way, the display substrate can avoid forming an isolation structure on the pixel defining layer, so that increasing thickness of the display substrate is avoided. Of course, embodiments of the present disclosure include but are not limited thereto, the pixel defining layer does not need to be arranged in the above-mentioned pixel spacing opening, so that the isolation structure can be directly arranged on the pixel definition layer, or the isolation structure can be manufactured by using the pixel definition layer.

For example, the material of the pixel defining layer may include organic materials, such as polyimide, acrylic, or polyethylene terephthalate.

In some examples, as illustrated by FIGS. 1 and 2, the display substrate 100 further includes a planarization layer 180, the planarization layer 180 is located between the base substrate 110 and the first electrodes 131; and the pixel isolation structure 140 is in direct contact with the planarization layer 180.

For example, the material of the planarization layer 180 may be an organic material, such as one or a combination of resin, acrylic or polyethylene terephthalate, polyimide, polyamide, polycarbonate, and epoxy resin.

In some examples, other film layers are disposed between the planarization layer 180 and the base substrate 110, these other film layers may include film layers or structures such as gate insulating layers, interlayer insulating layers, various film layers in the pixel circuit (for example, including thin film transistors, storage capacitors and other structures), data lines, gate lines, power signal lines, reset power signal lines, reset control signal lines, and light-emitting control signal lines.

In the following, the plane layout design of the pixel isolation structure provided by the embodiment of the present disclosure will be described with reference to FIG. 1. It should be noted that FIG. 1 is only an example of a pixel isolation structure provided by an embodiment of the present disclosure, the pixel isolation structure can also adopt other suitable layout designs.

As illustrated by FIG. 1, the plurality of sub-pixels 200 include a plurality of first color sub-pixels 201, a plurality of second color sub-pixels 202 and a plurality of third color sub-pixels 203, the pixel isolation structure 140 includes a plurality of annular isolation parts 1400, each of the plurality of pixel annular isolation parts 1400 surrounds a first color sub-pixel 201, a second color sub-pixel 202 or a third color sub-pixel 203.

In this display substrate, because the pixel isolation structure includes a plurality of annular isolation parts, each of the plurality of annular isolation part surrounds a first color sub-pixel, a second color sub-pixel or a third color sub-pixel, thus this pixel isolation structure can achieve isolating of most adjacent sub-pixels through simple annular isolation parts, so that crosstalk among adjacent sub-pixels is avoided.

In some examples, as illustrated by FIG. 1, the plurality of annular isolation parts 1400 include a plurality of first annular pixel isolation parts 141A and a plurality of second annular pixel isolation parts 142A, the plurality of first annular pixel isolation parts 141A and the plurality of first color sub-pixels 201 are arranged correspondingly, the plurality of second annular pixel isolations 142A and the plurality of third color sub-pixels 203 are arranged correspondingly; each of the plurality of first annular pixel isolation parts 141A surrounds a first color sub-pixel 201, each of the plurality of second annular pixel isolation parts 142A surrounds a third color sub-pixel 203. In this way, the plurality of first annular pixel isolation parts 141A can separate the plurality of first color sub-pixels 201 from other adjacent sub-pixels, the plurality of second annular pixel isolation parts 142 can separate the plurality of third color sub-pixels 203 from other adjacent sub-pixels, in this way, the display substrate can effectively avoid crosstalk among adjacent sub-pixels.

In some examples, as illustrated by FIG. 1, the plurality of first annular pixel isolation parts 141A and the plurality of second annular pixel isolation parts 142A are combined to form a grid structure.

In some examples, as illustrated by FIG. 1, a plurality of first color sub-pixels 201 and a plurality of third color sub-pixels 203 are alternately arranged along both the first direction and the second direction to form a plurality of first pixel rows 310 and a plurality of first pixel columns 320, the plurality of second color sub-pixels 202 are arranged in an array along the first direction and the second direction to form a plurality of second pixel rows 330 and a plurality of second pixel columns 340, the plurality of first pixel rows 310 and the plurality of second pixel rows 330 are alternately arranged along the second direction and staggered from each other in the first direction, and the plurality of first pixel columns 320 and the plurality of second pixel columns 340 are alternately arranged along the first direction and are staggered from each other in the second direction. The pixel isolation structure 140 is located between the first color sub-pixel 201 and the third color sub-pixel 203 that are adjacent, and/or, the pixel isolation structure 140 is located between the second color sub-pixel 202 and the third color sub-pixel 203 that are adjacent, and/or, the pixel isolation structure 140 is located between the first color sub-pixel 201 and the second color sub-pixel 202 that are adjacent.

In some examples, the light emitting efficiency of the third color sub-pixels is less than the light emitting efficiency of the second color sub-pixels.

For example, the first color sub-pixels 201 are configured to emit red light, the second color sub-pixels 202 are configured to emit green light, and the third color sub-pixels 203 are configured to emit blue light. Of course, embodiments of the present disclosure include but are not limited thereto.

In some examples, as illustrated by FIG. 1, an area of an orthographic projection of effective light-emitting region of the third color sub-pixels 203 on the base substrate 110 is greater than an area of an orthogonal projection of effective light-emitting region of the first color sub-pixels 201 on the base substrate 110; and the area of the orthographic projection of the effective light-emitting region of the first color sub-pixels 201 on the base substrate 110 is greater than an area of an orthogonal projection of effective light-emitting region of the second color sub-pixels 202 on the base substrate 110. Of course, embodiments of the present disclosure include but are not limited thereto, the area of the effective light-emitting region of each of the sub-pixels can be set according to actual needs.

In some examples, as illustrated by FIG. 1, the display substrate 100 further includes a spacer 170; the spacer 170 is located between the first color sub-pixel 201 and the third color sub-pixel 203. It should be noted that the spacers are used to support the evaporation mask for manufacturing the above-mentioned light-emitting layer.

FIG. 4 is a structural schematic diagram of a light-emitting functional layer of a sub-pixel in a display substrate provided by an embodiment of the present disclosure. It should be noted that FIG. 4 shows a layer structure of the light-emitting functional layer of sub-pixels of three different colors, therefore other structures between sub-pixels of different colors are not shown, such as pixel definition layers and pixel isolation structures.

As illustrated by FIG. 4, along the direction perpendicular to the base substrate 110, the plurality of sub-functional layers 1200 of the light-emitting functional layer 120 include hole transport layers 124 matching first light-emitting layers of different colors, the first light-emitting layer 121 of different colors, charge generation layers 129, hole output layers 126 matching second light-emitting layers of different colors, the second light-emitting layers 122 of different colors, electron transport layers 127 and electron injection layers 128.

As illustrated by FIG. 4, the hole transport layers 124 matching the first light emitting layers of different colors include a red hole transport layer 124R, a green hole output layer 124G and a blue hole output layer 124B; and the first light emitting layers 121 include a first red light emitting layer 121R, a first green light emitting layer 121G and a first blue light emitting layer 121B respectively located on the red hole transport layer 124R, the green hole output layer 124G and the blue hole output layer 124B. It should be noted that the first red light-emitting layer 121R, the first green light-emitting layer 121G and the first blue light-emitting layer 121B shown in FIG. 4 have a same thickness, however, the thicknesses of the first red emitting layer 121R, the first green emitting layer 121G and the first blue emitting layer 121B may be the same or different, and their thickness can be set according to actual conditions.

As illustrated by FIG. 4, the hole transport layers 126 matching the second light-emitting layers of different colors include a red hole transport layer 126R, a green hole output layer 126G and a blue hole output layer 126B; and the second light emitting layers 122 include a second red light emitting layer 122R, a second green light emitting layer 122G and a second blue light emitting layer 122B respectively located on the red hole transport layer 126R, the green hole output layer 126G and the blue hole output layer 126B. It should be noted that the second red emitting layer 122R, the second green emitting layer 122G and the second blue emitting layer 122B shown in FIG. 4 have a same thickness, however, the thicknesses of the second red emitting layer 122R, the second green emitting layer 122G and the second blue emitting layer 122B may be the same or different, their thicknesses can be set according to actual conditions.

As illustrated by FIG. 4, along the direction perpendicular to the base substrate 110, the plurality of sub-functional layers 1200 of the light-emitting functional layer 120 further include a hole blocking layer 125 located between the charge generation layer 129 and the first light-emitting layer 121.

As illustrated by FIG. 4, the charge generation layers 129 include a stacked n-type doped layer 129A for generating holes and a p-type doped layer 129B for generating electrons. For example, the material of the charge generation layers 129 may include an n-type doped organic layer/p-type doped organic layer, such as BPhen:Cs/NPB:F4-TCNQ, Alq₃:Li/NPB:FeCl₃, TPBi:Li/NPB:FeCl₃ and Alq₃:Mg/m-MTDATA:F4-TCNQ. Of course, embodiments of the present disclosure include but are not limited thereto. The material of the charge generation layers may also include a n-type doped organic layer/inorganic metal oxide, such as Alq₃:Mg/WO₃, Bphen:Li/MoO₃, BCP:Li/V₂O₅ and BCP:Cs/V₂O₅; or, a n-type doped organic layer/organic layer, such as Alq₃:Li/HAT-CN; or, a non-doped material, such as F16CuPc/CuPc and Al/WO₃/Au.

For example, materials of the first emitting layer and the second emitting layer may be selected from pyrene derivatives, anthracene derivatives, fluorene derivatives, perylene derivatives, styrylamine derivatives, and metal complexes.

For example, material of the hole injection layer may include an oxide, such as: molybdenum oxide, titanium oxide, vanadium oxide, rhenium oxide, ruthenium oxide, chromium oxide, zirconium oxide, hafnium oxide, tantalum oxide, silver oxide, tungsten oxide, and manganese oxide.

For example, the material of the hole injection layer may also include organic materials, such as: hexacyanohexaazatriphenylene, 2,3,5,6-tetrafluoro-7,7,8,8-tetracyanoquinodimethane (F4TCNQ), 1,2,3-tris[(cyano) (4-cyano-2,3,5,6-tetrafluorophenyl)methylene]cyclopropane.

For example, the material of the hole transport layer may include aromatic amines with hole transport properties and dimethylfluorene or carbazole materials, such as: 4,4′-bis[N-(1-naphthyl)-N-phenylamino]biphenyl (NPB), N,N′-bis(3-methylphenyl)-N,N′-diphenyl-[1,1′-biphenyl]-4,4′-diamine (TPD), 4-Phenyl-4′-(9-phenylfluoren-9-yl)triphenylamine (BAFLP), 4,4′-bis[N-(9,9-dimethylfluoren-2-yl)-N-phenylamino]biphenyl (DFLDPBi), 4,4′-bis(9-carbazolyl)biphenyl (CBP), and 9-Phenyl-3-[4-(10-phenyl-9-anthracenyl)phenyl]-9H-carbazole (PCzPA).

For example, material of the electron transport layer may include aromatic heterocyclic compounds, such as: benzimidazole derivatives, imidazole derivatives, pyrimidine derivatives, oxazine derivatives, quinoline derivatives, isoquinoline derivatives, phenanthroline derivatives, etc.

For example, the material of the electron injection layer can be alkali metals or metals and their compounds, such as: Lithium fluoride (LiF), ytterbium (Yb), magnesium (Mg), and calcium (Ca).

In some examples, the first electrodes 131 may be made of metal material, such as any one or more of magnesium (Mg), silver (Ag), copper (Cu), aluminum (Al), titanium (Ti) and molybdenum (Mo), or alloy materials of the above metals, such as aluminum-neodymium alloy (AlNd) or molybdenum-niobium alloy (MoNb), which can be a single-layer structure or a multi-layer composite structure, such as Ti/Al/Ti, etc., or, the first electrodes 131 may be a stack structure formed by metal and transparent conductive materials, such as ITO/Ag/ITO, Mo/AlNd/ITO and other reflective materials.

In some examples, the second electrode 132 may be made of any one or more of magnesium (Mg), silver (Ag), and aluminum (Al). or alloys made of any one or more of the above metals, or use transparent conductive material, such as indium tin oxide (ITO), or, a multi-layer composite structure of metal and transparent conductive material.

In some examples, the base substrate 110 may be made of one or more materials selected from glass, polyimide, polycarbonate, polyacrylate, polyetherimide, and polyethersulfone, this embodiment includes but is not limited thereto.

In some examples, the base substrate may be a rigid substrate or a flexible substrate; in a case that the base substrate is a flexible substrate, the base substrate may include a first flexible material layer, a first inorganic non-metallic material layer, a semiconductor layer, a second flexible material layer and a second inorganic non-metallic material layer that are stacked in sequence. The first flexible material layer and the second flexible material layer are made of materials such as polyimide (PI), polyethylene terephthalate (PET) or surface-treated polymer soft film. The first inorganic non-metallic material layer and the second inorganic non-metallic material layer are made of silicon nitride (SiNx) or silicon oxide (SiOx), etc., which is used to improve water and oxygen resistance of the base substrate, and the first inorganic non-metal material layer and the second inorganic non-metal material layer are also called barrier layers. Material of the semiconductor layer is amorphous silicon (a-si).

For example, taking the base substrate as a stacked structure P11/Barrier1/a-si/PI2/Barrier2 as an example, a manufacturing process of the substrate includes: first coating a layer of polyimide on a glass carrier plate, curing a film to form the first flexible (PI1) layer; subsequently depositing a barrier film on the first flexible layer, to form a first barrier (Barrier1) layer covering the first flexible layer; then depositing an amorphous silicon film on the first barrier layer, to form an amorphous silicon (a-si) layer covering the first barrier layer; then coating a layer of polyimide on the amorphous silicon layer, curing a film to form a second flexible (PI2) layer; then depositing a barrier film on the second flexible layer, to form a second barrier (Barrier2) layer covering the second flexible layer, and finally completing the preparation of the substrate.

FIG. 5 is a cross-sectional schematic diagram of a display substrate provided by an embodiment of the present disclosure. As illustrated by FIG. 5, the display substrate 100 further includes a planarization layer 180 between the base substrate 110 and the first electrodes 131 and a pixel isolation structure 140 on the planarization layer 180, and the pixel isolation structure 140 is in direct contact with the planarization layer 180. It should be noted that a protection structure can be formed below the pixel isolation structure, to prevent the underlying planarization layer from being etched.

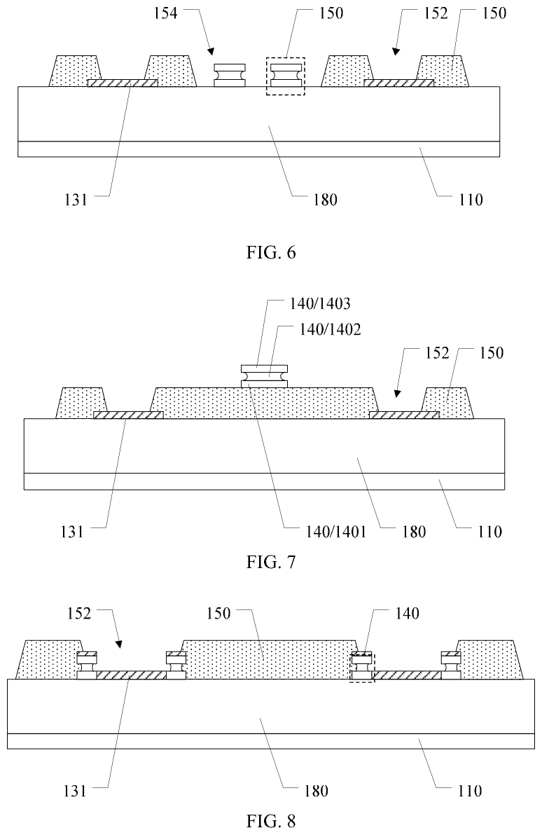

FIG. 6 is a cross-sectional schematic diagram of another display substrate provided by an embodiment of the present disclosure. As illustrated by FIG. 6, in the display substrate 100, a plurality of pixel isolation structures 140 are arranged between two adjacent sub-pixels 200. As illustrated by FIG. 6, two pixel isolation structures 140 are arranged between two adjacent sub-pixels 200. Embodiments of the present disclosure include but are not limited thereto, more pixel isolation structures can be arranged between two adjacent sub-pixels.

FIG. 7 is a cross-sectional schematic diagram of still another display substrate provided by an embodiment of the present disclosure. As illustrated by FIG. 7, the display substrate 100 further includes a pixel defining layer 150; the pixel defining layer 150 is partially located on a side of the first electrodes 131 away from the base substrate 110; the pixel defining layer 150 includes a plurality of pixel openings 152; the plurality of pixel openings 152 correspond to the plurality of sub-pixels 200 one-to-one to define the effective light-emitting areas of the plurality of sub-pixels 200; the plurality of pixel openings 152 are configured to expose the first electrodes 131, so that the first electrodes 131 are in contact with the subsequently formed light-emitting functional layer 120.

As illustrated by FIG. 7, the pixel isolation structure 140 is located on a side of the pixel defining layer 150 away from the base substrate 110; that is, the pixel isolation structure 140 is located on the pixel defining layer 150 between adjacent pixel openings 152. In this way, the display substrate can directly set the pixel isolation structure on the pixel defining layer, so that at least one sub-functional layer in the light-emitting functional layer is disconnected at the edge of the first electrode, so that crosstalk among adjacent sub-pixels is avoided.

FIG. 8 is a cross-sectional schematic diagram of still another display substrate provided by an embodiment of the present disclosure. As illustrated by FIG. 8, the display substrate 100 further includes a pixel defining layer 150 located on the base substrate 110; the pixel defining layer 150 is partially located on a side of the first electrodes 131 away from the base substrate 110; the pixel defining layer 150 includes a plurality of pixel openings 152; the plurality of pixel openings 152 correspond to the plurality of sub-pixels 200 one-to-one to define the effective light-emitting areas of the plurality of sub-pixels 200; and the plurality of pixel openings 152 are configured to expose the first electrodes 131, so that the first electrodes 131 are in contact with the subsequently formed light-emitting functional layer 120.

As illustrated by FIG. 8, at least a part of the pixel isolation structure 140 is located in the pixel opening 152. In this way, the display substrate can directly set a pixel isolation structure on the edge of the first electrode, so that at least one sub-functional layer in the light-emitting functional layer is disconnected at the edge of the first electrode, so that crosstalk among adjacent sub-pixels is avoided. In addition, because the pixel isolation structure is directly arranged in the pixel opening, there is no need to set additional intervals between adjacent sub-pixels for placing pixel isolation structures, thus the display substrate can increase pixel density.

In some examples, as illustrated by FIG. 8, the pixel isolation structures 140 are located at an edge of the first electrodes 131, a surface of each of the pixel isolation structures 140 away from the base substrate 110 is at least partially covered by material of the first electrodes 131. In this way, the display substrate avoids crosstalk among adjacent sub-pixels, and can also ensure an area of an effective display region of each of the sub-pixels to the greatest extent while increasing the pixel density.

In some examples, as illustrated by FIG. 8, orthographic projections of the pixel isolation structures 140 on the base substrate 110 are at least partially overlapped with an orthographic projection of the pixel defining layer 150 on the base substrate 110. In this way, the display substrate avoids crosstalk among adjacent sub-pixels, and can also ensure an area of an effective display region of each of the sub-pixels to the greatest extent while increasing the pixel density.

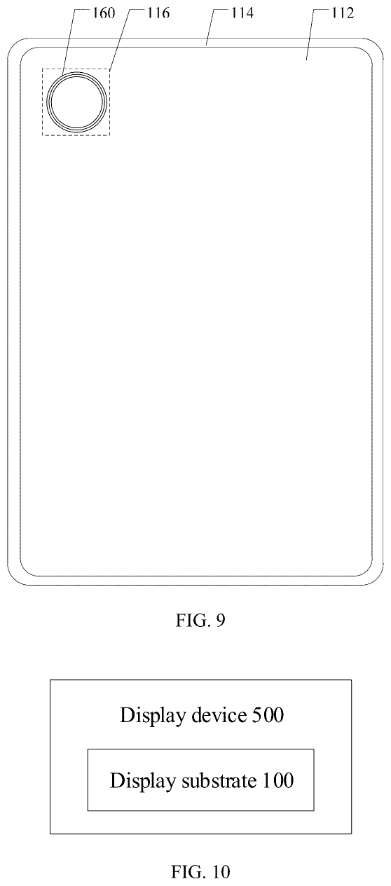

FIG. 9 is a planar schematic diagram of a display substrate provided by an embodiment of the present disclosure. As illustrated by FIG. 9, the base substrate 110 includes a display region 112 and a peripheral region 114 surrounding the display region 112. The display region 112 includes an opening region 116, and an opening isolation structure 160 is arranged at an edge of the opening region 116. A cross-sectional structure of the opening isolation structure 160 is the same as a cross-sectional structure of the pixel isolation structure 140; that is, the opening isolation structure 160 also has a plurality of stacked opening isolation parts, and a concave structure is formed on a side of the opening isolation structure. In this way, a film layer with higher conductivity in the light-emitting functional layer can be disconnected at the opening isolation structure at the edge of the opening region. It should be noted that no sub-pixels are arranged in the opening region, and light is allowed to pass through. It should be noted that the cross-sectional structure of the opening isolation structure can adopt the cross-sectional structure of the pixel isolation structure provided in any one of the above examples, for the sake of brevity, the embodiments of the present disclosure will not be described in detail herein.

In some examples, the material of the opening isolation structure 160 is the same as material of the pixel isolation structure 140. It should be noted that the material of the opening isolation structure can be the material of the pixel isolation structure provided in any one of the above examples. For the sake of brevity, the embodiments of the present disclosure will not be described in detail herein.

At least one embodiment of the present disclosure further provides a display device. FIG. 10 is a schematic diagram of a display device provided by an embodiment of the present disclosure. As illustrated by FIG. 10, the display device 500 further includes a display substrate 100. The display substrate sets an isolation structure between adjacent sub-pixels, and the charge generation layer in the light-emitting functional layer is disconnected at a location of the isolation structure, so that crosstalk among adjacent sub-pixels caused by the charge generation layer with higher conductivity is avoided. In this way, a display device including the display substrate can also avoid crosstalk among adjacent sub-pixels, thus the display device has higher product yield and higher display quality.

On the other hand, the display substrate can increase the pixel density while adopting a dual-layer light emitting (Tandem EL) design. Therefore, a display device including the display substrate has the advantages of long life, low power consumption, high brightness, and high resolution.

For example, the display device may be a display device such as an organic light-emitting diode display device, as well as any products or components with display functions such as televisions, digital cameras, mobile phones, watches, tablet computers, laptop computers, and navigators that include the display device, the embodiment is not limited thereto.

At least one embodiment of the present disclosure further provides a manufacturing method of a display substrate. The manufacturing method of the display substrate includes: forming a plurality of first electrodes on the base substrate; forming a pixel isolation structure on the base substrate; forming a light-emitting functional layer on a side of the pixel isolation structure and the plurality of first electrodes away from the base substrate, the light-emitting functional layer includes a plurality of sub-functional layers; and forming a second electrode on a side of the light-emitting functional layer away from the base substrate, and the second electrode, the light-emitting functional layer and the plurality of first electrodes form light-emitting elements of a plurality of sub-pixels, the pixel isolation structure is located between adjacent sub-pixels, the pixel isolation structure includes a first sub-pixel isolation part, a second sub-pixel isolation part and a third sub-pixel isolation part that are stacked, the second sub-pixel isolation part is located on a side of the first sub-pixel isolation part away from the base substrate, the third sub-pixel isolation part is located on a side of the second sub-pixel isolation part away from the first sub-pixel isolation part, the second sub-pixel isolation part includes a plurality of sub-isolation layers stacked in a direction perpendicular to the base substrate, the first sub-pixel isolation part has a first protruding part beyond at least one of the plurality of sub-isolation layers in an arrangement direction of two adjacent sub-pixels of the plurality of sub-pixels, and the third sub-pixel isolation part has a second protruding part beyond at least one of the plurality of sub-isolation layers in an arrangement direction of the two adjacent sub-pixels.

In the manufacturing method of the display substrate provided by the embodiment of the present disclosure, because the first sub-pixel isolation part has a first protruding part beyond at least one of the plurality of sub-isolation layers in the arrangement direction of the two adjacent sub-pixels, the third sub-pixel isolation part has a second protruding part beyond at least one of the plurality of sub-isolation layers in the arrangement direction of the two adjacent sub-pixels, thus the side of the pixel isolation structure in the arrangement direction of the two adjacent sub-pixels will form a concave structure, so that at least one sub-functional layer in the light-emitting functional layer subsequently formed on the pixel isolation structure can be disconnected. In this way, by arranging the above-mentioned pixel isolation structure between adjacent sub-pixels, the display substrate manufactured by the manufacturing method of the display substrate can avoid crosstalk among adjacent sub-pixels caused by the sub-functional layer with higher conductivity in the light-emitting functional layer.

On the other hand, because the display substrate manufactured by the display substrate manufacturing method can avoid crosstalk among adjacent sub-pixels through the pixel isolation structure, the display substrate can increase the pixel density while adopting a dual-layer light emitting (Tandem EL) design. Therefore, the display substrate can have the advantages of long life, low power consumption, high brightness, and high resolution.

In some examples, in the arrangement direction of the two adjacent sub-pixels 200, an average size of the second sub-pixel isolation part 1402 is smaller than an average size of the first sub-pixel isolation part 1401 and an average size of the third sub-pixel isolation part 1403.

In some examples, an orthographic projection of the at least one of the plurality of sub-isolation layers 14020 on the base substrate 110 respectively falls within orthographic projections of the first sub-pixel isolation part 1401 and the third sub-pixel isolation part 1403 on the base substrate 110. In this way, the pixel isolation structure will form a concave structure on the side in the arrangement direction of the two adjacent sub-pixels, so that at least one sub-functional layer in the light-emitting functional layer subsequently formed on the pixel isolation structure can be disconnected.

In some examples, an orthographic projection of the second sub-pixel isolation 1402 on the substrate 110 falls within orthographic projections of the first sub-pixel isolation 1401 and the third sub-pixel isolation 1403 on the substrate 110 respectively. In this way, relative to the first sub-pixel isolation part and the third sub-pixel isolation part, the entire second sub-pixel isolation part shrinks inward, thus the side of the pixel isolation structure in the arrangement direction of the two adjacent sub-pixels will form a concave structure, so that at least one sub-functional layer in the light-emitting functional layer subsequently formed on the pixel isolation structure can be disconnected.

In some examples, the plurality of sub-isolation layers 14020 of the second sub-pixel isolation part 1402 include a first sub-isolation layer 1402A, a second sub-isolation layer 1402B and a third sub-isolation layer 1402C that are stacked in the direction perpendicular to the base substrate 110, and an orthographic projection of the second sub-isolation layer 1402B on the base substrate 110 falls within orthographic projections of the first sub-isolation layer 1402A and the third sub-isolation layer 1402C on the base substrate 110 respectively. In this way, the side of the second sub-pixel isolation part in the arrangement direction of the two adjacent sub-pixels will also form a concave structure.

In some examples, the side of the second sub-pixel isolation part 1402 in the arrangement direction of the two adjacent sub-pixels is a concave surface.

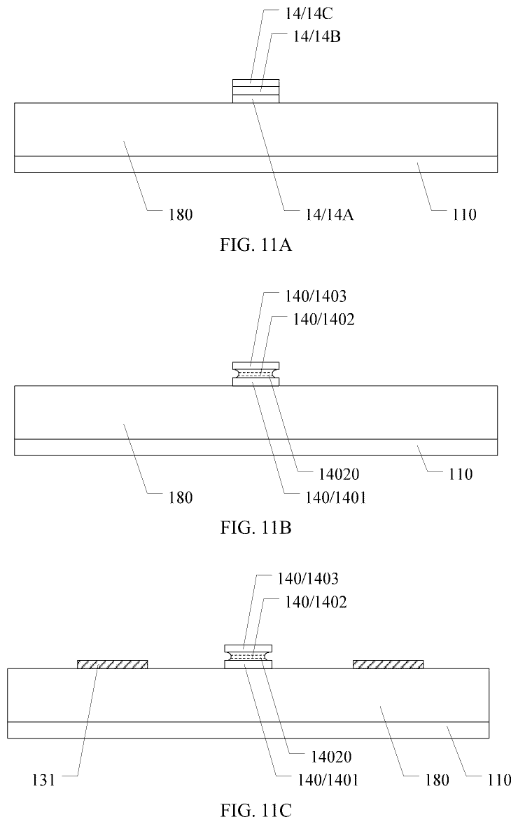

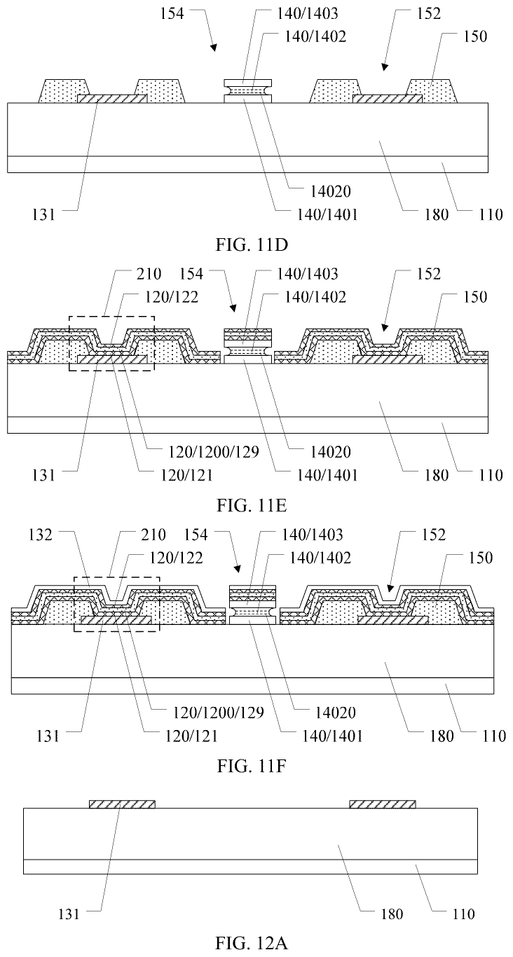

FIGS. 11A to 11F are schematic diagrams of steps of a display substrate provided by an embodiment of the present disclosure. As illustrated by FIGS. 11A to 11F, the manufacturing method of the display substrate includes:

As illustrated by FIG. 11A, a stacked structure 14 is formed on the base substrate 110 before forming a plurality of first electrodes 131 on the base substrate 110, in which the stacked structure 14 includes a first sub-layer 14A, a second sub-layer 14B and a third sub-layer 14C that are stacked.

As illustrated by FIG. 11B, the stacked structure 14 is etched to remove a part of the second sub-layer 14B, so that the stacked structure 14 forms the pixel isolation structure 140, the first sub-layer 14A forms the first sub-pixel isolation part 1401, the second sub-layer 14B forms the second sub-pixel isolation part 1402, and the third sub-layer 14C forms the third sub-pixel isolation part 1403.

In the manufacturing method of the display substrate provided in this example, the entire pixel isolation structure is completed before forming the first electrode, in this way, the manufacturing process steps of the pixel isolation structure can be avoided from adversely affecting the formation of the first electrode.

For example, materials of the first sub-layer 14A and the third sub-layer 14C include a first metal, material of the second sub-layer 14B includes a second metal. In this way, selectivity of the etching process can be used to select an etchant that only etches the second metal but not the first metal, the first sub-pixel isolation part has a first protruding part beyond at least one of the plurality of sub-isolation layers in the arrangement direction of the two adjacent sub-pixels through an etching process, and the third sub-pixel isolation part has a second protruding part beyond at least one of the plurality of sub-isolation layers in the arrangement direction of the two adjacent sub-pixels. It should be noted that because the side of the second sub-pixel isolation part is etched to different degrees, a plurality of sub-isolation layers with different sizes will be formed.

In some examples, the first metal is titanium and the second metal is aluminum. Of course, the embodiments of the present disclosure include but are not limited thereto, and other suitable metal materials can also be selected for the first metal and the second metal. In addition, the pixel isolation structure is not limited to be made of metal materials, and the pixel isolation structure can also be made of inorganic non-metallic materials.

In some examples, materials of the first sub-layer 14A and the third sub-layer 14C include a first inorganic non-metal material, and the material of the second sub-layer 14B includes a second inorganic non-metal material. At this time, the selectivity of the etching process can also be utilized to select an etchant that only etches the second microporous non-metallic material but not the first inorganic non-metallic material, the first sub-pixel isolation part has a first protruding part beyond at least one of the plurality of sub-isolation layers in the arrangement direction of the two adjacent sub-pixels through an etching process, and the third sub-pixel isolation part has a second protruding part beyond at least one of the plurality of sub-isolation layers in the arrangement direction of the two adjacent sub-pixels.

In some examples, the first inorganic non-metal material includes silicon oxide, and the second inorganic non-metal material includes silicon nitride. Of course, embodiments of the present disclosure include but are not limited thereto, and the first inorganic non-metal material and the second inorganic non-metal material may also be other suitable inorganic non-metal materials.

As illustrated by FIG. 11C, after forming a pixel isolation structure 140, the first electrodes 13 are formed on the base substrate 110.

As illustrated by FIG. 11D, a pixel defining layer 150 is formed on a side of the first electrodes 131 and the pixel isolation structure 140 away from the base substrate 110, the pixel defining layer 150 includes a plurality of pixel openings 152 and a pixel spacing openings 154; the plurality of pixel openings 152 correspond to the plurality of sub-pixels 200 one-to-one to define effective light-emitting areas of the plurality of sub-pixels 200; the plurality of pixel openings 152 are configured to expose the first electrodes 131, so that the first electrodes 131 are in contact with the subsequently formed light-emitting functional layer 120. The pixel spacing opening 154 is located between adjacent first electrodes 131, at least a part of the isolation structure 140 is located within the pixel spacing opening 154.

For example, a material of the pixel defining layer may include organic materials, such as polyimide, acrylic or polyethylene terephthalate, etc.

As illustrated by FIG. 11E, a light-emitting functional layer 120 is formed on a side of the pixel defining layer 150 away from the base substrate 110, the light-emitting functional layer 120 includes a plurality of sub-functional layers 1200, the plurality of sub-functional layers 1200 include a charge generation layer 129, and a first light emitting layer 121 and a second light emitting layer 122 on two sides of the charge generation layer 129 in the direction perpendicular to the base substrate 110 respectively; because the side of the pixel isolation structure 140 in the arrangement direction of the two adjacent sub-pixels will form a concave structure, the charge generation layer 129 is disconnected at the position where the pixel isolation structure 140 is located.

As illustrated by FIG. 11F, a second electrode 132 is formed on a side of the light-emitting functional layer 120 away from the base substrate 110. It should be noted that the manufacturing method of the display substrate is not limited to the above steps, but may also include steps of forming other necessary film layers. For example, the manufacturing method of the display substrate further includes a step of forming a planarization layer on the base substrate, and a step of forming film layers such as a gate insulating layer, an interlayer insulating layer, and a pixel circuit layer (including thin film transistors, storage capacitors, and other structures) between the base substrate and the planarization layer.

For example, a material of the planarization layer can be an organic material, such as one or a combination of resin, acrylic or polyethylene terephthalate, polyimide, polyamide, polycarbonate, epoxy resin, etc.

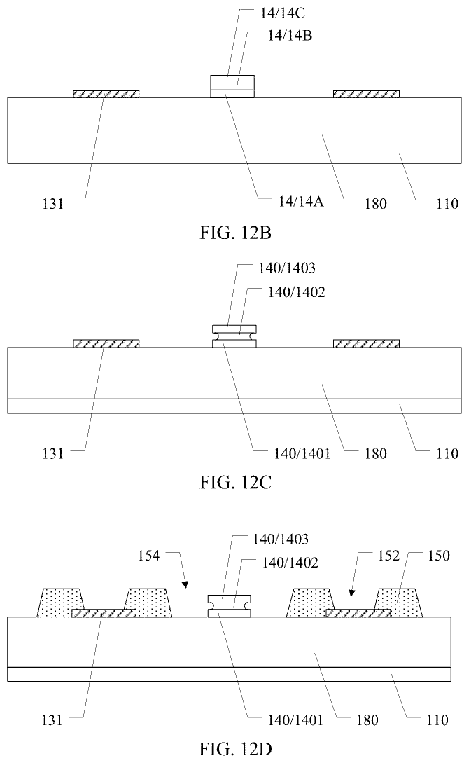

FIGS. 12A to 12D are schematic diagrams of steps of a display substrate provided by an embodiment of the present disclosure. As illustrated by FIGS. 12A to 12D, the manufacturing method of the display substrate includes:

As illustrated by FIG. 12A, a plurality of first electrodes 131 is formed on the base substrate 110. For example, a plurality of first electrodes 131 may be formed by using a same film layer through a same patterning process.

As illustrated by FIG. 12B, a stacked structure 14 is formed on a side of the base substrate 110, in which the stacked structure 14 includes a first sub-layer 14A, a second sub-layer 14B and a third sub-layer 14C that are stacked.

As illustrated by FIG. 12C, the stacked structure 14 is etched to remove a part of the second sub-layer 14B, so that the stacked structure 14 forms the pixel isolation structure 140, the first sub-layer 14A forms the first sub-pixel isolation part 1401, the second sub-layer 14B forms the second sub-pixel isolation part 1402, and the third sub-layer 14C forms the third sub-pixel isolation part 1403.

In the display substrate manufacturing method provided in this example, the entire pixel isolation structure is completed before forming the first electrode, in this way, the manufacturing process steps of the pixel isolation structure can be avoided from adversely affecting the formation of the first electrode.

For example, materials of the first sub-layer 14A and the third sub-layer 14C include a first metal, and the material of the second sub-layer 14B includes a second metal. In this way, the selectivity of the etching process can be used to select an etchant that only etches the second metal but not the first metal, the first sub-pixel isolation part has a first protruding part beyond at least one of the plurality of sub-isolation layers in the arrangement direction of the two adjacent sub-pixels through the etching process, and the third sub-pixel isolation part has a second protruding part beyond at least one of the plurality of sub-isolation layers in the arrangement direction of the two adjacent sub-pixels. It should be noted that because the side of the second sub-pixel isolation part is etched to different degrees, a plurality of sub-isolation layers with different sizes will be formed.

In some examples, the first metal is titanium, and the second metal is aluminum. Of course, the embodiments of the present disclosure include but are not limited thereto, and other suitable metal materials can also be selected for the first metal and the second metal. In addition, the pixel isolation structure is not limited to be made of metal materials, the pixel isolation structure can also be made of inorganic non-metallic materials.

In some examples, the materials of the first sub-layer 14A and the third sub-layer 14C include a first inorganic non-metal material, and the material of the second sub-layer 14B includes a second inorganic non-metal material. At this time, the selectivity of the etching process can also be utilized to select an etchant that only etches the second microporous non-metallic material but not the first inorganic non-metallic material, the first sub-pixel isolation part has a first protruding part beyond at least one of the plurality of sub-isolation layers in the arrangement direction of the two adjacent sub-pixels through the etching process, and the third sub-pixel isolation part has a second protruding part beyond at least one of the plurality of sub-isolation layers in the arrangement direction of the two adjacent sub-pixels.

In some examples, the first inorganic non-metal material includes silicon oxide, and the second inorganic non-metal material includes silicon nitride. Of course, embodiments of the present disclosure include but are not limited thereto, and the first inorganic non-metal material and the second inorganic non-metal material may also be other suitable inorganic non-metal materials.

As illustrated by FIG. 12D, a pixel defining layer 150 is formed on a side of the first electrodes 131 and the pixel isolation structure 140 away from the base substrate 110, in which the pixel defining layer 150 includes a plurality of pixel openings 152 and a pixel spacing opening 154; the plurality of pixel openings 152 correspond to the plurality of sub-pixels 200 one-to-one to define effective light-emitting areas of the plurality of sub-pixels 200; the plurality of pixel openings 152 are configured to expose the first electrodes 131, so that the first electrodes 131 are in contact with the subsequently formed light-emitting functional layer 120. The pixel spacing opening 154 is located between adjacent first electrodes 131, and at least a part of the isolation structure 140 is located in the pixel spacing opening 154.

For example, the material of the pixel defining layer may include organic materials, such as polyimide, acrylic or polyethylene terephthalate, etc.

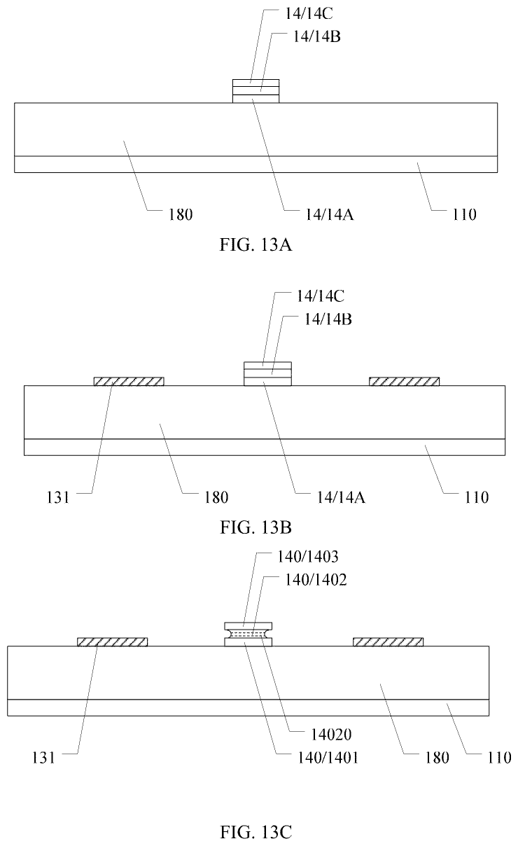

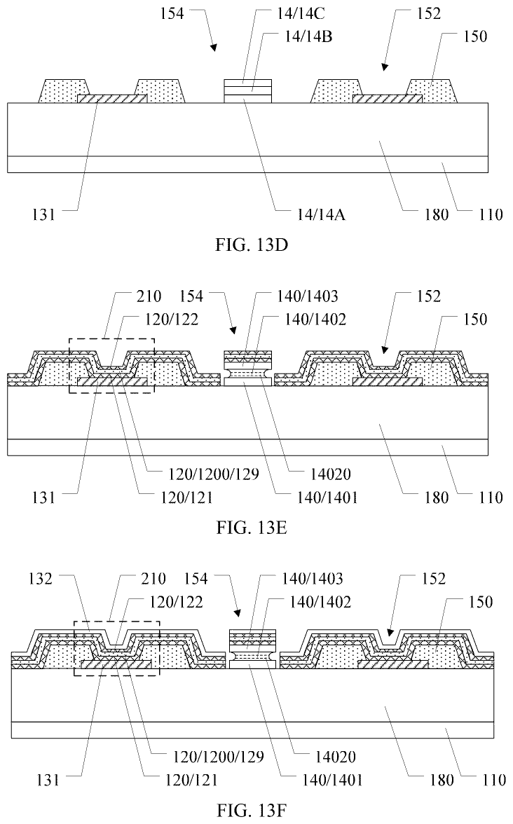

FIGS. 13A to 13F are schematic diagrams of steps of still another display substrate provided by an embodiment of the present disclosure. As illustrated by FIGS. 13A to 13F, the manufacturing method of the display substrate also includes:

As illustrated by FIG. 13A, before forming a plurality of first electrodes 131 on the base substrate 110, a stacked structure 14 is formed on the base substrate 110, in which the stacked structure 14 includes a first sub-layer 14A, a second sub-layer 14B and a third sub-layer 14C that are stacked.

As illustrated by FIG. 13B, a plurality of first electrodes 131 are formed on the base substrate 110.

As illustrated by FIG. 13C, after forming a plurality of first electrodes 131 on the base substrate 110, a pixel defining layer 150 is formed on a side of the stacked structure 14 and the first electrodes 131 away from the base substrate 110, and the pixel defining layer 150 is patterned to form a plurality of pixel openings 152 and a pixel spacing opening 154 on the pixel defining layer 150; in which the plurality of pixel openings 152 correspond to the plurality of sub-pixels 200 one-to-one to define effective light-emitting areas of the plurality of sub-pixels 200; the plurality of pixel openings 152 are each configured to expose the first electrodes 131, so that the first electrodes 131 are in contact with the subsequently formed light-emitting functional layer 120. The pixel spacing opening 154 is located between adjacent first electrodes 131, and at least a part of the isolation structure 140 is located in the pixel spacing opening 154.

As illustrated by FIG. 13D, the stacked structure 14 is etched to remove a part of the second sub-layer 14B, so that the stacked structure 14 forms the pixel isolation structure 140, the first sub-layer 14A forms the first sub-pixel isolation part 1401, the second sub-layer 14B forms the second sub-pixel isolation part 1402, and the third sub-layer 14C forms the third sub-pixel isolation part 1403.

As illustrated by FIG. 13E, a light-emitting functional layer 120 is formed on a side of the pixel defining layer 150 away from the base substrate 110, in which the light-emitting functional layer 120 includes a plurality of sub-functional layers 1200, the plurality of sub-functional layers 1200 include a charge generation layer 129 and a first light emitting layer 121 and a second light emitting layer 122 on two sides in a direction perpendicular to the base substrate 110 respectively; because the side of the pixel isolation structure 140 in the arrangement direction of the two adjacent sub-pixels will form a concave structure, the charge generation layer 129 is disconnected at the position where the pixel isolation structure 140 is located.

As illustrated by FIG. 13F, a second electrode 132 is formed on a side of the light-emitting functional layer 120 away from the base substrate 110.

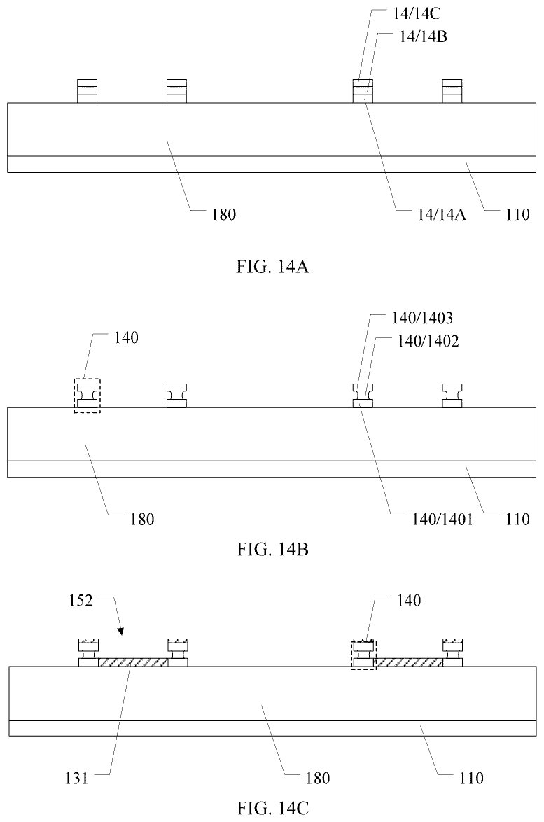

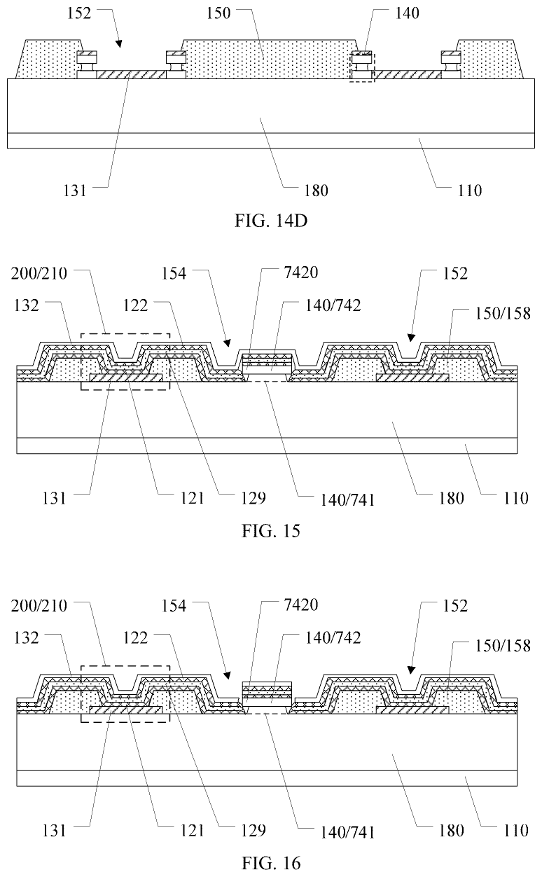

FIGS. 14A to 14D are schematic diagrams of steps of still another display substrate according to an embodiment of the present disclosure. As illustrated by FIGS. 14A to 14D, the manufacturing method of the display substrate also includes:

As illustrated by FIG. 14A, before forming a plurality of first electrodes 131 on the base substrate 110, a stacked structure 14 is formed on the base substrate 110, in which the stacked structure 14 includes a first sub-layer 14A, a second sub-layer 14B and a third sub-layer 14C that are stacked.

As illustrated by FIG. 14B, the stacked structure 14 is etched to remove a part of the second sub-layer 14B, so that the stacked structure 14 forms the pixel isolation structure 140, the first sub-layer 14A forms the first sub-pixel isolation part 1401, the second sub-layer 14B forms the second sub-pixel isolation part 1402, and the third sub-layer 14C forms the third sub-pixel isolation part 1403.

As illustrated by FIG. 14C, a plurality of first electrodes 131 are formed on the base substrate 110.

As illustrated by FIG. 14D, after forming a plurality of first electrodes 131 on the base substrate 110, the pixel defining layer 150 is formed on a side of the pixel isolation structure 140 and the first electrodes 131 away from the base substrate 110; and the pixel defining layer 150 is patterned to form a plurality of pixel openings 152 on the pixel defining layer 150; in which the plurality of pixel openings 152 correspond to the plurality of sub-pixels 200 one-to-one to define effective light-emitting areas of the plurality of sub-pixels 200; the plurality of pixel openings 152 are configured to expose the first electrodes 131 so that the first electrodes 131 are in contact with the subsequently formed light-emitting functional layer 120; at this time, the pixel isolation structure 140 is at least partially located in the plurality of pixel openings 152. In this way, the display substrate can directly set a pixel isolation structure on the edge of the first electrodes, so that at least one sub-functional layer in the light-emitting functional layer is disconnected at the edge of the first electrodes, so that crosstalk among adjacent sub-pixels is avoided. In addition, because the pixel isolation structure is directly installed in the pixel opening, there is no need to set an additional interval between adjacent sub-pixels for placing the pixel isolation structure, thus the display substrate can increase pixel density.

In some examples, as illustrated by FIG. 14D, the pixel isolation structure 140 is located at the edge of the first electrodes 131, and the surface of the pixel isolation structure 140 away from the base substrate 110 is at least partially covered by the material of the first electrodes 131. In this way, the display substrate avoids crosstalk among adjacent sub-pixels, and the display substrate can not only increase the pixel density, but also ensure an area of an effective display region of each of the sub-pixels to the greatest extent.

In some examples, as illustrated by FIG. 14D, an orthographic projection of the pixel isolation structure 140 on the base substrate 110 is at least partially overlapped with an orthographic projection of the pixel defining layer 150 on the base substrate 110. In this way, the display substrate avoids crosstalk among adjacent sub-pixels, and the display substrate can not only increase the pixel density, but also ensure an area of an effective display region of each of the sub-pixels to the greatest extent.

An embodiment of the present disclosure provides a display substrate. FIG. 15 is a structural schematic diagram of another display substrate provided by an embodiment of the present disclosure. As illustrated by FIG. 15, the display substrate 100 includes a base substrate 110 and a plurality of sub-pixels 200; the plurality of sub-pixels 200 are located on the base substrate 110, and each of the plurality of sub-pixels 200 includes a light-emitting element 210; each of the light-emitting elements 210 includes a light-emitting functional layer 120, and first electrodes 131 and a second electrode 132 located on two sides of the light-emitting functional layer 120 respectively, the first electrodes 131 are located between the light-emitting functional layer 120 and the base substrate 110; the second electrode 132 is at least partially located on a side of the light-emitting functional layer 120 away from the first electrodes 131; that is, the first electrodes 131 and the second electrode 132 are located on two sides in a direction perpendicular to the light-emitting functional layer 120 respectively. The light-emitting functional layer 120 includes a plurality of sub-functional layers, and the plurality of sub-functional layers include a conductive sub-layer 129 with relatively high conductivity. It should be noted that the above-mentioned light-emitting functional layer does not only include a film layer that directly emits light, but also includes a functional film layer for assisting light emitting, such as: a hole transport layer, a electron transport layer, etc.

For example, the conductive sub-layer 129 may be a charge generation layer. For example, the first electrode 131 may be an anode, and the second electrode 132 may be a cathode. For example, the cathode may be formed from a material with high conductivity and low work function, for example, the cathode can be made of metal material. For example, the anode may be formed from atransparent conductive material with a high work function.

As illustrated by FIG. 15, the display substrate 100 also includes an isolation structure 140, the isolation structure 140 is located on the base substrate 110, and is located between adjacent sub-pixels 200; the charge generation layer 129 in the light-emitting functional layer 120 is disconnected at the position where the isolation structure 140 is located. It should be noted that the above-mentioned “adjacent sub-pixels” means that there are no other sub-pixels between the two sub-pixels.

In the display substrate provided by the embodiment of the present disclosure, by arranging an isolation structure between adjacent sub-pixels, the charge generation layer in the light-emitting functional layer is disconnected at the position of the isolation structure, so that crosstalk among adjacent sub-pixels caused by the charge generation layer with higher conductivity is avoided. On the other hand, because the display substrate can avoid crosstalk among adjacent sub-pixels through the isolation structure, thus the display substrate can increase the pixel density while adopting a dual-layer light emitting (Tandem EL) design. Therefore, the display substrate can have the advantages of long life, low power consumption, high brightness, and high resolution.

In some examples, as illustrated by FIG. 15, each of the isolation structures 140 includes a first sub-isolation structure 741 and a second sub-isolation structure 742 that are stacked; the first sub-isolation structure 741 is located between the second sub-isolation structure 742 and the base substrate 110, and a material of the second sub-isolation structure 742 includes inorganic non-metallic materials.

In some examples, as illustrated by FIG. 15, along the arrangement direction of adjacent sub-pixels 200, the edge of the second sub-isolation structure 742 in the isolation structure 140 between the adjacent sub-pixels 200 protrudes relative to an edge of the first sub-isolation structure 741 to form an isolation protruding part 7420, at least one of the plurality of sub-functional layers included in the light-emitting functional layer 120 is disconnected at the isolation protruding part 7420. In embodiments of the present disclosure, the isolation structure is arranged between adjacent sub-pixels in the display substrate, at least one layer of the light-emitting functional layer can be disconnected at the isolation protruding part of the second sub-isolation structure, and it is beneficial to reduce probability of crosstalk among adjacent sub-pixels.

For example, as illustrated by FIG. 15, the plurality of sub-pixels 200 may include two adjacent sub-pixels 200. For example, at least one edge of the second sub-isolation structure 742 protrudes relative to a corresponding edge of the first sub-isolation structure 741 to form at least one isolation protruding part 7420.

For example, as illustrated by FIG. 15, both side edges of the second sub-isolation structure 742 protrude relative to the corresponding edges of the first sub-isolation structure 741 to form two isolation protruding part 7420.

FIG. 15 schematically shows that an isolation structure 140 is arranged between two adjacent sub-pixels 200, the isolation structure 140 includes two isolation protruding part 7420, but not limited thereto, two or more isolation structures can also be set between two adjacent sub-pixels, each of the isolation structures includes at least one isolation protruding part, by setting a number of isolation structures and a number of isolation protruding parts, at least one sub-functional layer of the light-emitting functional layer can be disconnected by the isolation structure.

For example, as illustrated by FIG. 15, an orthographic projection of a surface of the first sub-isolation structure 741 facing the second sub-isolation structure 742 on the base substrate 110 is completely located on an orthographic projection of a surface of the second sub-isolation structure 742 facing the base substrate 110 on the base substrate 110. For example, a size of the second sub-isolation structure 742 in the arrangement direction of adjacent sub-pixels is larger than a size of the surface of the first sub-isolation structure 741 facing the second sub-isolation structure 742 in the arrangement direction of adjacent sub-pixels.

For example, as illustrated by FIG. 15, in the direction perpendicular to the base substrate 110, a thickness of the first sub-isolation structure 741 is greater than a thickness of the second sub-isolation structure 742.

For example, as illustrated by FIG. 15, the light-emitting functional layer 120 may include a first light-emitting layer 121, a charge generation layer (CGL) 129 and a second light-emitting layer 122 that are stacked, and the charge generation layer 129 is located between the first light-emitting layer 121 and the second light-emitting layer 122. The charge generation layer has strong conductivity, which can make the light-emitting functional layer have the advantages of long life, low power consumption and high brightness, for example, compared with a light-emitting functional layer without a charge generation layer, the sub-pixel can nearly double the light emitting brightness by setting a charge generation layer in the light emitting functional layer.

For example, in each of the sub-pixels 200, the light-emitting functional layer 120 may also include a hole injection layer (HIL), a hole transport layer (HTL), an electron transport layer (ETL), and an electron injection layer (EIL).

For example, the hole injection layer, the hole transport layer, the electron transport layer, the electron injection layer and the charge generation layer are all common layers of a plurality of sub-pixels, which can be called a common layer. For example, at least one sub-functional layer in the light-emitting functional layer that is disconnected at the isolation protruding part may be at least one of the above-mentioned common layers. By disconnecting at least one sub-functional layer in the above-mentioned common layer at the isolation protruding part located between adjacent sub-pixels, the probability of crosstalk among adjacent sub-pixels can be reduced.

For example, in a same sub-pixel 200, the first light-emitting layer 121 and the second light-emitting layer 122 may be light-emitting layers that emit light of a same color. For example, the first light-emitting layer 121 (or the second light-emitting layer 122) in the sub-pixel 200 that emits light of different colors emits light of different colors. Of course, the embodiments of the present disclosure are not limited thereto; for example, in a same sub-pixel 200, the first light emitting layer 121 and the second light emitting layer 122 may be light emitting layers that emit light of different colors. By arranging light-emitting layers that emit light of different colors in the same sub-pixel 200, the light emitted by the multi-layer light-emitting layers included in the sub-pixel 200 can be mixed into white light, and the color of the light emitted from each sub-pixel is adjusted by setting a color filter layer.

For example, in adjacent sub-pixels 200, the light-emitting layers located on a same side of the charge generation layer 129 may be spaced apart from each other, or may overlap or connect at the interval between the two sub-pixels 200, and the embodiment of the present disclosure does not limit this.

For example, the material of the charge generation layer 129 may be the same as that of the electron transport layer. For example, the material of the electron transport layer may include aromatic heterocyclic compounds, such as benzimidazole derivatives, imidazopyridine derivatives, benziimidazophenanthridine derivatives and other imidazole derivatives; azine derivatives such as pyrimidine derivatives and triazine derivatives; compounds containing a nitrogen-containing six-membered ring structure such as quinoline derivatives, isoquinoline derivatives, and phenanthroline derivatives (compounds having a phosphine oxide-based substituent on the heterocyclic ring are also included).

For example, the material of the charge generation layer 129 may be a material containing a phosphorus oxygen group or a material containing a triazine.

For example, in a case that there is no isolation structure 140 arranged between the two adjacent sub-pixels 200, the common layers such as the charge generation layer 129 in the light-emitting functional layer 120 of the two adjacent sub-pixels 200 may be connected or may be an entire film layer, for example, the charge generation layer 129 has higher conductivity, for a display device with high resolution, the high conductivity of the charge generation layer 129 easily causes crosstalk among adjacent sub-pixels 200.

In the display substrate provided by the embodiment of the present disclosure, by arranging an isolation structure with an isolation protruding part between the two adjacent sub-pixels, at least one layer of the light-emitting functional layer formed at the isolation protruding part can be disconnected, at this time, at least one film layer (such as a charge generation layer) in the light-emitting functional layer of the two adjacent sub-pixels is arranged at intervals, resistance of the light-emitting functional layer between adjacent sub-pixels can be increased, therefore, while reducing the probability of crosstalk among the two adjacent sub-pixels, the normal display of the sub-pixels is not affected.

For example, as illustrated by FIG. 15, a material of the second sub-isolation structure 742 may include any one or more of silicon nitride, silicon oxide, or silicon oxynitride.

For example, as illustrated by FIG. 15, the second electrode 132 in the plurality of sub-pixels 200 may be a common electrode shared by the plurality of sub-pixels 200, in a case that there is no isolation structure 140 arranged between the two adjacent sub-pixels 200, the second electrode 132 is an entire film layer.

For example, as illustrated by FIG. 15, a size of the isolation protruding part 7420 may be in the range of 0.1 microns to 5 microns. For example, the size of the isolation protruding part 7420 may be in the range of 0.2 microns to 2 microns.

For example, as illustrated by FIG. 15, along the direction perpendicular to the base substrate 110, a ratio of a thickness of the isolation structure 140 to a thickness of the light-emitting functional layer 120 is from 0.8 to 1.2. For example, the ratio of the thickness of the isolation structure 140 to the thickness of the light-emitting functional layer 120 is from 0.9 to 1.1. For example, along the direction perpendicular to the base substrate 110, the thickness of the second sub-isolation structure 742 may be from 100 Å to 10,000 Å. For example, the thickness of the second sub-isolation structure 742 may be from 200 A to 1500 Å. For example, along the direction perpendicular to the base substrate 110, the thickness of the first sub-isolation structure 741 may be from 100 Å to 10,000 Å. For example, the thickness of the first sub-isolation structure 741 may be from 200 Å to 2000 Å. An example of the embodiment of the present disclosure can be set by setting the thickness of the isolation structure, for example, the ratio of the thickness of the isolation structure to the thickness of the light-emitting functional layer is set to from 0.8 to 1.2, so that the light-emitting functional layer 120 is disconnected at the isolation protruding part 7420 of the isolation structure 140, while the second electrode 132 remains continuous and not interrupted, so that this prevents crosstalk among adjacent sub-pixels, and at the same time, the second electrode is not blocked and ensure display uniformity.

For example, the thickness of the isolation structure 140 may be from 300 Å to 5000 Å, the above-mentioned thickness (from 300 Å to 5000 Å) of the isolation structure 140 can cause the light-emitting functional layer 120 to be inevitably disconnected at an edge of the isolation structure, and whether the second electrode 132 is disconnected is further determined according to the thickness of the isolation structure 140.

In the embodiments of the present disclosure, by setting the thickness of the isolation structure and the size of the isolation protruding part, at least one film layer of the light-emitting functional layer can be disconnected at the isolation protruding part.

FIG. 16 is a partial cross-sectional structural schematic diagram of a display substrate provided according to another example of an embodiment of the present disclosure. The difference between the display substrate in the example shown in FIG. 16 and the display substrate in the example shown in FIG. 15 is that the thicknesses of the isolation structures are different, the thickness of the isolation structure 140 in the display substrate shown in FIG. 16 is greater than the thickness of the isolation structure 140 in the display substrate shown in FIG. 15, for example, as illustrated by FIG. 16, by setting the thickness of the isolation structure 140 larger (for example, the ratio of the thickness of the isolation structure to the thickness of the light-emitting functional layer is greater than 1.5), so that both the light-emitting functional layer and the second electrode are disconnected at the isolation protruding part of the isolation structure.

For example, FIG. 15 schematically shows that all film layers included in the light-emitting functional layer 120 are disconnected at the isolation protruding part parts 7420 of the isolation structure 140, the second electrode 132 is not disconnected at the isolation protruding prat 7420 of the isolation structure 140. But it is not limited thereto, in other examples, the thickness of the isolation structure can be set, so that a part of the film layer on a side of the light-emitting functional layer close to the base substrate is disconnected at the isolation protruding part, the part of the film layer on the side of the light-emitting functional layer away from the base substrate is not disconnected at the isolation protruding part, and the second electrode is not disconnected at the isolation protruding part.

For example, as illustrated by FIG. 15, a material of the first sub-isolation structure 741 includes organic material.

For example, as illustrated by FIG. 15, the display substrate further includes an organic layer 180, which is located between the second sub-isolation structure 742 and the base substrate 110. The organic layer 180 may serve as a planarization layer.

For example, as illustrated by FIG. 15, the first sub-isolation structure 741 and the organic layer 180 are integrated structures. For example, the first sub-isolation structure 741 may be apart of the organic layer 180. For example, the first sub-isolation structure 741 may be a part of the organic layer 180 that protrudes toward a side away from the base substrate 110.

For example, as illustrated by FIG. 15, the organic layer 180 includes a planarization (PLN) layer. For example, a material of the first sub-isolation structure 741 includes photoresist, polyimide (PI) resin, acrylic resin, silicon compound or polyacrylic resin.

For example, as illustrated by FIG. 15, a first cross section of the first sub-isolation structure 741 taken along the arrangement direction of adjacent sub-pixels 200 and perpendicular to a plane of the base substrate 110 includes a rectangular shape. For example, the first cross section of the first sub-isolation structure 741 taken along the arrangement direction of the adjacent sub-pixels 200 and perpendicular to the plane of the base substrate 110 includes a trapezoid, and an angle between a side of the trapezoid and a bottom of a side of the trapezoid close to the base substrate 110 is not greater than 90 degrees.

For example, as illustrated by FIG. 15, the cross section of the first sub-isolation structure 741 may be a trapezoid, an upper bottom of the trapezoid is located on a side of a lower bottom of the trapezoid away from the base substrate 110, angles between sides of the trapezoid and the bottom are no greater than 90 degrees.

For example, as illustrated by FIG. 15, a length of the upper bottom of the trapezoidal cross-section of the first sub-isolation structure 741 is smaller than a length of the side of the cross-section of the second sub-isolation structure 742 close to the base substrate 110, so that an edge of the second sub-isolation structure 742 and an edge of the upper bottom of the first sub-isolation structure 741 form an undercut structure, that is, the edge of the second sub-isolation structure 742 includes the isolation protruding part 7420.

FIG. 15 schematically shows that a side of the first sub-isolation structure 741 is a straight side, but is not limited thereto. In an actual process, the side of the formed first sub-isolation structure 741 may also be a curved edge. For example, the curved edge is bent toward a side away from a center of the first sub-isolation structure 741 where the curved edge is located, or the curved edge is bent toward a side close to the center of the first sub-isolation structure 741 where the curved edge is located, at this time, an angle between the curved edge and the lower bottom of the first sub-isolation structure 741 may refer to an angle between a tangent line at a midpoint of the curved edge and the lower bottom, can also refer to an angle between a tangent line at an intersection point of the curved edge and the lower bottom and the lower bottom.

For example, as illustrated by FIG. 15, a second cross-section of the second sub-isolation structure 742 taken along the arrangement direction of the adjacent sub-pixels 200 and perpendicular to the plane of the base substrate 110 includes a rectangle or a trapezoid. For example, FIG. 15 schematically shows that a shape of the second cross-section of the second sub-isolation structure 742 is a rectangle, by setting a short side of the second section of the second sub-isolation structure 742, so that an angle between the short side and the long side of the side close to the base substrate 110 is a right angle or a substantially right angle (for example, a roughly right angle can mean that angle difference between the two sides and 90 degrees is no more than 10 degrees), which may be advantageous for the light-emitting functional layer 120 to be disconnected at an edge of the second sub-isolation structure 742.

For example, the shape of the second cross-section of the second sub-isolation structure 742 taken along the arrangement direction of adjacent sub-pixels and perpendicular to the plane of the base substrate 110 may be a trapezoid, an angle between a side of the trapezoid and a bottom edge of a side of the trapezoid away from the base substrate 110 is not less than 70 degrees. In the embodiment of the present disclosure, by setting an angle between a side of the second sub-isolation structure 742 and the bottom edge of the trapezoid on the side away from the base substrate, so that the light-emitting functional layer 120 is disconnected at the edge of the second sub-isolation structure 742.

For example, the shape of the second cross-section of the second sub-isolation structure 742 may be a trapezoid, a length of a bottom of the trapezoid on a side away from the base substrate 110 is shorter than a length of a bottom of the trapezoid on a side close to the base substrate 110.

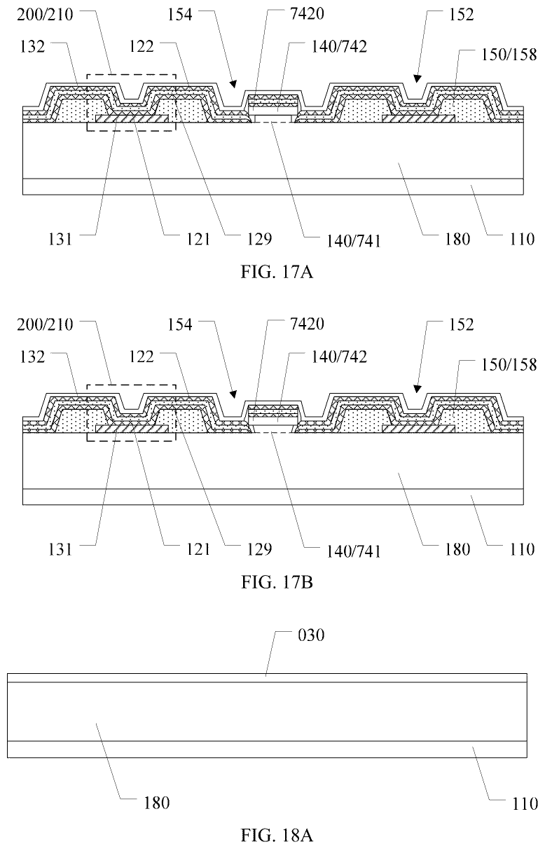

FIG. 17A is a partial cross-sectional structural schematic diagram of a display substrate provided according to another example of an embodiment of the present disclosure. Difference between the display substrate shown in FIG. 17A and the display substrate shown in FIG. 15 is that shapes of first cross-sections taken along the arrangement direction of adjacent sub-pixels 200 and perpendicular to the base substrate 110 of the first sub-isolation structure 741 are different. For example, as illustrated by FIG. 17A, the shape of the first cross section of the first sub-isolation structure 741 taken by a plane perpendicular to the base substrate 110 may be a rectangle, the shape of the first cross-section of the second sub-isolation structure 742 taken by a plane perpendicular to the base substrate 110 is also a rectangle, which may be advantageous for the light-emitting functional layer 120 to be disconnected at the edge of the isolation structure 140.

FIG. 17B is a partial cross-sectional structural schematic diagram of a display substrate provided according to still another example of an embodiment of the present disclosure. Difference between the display substrate shown in FIG. 17B and the display substrate shown in FIG. 17A is that shapes of first cross-sections taken along the arrangement direction of adjacent sub-pixels 200 and perpendicular to the base substrate 110 of the first sub-isolation structure 741 are different. For example, as illustrated by FIG. 17B, the shape of the first cross section of the first sub-isolation structure 741 taken by a plane perpendicular to the base substrate 110 may be a trapezoid, and a length of the bottom of the trapezoid away from the base substrate 110 is greater than a length of the bottom of the trapezoid close to the base substrate 110, which may be advantageous for the light-emitting functional layer 120 to be disconnected at the edge of the isolation structure 140.

For example, as illustrated by FIGS. 15 to 17B, the first electrodes 131 are in contact with a surface of the organic layer 180 away from the base substrate 110. For example, the first electrodes 131 may be an anode, and the second electrode 132 may be a cathode. For example, the cathode may be formed from a material with high conductivity and low work function, for example, the cathode may be made of metallic material. For example, the anode may be formed from a transparent conductive material with a high work function.

For example, as illustrated by FIGS. 15 to 17B, the display substrate further includes a pixel defining layer 150, which is located on a side of the organic layer 180 away from the base substrate 110, the pixel defining layer 150 includes a plurality of first openings 152, and the pixel defining layer 150 includes a plurality of first openings 152. The plurality of first openings 152 are arranged in one-to-one correspondence with the plurality of sub-pixels 200 to define light-emitting areas of the plurality of sub-pixels 200, and the plurality of first openings 152 are configured to expose the first electrodes 131. For example, at least a part of the first electrodes 131 are located between the pixel defining layer 150 and the base substrate 110. For example, in a case that the light emitting function layer 120 is formed in the first opening 152 of the pixel defining layer 150, the first electrodes 131 and the second electrode 132 located on two sides of the light-emitting functional layer 120 respectively can drive the light-emitting functional layer 120 in the plurality of first openings 152 to emit light. For example, the above-mentioned light-emitting areas may refer to the regions where the sub-pixel effectively emits light, shapes of the light-emitting areas refer to a two-dimensional shape, for example, the shapes of the light-emitting areas may be the same as the shapes of the first openings 152 of the pixel defining layer 150.

For example, as illustrated by FIGS. 15 to 17B, the part of the pixel defining layer 150 except the first openings 152 are a pixel defining part, material of the pixel defining part may include polyimide, acrylic or polyethylene terephthalate, etc.

For example, as illustrated by FIGS. 15 to 17B, the pixel defining layer 150 further includes a plurality of second openings 154, the plurality of second openings 154 are configured to expose the isolation structure 140. For example, a gap is arranged between the isolation structure 140 and the pixel defining part of the pixel defining layer 150.

For example, as illustrated by FIGS. 15 to 17B, the second sub-isolation structure 742 includes at least one isolation layer. For example, the second sub-isolation structure 742 may include a single layer of isolation layers, and material of the single-layer film layer can be silicon oxide or silicon nitride. For example, the second sub-isolation structure 742 may include two layers of isolation layers, materials of the two-layer isolation layers are silicon oxide and silicon nitride respectively. The embodiments of the present disclosure are not limited thereto, the second sub-isolation structure may include three or more layers of isolation layers, and the number of isolation layers included in the second sub-isolation structure may be set according to product requirements.

For example, as illustrated by FIGS. 15 to 17B, along the direction perpendicular to the base substrate 110, the thickness of the isolation structure 140 is smaller than the thickness of the pixel defining part.

For example, as illustrated by FIGS. 15 to 17B, along a direction parallel to the base substrate 110, a size of the isolation protruding part 7420 is not less than 0.01 microns. For example, along the direction parallel to the base substrate 110, the size of the isolation protruding part 7420 is not less than 0.1 micron. For example, along the direction parallel to the base substrate 110, the size of the isolation protruding part 7420 may be from 0.01 microns to 5 microns. For example, along the direction parallel to the base substrate 110, the size of the isolation protruding part 7420 may be from 0.05 microns to 4 microns. For example, along the direction parallel to the base substrate 110, the size of the isolation protruding part 7420 may be from 0.1 microns to 2 microns.

For example, as illustrated by FIGS. 15 to 17B, a second cross section of the second sub-isolation structure 742 taken along the arrangement direction of adjacent sub-pixels 200 and perpendicular to the plane of the base substrate 110 includes a rectangle or a trapezoid. For example, the second cross-sectional shape of the second sub-isolation structure 742 is a rectangle, by arranging a short side of the second section of the second sub-isolation structure 742 to form a right angle or substantially a right angle with a long side on the side close to the base substrate 110 (for example, a roughly right angle can mean that the angle difference between the two sides and 90 degrees is no more than 10 degrees), which may be advantageous for the light-emitting functional layer 120 to be disconnected at an edge of the second sub-isolation structure 742.

For example, the second cross section of the second sub-isolation structure 742 may be a trapezoid, and an angle between a side of the trapezoid and a bottom of the trapezoid on a side close to the base substrate 110 is not less than 70 degrees. For example, the second cross-section may be a trapezoid, an angle between a side of the trapezoid and a bottom of a side of the trapezoid close to the base substrate 110 is not less than 90 degrees, so that an angle between a side of the second sub-isolation structure 742 and a bottom of the trapezoid on a side away from the base substrate 110 is an acute angle, which may be advantageous for the light-emitting functional layer 120 to be disconnected at an edge of the second sub-isolation structure 742.

For example, the display substrate also includes pixel circuits, a first electrode 131 of the organic light-emitting element 210 may be connected with one of a source electrode and a drain electrode of a thin film transistor in a pixel circuit through a via hole penetrating a organic layer 180 and other film layers. For example, the pixel circuit also includes a storage capacitor. For example, a gate insulation layer, an interlayer insulation layer, various film layers in the pixel circuit, data lines, gate lines, power signal lines, reset power signal lines, reset control signal lines, light-emitting control signal lines and other film layers or structures may be arranged between the organic layer 180 and the base substrate 110. For example, film layers between the organic layer 180 and the base substrate 110 may include one layer of power signal lines, or may include two layers of power signal lines. For example, a side surface of the organic layer 180 facing the base substrate 110 may be in contact with the interlayer insulating layer.

For example, a spacer may be arranged on a side of the pixel defining part of the pixel defining layer 150 away from the base substrate 110, and the spacer is configured to support an evaporation mask for manufacturing the light-emitting layer.

For example, an embodiment of the present disclosure provides a manufacturing method for forming the display substrate shown in FIG. 15, which includes forming a plurality of sub-pixels 200 on the base substrate 110, in which forming the sub-pixel 200 includes sequentially forming a first electrode 131, a light-emitting functional layer 120 and a second electrode 132 that are stacked in a direction perpendicular to the base substrate 110; forming a first material layer on the base substrate 110; forming a second material layer on the first material layer, in which the second material layer is an inorganic non-metallic material layer; simultaneously patterning the first material layer and the second material layer to form the isolation structure 140. The forming the isolation structure 140 includes patterning a second material layer to form the second sub-isolation structure 742, at the same time, etching a part of the first material layer located directly below the second sub-isolation structure 742 to form the first sub-isolation structure 741; along the arrangement direction of adjacent sub-pixels 200, protruding an edge of the second sub-isolation structure 742 in the isolation structure 140 between the adjacent sub-pixels 200 relative to an edge of the first sub-isolation structure 741 to form an isolation protruding part 7420; forming the light-emitting functional layer 120 after forming the isolation structure 140, in which the light-emitting functional layer 120 includes a plurality of film layers, and at least one of the plurality of film layers is interrupted at the isolation protruding part 7420.

For example, the second material layer is an organic material layer, the simultaneously patterning the first material layer and the second material layer to form an isolation structure 140 includes: using a dry etching method to etch the second material layer to form a second sub-isolation structure 742, at the same time, dry etching a part of the organic material layer directly below the second sub-isolation structure 742 to form a first sub-isolation structure 741.

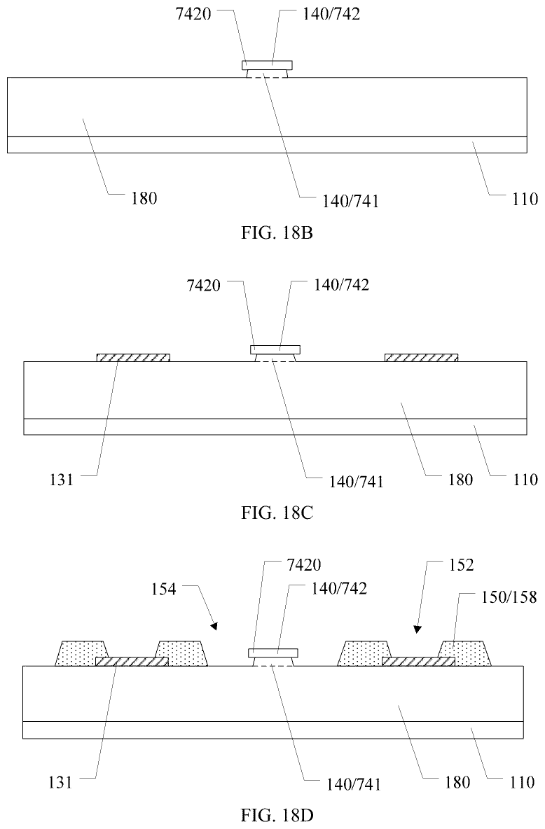

FIGS. 18A to 18D are flow schematic diagrams of a manufacturing method of the display substrate before forming the display substrate shown in FIG. 15. As illustrated by FIG. 15, FIG. 18A to FIG. 18D, the manufacturing method of the display substrate includes: forming a plurality of sub-pixels 200 on the base substrate 110, in which forming the sub-pixel 200 includes sequentially forming a first electrode 131, a light-emitting functional layer 120 and a second electrode 132 that are stacked in a direction perpendicular to the base substrate 110; forming an organic material layer 180 (that is, a first material layer) on the base substrate 110; forming an inorganic non-metal material layer 030 (that is, a second material layer) on the organic material layer 180; patterning the inorganic non-metallic material layer 030 to form a second sub-isolation structure 742, at the same time, etching a part of the organic material layer 180 directly below the second sub-isolation structure 742 to form a first sub-isolation structure 741. The isolation structure 140 includes a first sub-isolation structure 741 and a second sub-isolation structure 742, along the arrangement direction of adjacent sub-pixels 200, an edge of the second sub-isolation structure 742 in the isolation structure 140 between the adjacent sub-pixels 200 protrudes relative to an edge of the first sub-isolation structure 741 to form an isolation protruding part 7420; the light-emitting functional layer 120 is formed after forming the isolation structure 140, the light-emitting functional layer 120 includes a plurality of film layers, and at least one of the plurality of film layers is disconnected at the isolation protruding part 7420.

For example, as illustrated by FIGS. 15 and 18A, the manufacturing method of a display substrate may include manufacturing a base substrate 110 on a glass carrier. For example, the base substrate 110 may be a flexible base substrate. For example, forming the base substrate 110 may include sequentially forming a first flexible material layer, a first inorganic material layer, a semiconductor layer, a second flexible material layer, and a second inorganic material layer that are stacked on a glass carrier. The first flexible material layer and the second flexible material layer are made of materials such as polyimide (PI), polyethylene terephthalate (PET) or surface-treated polymer soft film. The first inorganic material layer and the second inorganic material layer are made of silicon nitride (SiNx) or silicon oxide (SiOx), which is used to improve water and oxygen resistance of the base substrate, and the first inorganic material layer and the second inorganic material layer are also called barrier layers.

For example, before forming an organic material layer 020, a driving structure layer of the pixel circuit may be formed on the base substrate 110. The driving structure layer includes a plurality of pixel circuits, each of the plurality of pixel circuits includes a plurality of transistors and at least one storage capacitor, for example, the pixel circuit can adopt 2T1C, 3T1C or 7T1C design. For example, the forming the driving structure layer may include sequentially depositing a first insulating film and an active layer film on the base substrate 110, by patterning the active layer film through a patterning process, forming a first insulating layer covering the entire base substrate 110, and an active layer pattern arranged on the first insulating layer, the active layer pattern at least includes an active layer. For example, depositing the second insulating film and the first metal film in sequence, patterning the first metal film through a patterning process, and forming a second insulating layer covering the active layer pattern, and a first gate metal layer pattern arranged on the second insulating layer, in which the first gate metal layer pattern at least includes a gate electrode and a first capacitor electrode. For example, depositing a third insulating film and a second metal film in sequence, patterning the second metal film through a patterning process, and forming a third insulating layer covering the first gate metal layer, and a second gate metal layer pattern arranged on the third insulating layer, in which the second gate metal layer pattern at least includes a second capacitor electrode, a position of the second capacitor electrode corresponds to a position of the first capacitor electrode. Subsequently, depositing a fourth insulating film, patterning the fourth insulating film through a patterning process, forming a fourth insulating layer covering the second gate metal layer, opening at least two first via holes on the fourth insulation layer, etching away the fourth insulating layer, the third insulating layer and the second insulating layer in the two first via holes, and exposing the surface of the active layer of the active layer pattern. Subsequently, depositing a third metal film, patterning the third metal film through a patterning process, and forming a source-drain metal layer pattern on the fourth insulating layer, in which the source-drain metal layer pattern at least includes a source electrode and a drain electrode located in the display region. The source electrode and the drain electrode may be connected with the active layer in the active layer pattern through the first via holes respectively.

For example, the first insulating layer, the second insulating layer, the third insulating layer and the fourth insulating layer may be made of any one or more of silicon oxide (SiOx), silicon nitride (SiNx) and silicon oxynitride (SiON), which can be a single layer, multi-layer or composite layer. The first insulating layer may be a buffer layer, which is used to improve the water and oxygen resistance of the base substrate 110; the second insulating layer and the third insulating layer may be gate insulating (GI, Gate Insulator) layers; the fourth insulation layer may be an interlayer insulation (ILD, Interlayer Dielectric) layer. The first metal film, the second metal film and the third metal film are made of metal materials, such as any one or more of silver (Ag), copper (Cu), aluminum (Al), titanium (Ti) and molybdenum (Mo), or alloy materials of the above metals, such as aluminum-neodymium alloy (AlNd) or molybdenum-niobium alloy (MoNb), which can be a single-layer structure or a multi-layer composite structure, such as Ti/Al/Ti, etc. The active layer film uses one or more materials such as amorphous indium gallium zinc oxide material (a-IGZO), zinc oxynitride (ZnON), indium zinc tin oxide (IZTO), amorphous silicon (a-Si), polycrystalline silicon (p-Si), hexathiophene, and polythiophene, that is, the present disclosure is applicable to transistors manufactured based on oxide technology, silicon technology, and organic technology.

For example, as illustrated by FIG. 18A and FIG. 18B, after forming an inorganic non-metal material layer 030, the inorganic non-metal material layer 030 is patterned. For example, the patterning the inorganic non-metallic material layer 030 includes etching the inorganic non-metallic material layer 030 using a dry etching method to form a second sub-isolation structure 742, at the same time, a part of the organic material layer 020 directly below the second sub-isolation structure 742 is dry etched to form a first sub-isolation structure 741. For example, a mask may be used to shield the inorganic non-metallic material layer 030 at the position where the second sub-isolation structure 742 is to be formed, so that the inorganic non-metallic material layer 030 at other locations than the position where the second sub-isolation structure 742 is to be formed is etched, during the dry etching process of the inorganic non-metallic material layer 030, the etching gas will etch the part of the organic material layer 020 that is not blocked by the mask, so that an organic material layer with a certain thickness (that is, the first sub-isolation structure 741) remains directly below the inorganic non-metallic material layer (that is, the second sub-isolation structure 742) retained after etching, a side of the organic material layer 020 away from the base substrate 110 forms a protruding part located directly below the second sub-isolation structure 742, and this protruding part is the first sub-isolation structure 741.

For example, as illustrated by FIG. 18A and FIG. 18B, during the dry etching process of the inorganic non-metallic material layer 030, etched thickness of the organic material layer 020 may be from 100 Å to 10000 Å, then the thickness of the formed first sub-isolation structure 741 may be from 100 Å to 10000 Å. For example, during the dry etching process of the inorganic non-metal material layer 030, the etched thickness of the organic material layer 020 can be from 200 Å to 2000 Å, then the thickness of the first sub-isolation structure 741 formed may be from 200 Å to 2000 Å.

For example, as illustrated by FIG. 15 and FIG. 18C, after forming the isolation structure 140, the first electrode 131 of the sub-pixel on the planarization layer 180 is patterned. For example, the first electrode 131 is connected with the drain electrode of the transistor through a second via hole in the planarization layer 180.

For example, the first electrode 131 may be made of a metal material, such as any one or more of magnesium (Mg), silver (Ag), copper (Cu), aluminum (Al), titanium (Ti), and molybdenum (Mo), or alloy materials of the above metals, such as aluminum-neodymium alloy (AlNd) or molybdenum-niobium alloy (MoNb), which can be a single-layer structure or a multi-layer composite structure, such as Ti/Al/Ti, or the first electrode 131 is a stack structure formed by metal and transparent conductive materials, such as reflective materials such as ITO/Ag/ITO, Mo/AlNd/ITO.

For example, as illustrated by FIGS. 15 and 18D, after the first electrode 131 is formed, the pixel defining layer 150 may be formed. For example, as illustrated by FIGS. 15 and 18D, after the first electrode 131 is formed, the pixel defining layer 150 may be formed. For example, the pixel defining layer 150 of the display area includes a plurality of pixel defining parts 158, a first opening 152 or a second opening 154 is formed between adjacent pixel defining parts 401, a pixel defining film in the first opening 152 and the second opening 154 is developed, the first opening 152 exposes at least a part of the surface of the first electrodes 131 of the plurality of sub-pixels, and the second opening 154 exposes the isolation structure 140.

For example, after forming the pixel defining layer 150, spacers may be formed on the pixel defining part. For example, a thin film of organic material is coated on the base substrate 110 on which the foregoing pattern is formed, and spacers are formed through masking, exposure, and development processes. The spacer can serve as a support layer configured to support the FMM (fine metal mask) during the evaporation process.

For example, as illustrated by FIG. 15, after forming the spacers, sequentially forming a light-emitting functional layer 120 and a second electrode 132. For example, one of the second electrode 132 may be a transparent cathode. The light-emitting functional layer 120 can emit light from a side away from the base substrate 110 through the transparent cathode, to achieve top emission. For example, the second electrode 132 may be made of any one or more of magnesium (Mg), silver (Ag), and aluminum (Al), or may adopt alloys made of any one or more of the above metals, or may adopt transparent conductive materials, such as indium tin oxide (ITO), or may adopt a multi-layer composite structure of metal and transparent conductive materials.

For example, forming the light-emitting functional layer 120 may include: using an open mask to sequentially evaporate to form a hole injection layer and a hole transport layer; using FMM to sequentially evaporate to form first light-emitting layers 131 that emit light of different colors, such as a blue light-emitting layer, a green light-emitting layer and a red light-emitting layer; using an open mask to sequentially evaporate to form an electron transport layer, a charge generation layer 133, and a hole transport layer; using FMM to sequentially evaporate to form second light-emitting layers 132 that emit light of different colors, such as a blue light-emitting layer, a green light-emitting layer and a red light-emitting layer; and using an open mask to sequentially evaporate to form an electron transport layer, a second electrode and an light coupling layer. For example, the hole injection layer, the hole transport layer, the electron transport layer, the charge generation layer, the second electrode and the light coupling layer are all common layers of multiple sub-pixels.

For example, as illustrated by FIG. 15, the formed light-emitting functional layer 120 will be disconnected at the isolation protruding part 7420 of the isolation structure 140, so that a part of the light-emitting functional layer 120 located in the second opening 154 of the pixel defining layer 150 is located on the isolation structure 140, and the other part is located on the organic layer 180.

For example, after forming the second electrode 132, the manufacturing method of the display substrate further includes forming an encapsulation layer, the encapsulation layer may include a first encapsulation layer, a second encapsulation layer and a third encapsulation layer that are stacked. The first encapsulation layer is made of inorganic material and covers the second electrode 132 in the display region. The second encapsulation layer adopts organic materials. The third encapsulation layer is made of inorganic material and covers the first encapsulation layer and the second encapsulation layer. However, this embodiment is not limited thereto. For example, the encapsulation layer may also adopt a five-layer structure of inorganic/organic/inorganic/organic/inorganic.

For example, compared to a display substrate without an isolation structure, the display substrate with the isolation structure provided by the embodiment of the present disclosure only adds one mask process, which has a low impact on the process productivity.

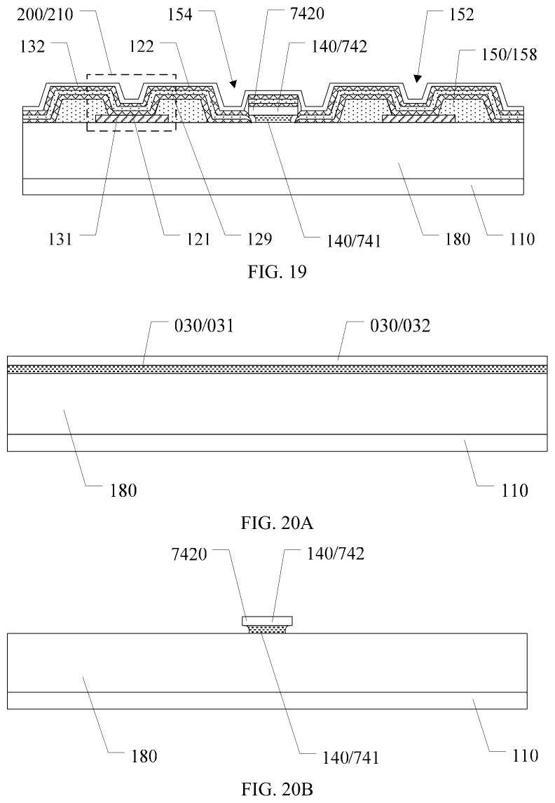

FIG. 19 is a partial cross-sectional structural schematic diagram of a display substrate according to another example of an embodiment of the present disclosure. The display substrate in the example shown in FIG. 19 is different from the display substrate in the example shown in FIG. 15 in that the material of the first sub-isolation structure 741 in the display substrate shown in FIG. 19 includes inorganic non-metallic materials. The sub-pixel 200, the base substrate 110 and the pixel definition layer 150 in the display substrate shown in FIG. 19 may have same features as the sub-pixels 200, the base substrate 110 and the pixel defining layer 150 in the display substrate in any example shown in FIGS. 15 to 17B, which will not be described again.

For example, as illustrated by FIG. 19, the material of the first sub-isolation structure 741 is different from the material of the second sub-isolation structure 742. For example, the material of the second sub-isolation structure 742 may include any one or more of silicon nitride, silicon oxide, or silicon oxynitride, the material of the first sub-isolation structure 741 may also include any one or more of silicon nitride, silicon oxide, or silicon oxynitride, and the material of the first sub-isolation structure 741 is different from the material of the second sub-isolation structure 742.

For example, as illustrated by FIG. 19, the plurality of sub-pixels 200 may include two adjacent sub-pixels 200 arranged along an arrangement direction of adjacent sub-pixels. for example, at least one edge of the second sub-isolation structure 742 protrudes relative to a corresponding edge of the first sub-isolation structure 741 to form at least one isolation protruding part 7420. For example, as illustrated by FIG. 23, both side edges of the second sub-isolation structure 742 protrude relative to the corresponding edges of the first sub-isolation structure 741 to form two isolation protruding parts 7420. For example, two isolation protruding parts 7420 are arranged along the arrangement direction of adjacent sub-pixels.

For example, FIG. 19 schematically shows that one isolation structure 140 is arranged between two adjacent sub-pixels 200, the isolation structure 140 includes two isolation protruding parts 7420, but is not limited thereto, two or more isolation structures can also be arranged between two adjacent sub-pixels, each of the isolation structures includes at least one isolation protruding part, by setting a number of isolation structures and a number of isolation protruding parts, it is beneficial for at least one layer of the light-emitting functional layer to achieve a better disconnection effect.

For example, as illustrated by FIG. 19, an orthographic projection of a surface of the first sub-isolation structure 741 facing the second sub-isolation structure 742 on the base substrate 110 is completely located within an orthographic projection of a surface of the second sub-isolation structure 742 facing the base substrate 110 on the base substrate 110.

For example, as illustrated by FIG. 19, in the direction perpendicular to the base substrate 110, a thickness of the first sub-isolation structure 741 is greater than a thickness of the second sub-isolation structure 742.

For example, as illustrated by FIG. 19, in the direction perpendicular to the base substrate 110, and a thickness of the isolation structure 140 is smaller than a thickness of the pixel defining part 401. For example, a gap is arranged between the isolation structure 140 and the pixel defining part 401.

For example, as illustrated by FIG. 19, a surface of the organic layer 180 on the side away from the base substrate 110 exposed by the second opening 154 of the pixel defining layer 150 may be a planarization surface, that is, the surface of the organic layer 180 on the side away from the base substrate 110 does not include a protruding part.

For example, as illustrated by FIG. 19, the first sub-isolation structure 741 is arranged on the surface of the organic layer 180 away from the base substrate 110.

For example, as illustrated by FIG. 19, in the direction perpendicular to the base substrate 110, a thickness of the second sub-isolation structure 742 is no greater than a thickness of the light-emitting functional layer 120. For example, the thickness of the second sub-isolation structure 742 may be from 500 Å to 8000 Å.

For example, as illustrated by FIG. 19, along the direction perpendicular to the base substrate 110, a ratio of the thickness of the isolation structure 140 to the thickness of the light-emitting functional layer 120 is from 0.8 to 1.2. For example, the ratio of the thickness of the isolation structure 140 to the thickness of the light-emitting functional layer 120 is from 0.9 to 1.1. An example of the embodiment of the present disclosure can be set by setting the thickness of the isolation structure. For example, the ratio of the thickness of the isolation structure to the thickness of the light-emitting functional layer is set to from 0.8 to 1.2, so that the light-emitting functional layer 120 is disconnected at the isolation protruding part 7420 of the isolation structure 140, the second electrode 132 remain continuous without being interrupted, thus the second electrode 132 plays a role in preventing crosstalk among adjacent sub-pixels, at the same time, the second electrode is not blocked and the uniformity of the display is ensured.

For example, FIG. 19 schematically shows that all film layers included in the light-emitting functional layer 120 are disconnected at the isolation protruding parts 7420 of the isolation structure 140, but not limited thereto, it is also possible that a part of the film layer of the light-emitting functional layer 120 is disconnected at the isolation protruding part 7420 of the isolation structure 140, and the other part of the film layer is continuous at the isolation protruding part 7420. The film layer that is disconnected at the isolation protruding part 7420 can be regarded as a misaligned film layer, by misaligning the film layer at the isolation protruding part 7420, it is beneficial to reduce the lateral crosstalk of the film layer.

Of course, the example shown in FIG. 19 is not limited thereto; the thickness of the isolation structure can also be set to be greater than the thickness of the light-emitting functional layer, so that both the light-emitting functional layer and the second electrode are disconnected at an edge of the isolation structure.

For example, as illustrated by FIG. 19, a first cross section of the first sub-isolation structure 741 taken along an arrangement direction of adjacent sub-pixels 200 and perpendicular to the plane of the base substrate 110 includes a rectangle or a trapezoid. For example, the first cross section is a trapezoid, a length of a bottom of the trapezoid on a side away from the base substrate 110 is greater than a length of a bottom of the trapezoid on the side close to the base substrate 110. For example, an angle between the side of the trapezoid and the bottom of the side of the trapezoid close to the base substrate 110 is not less than 70 degrees. For example, along the direction parallel to the base substrate 110, a size of the isolation protruding part 7420 is not less than 0.01 micron. For example, along the direction parallel to the base substrate 110, the size of the isolation protruding part 7420 is not less than 0.1 micron.

For example, as illustrated by FIG. 19, the size of the isolation protruding part 7420 may be in the range of 0.01 microns to 5 microns. For example, the angle between the side of the trapezoid and the bottom of the side of the trapezoid close to the base substrate 110 is not less than 90 degrees. For example, the size of the isolation protruding part 7420 may be in the range of 0.1 microns to 2 microns.

For example, the side of the first sub-isolation structure 741 can be a straight side or a curved side. For example, the curved edge is bent toward a side close to the center of the first sub-isolation structure 741 where it is located, at this time, an angle between the curved edge of the first sub-isolation structure 741 and the bottom on the side close to the base substrate 110 may refer to an angle between the tangent line at the midpoint of the curved edge and the bottom, can also refer to an angle between the tangent line at the intersection point of the curved edge and the bottom and the bottom.

In the embodiments of the present disclosure, by setting the thickness of the isolation structure, the size of the isolation protruding part, and the side angle of the first sub-isolation structure, at least one film layer of the light-emitting functional layer can be disconnected at the isolation protruding part.

For example, as illustrated by FIG. 19, a second cross section of the second sub-isolation structure 742 taken along an arrangement direction of adjacent sub-pixels 200 and perpendicular to the plane of the base substrate 110 includes a rectangle or a trapezoid. For example, a shape of the second cross-sectional of the second sub-isolation structure 742 is a rectangle, by setting a short side of the second section of the second sub-isolation structure 742 so that an angle between the short side and a long side of the side close to the base substrate 110 is a right angle or a substantially right angle (for example, a roughly right angle can mean that the difference between the angle between the two sides and 90 degrees is no more than 10 degrees), it may be advantageous for the light-emitting functional layer 120 to be disconnected at the edge of the second sub-isolation structure 742.

For example, the second cross section of the second sub-isolation structure 742 may be a trapezoid, an angle between the side of the trapezoid and the bottom of the trapezoid on the side close to the base substrate 110 is not less than 70 degrees. For example, the second cross-section may be a trapezoid, the angle between the side of the trapezoid and the bottom of the side of the trapezoid close to the base substrate 110 is not less than 90 degrees, so that the angle between the side of the second sub-isolation structure 742 and the bottom of the trapezoid on the side away from the base substrate 110 is an acute angle, it may be advantageous for the light-emitting functional layer 120 to be disconnected at an edge of the second sub-isolation structure 742.

For example, FIG. 19 schematically shows that the first sub-isolation structure 741 includes a film layer, and the second sub-isolation structure 742 includes a film layer, but is not limited thereto, at least one of the first sub-isolation structure 741 and the second sub-isolation structure 742 may include a plurality of film layers, at least an edge of the second sub-isolation structure 742 protrudes relative to an edge of the first sub-isolation structure 741 to form an isolation protruding part for disconnecting at least one layer of the light-emitting functional layer.

In a case that a side angle of the isolation structure is relatively large (for example, an angle between the side of the first cross section and the bottom of the side close to the base substrate, and/or an angle between a side plate of the second cross section and the bottom edge of the side close to the base substrate), the thickness of the light-emitting functional layer deposited becomes thinner overall, and at least one film layer of the light-emitting functional layer located between adjacent sub-pixels is disconnected, so that the resistance of the film layer is increased, and crosstalk among adjacent sub-pixels is further reduced.

For example, one embodiment of the present disclosure provides a manufacturing method for forming the display substrate shown in FIG. 19, which includes forming a plurality of sub-pixels 200 on the base substrate 110, in which forming the sub-pixel 200 includes sequentially forming a stacked first electrode 131, a light-emitting functional layer 120 and a second electrode 132 in a direction perpendicular to the base substrate 110; forming a first material layer on the base substrate 110; forming a second material layer on the first material layer, and the second material layer is an inorganic non-metallic material layer; simultaneously patterning the first material layer and the second material layer to form an isolation structure 140. Forming the isolation structure 140 includes patterning the second material layer to form the second sub-isolation structure 742, and etching the part of the first material layer directly below the second sub-isolation structure 742 to form the first sub-isolation structure 741; along an arrangement direction of adjacent sub-pixels 200, the edge of the second sub-isolation structure 742 in the isolation structure 140 between the adjacent sub-pixels 200 protrudes relative to the edge of the first sub-isolation structure 741 to form an isolation protruding part 7420; a light-emitting functional layer 120 is formed after forming the isolation structure 140, the light-emitting functional layer 120 includes a plurality of film layers, and at least one of the plurality of film layers is interrupted at the isolation protruding part 7420.

For example, the second material layer is an inorganic material layer, and simultaneously patterning the first material layer and the second material layer to form the isolation structure 140 includes: using etching liquids with different etching selectivity ratios for the first material layer and the second material layer to simultaneously etch the first material layer and the second material layer, in which the etching selectivity ratio of the etching liquid to the first material layer is greater than the etching selectivity ratio of the etching liquid to the second material layer, so that the edge of the first sub-isolation structure 741 formed after the first material layer is etched is retracted relative to the edge of the second sub-isolation structure 742 formed after the second material layer is etched to form an undercut structure.

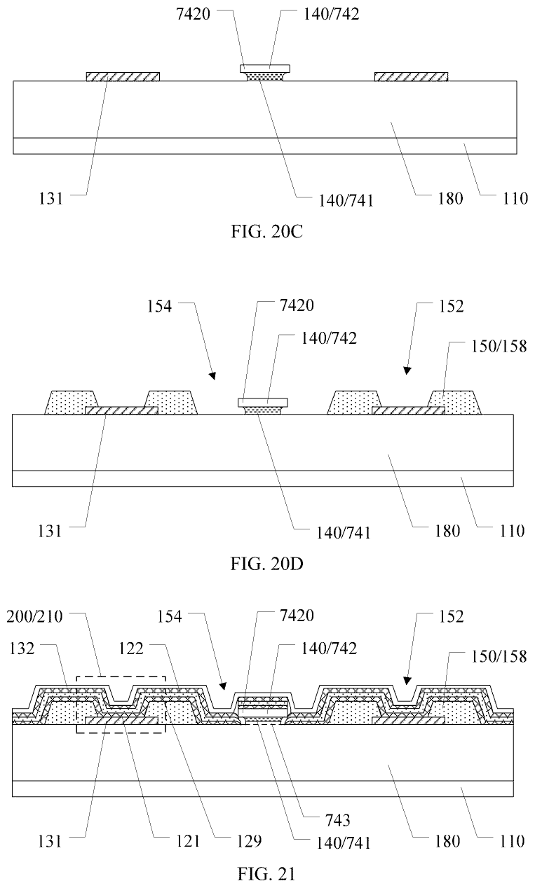

For example, FIGS. 20A to 20D are flow schematic diagrams of a manufacturing method of the display substrate before forming the display substrate shown in FIG. 19. As illustrated by FIG. 19, FIGS. 20A to 20D, the manufacturing method of the display substrate includes: forming a plurality of sub-pixels 200 on the base substrate 110, in which forming the sub-pixel 200 includes sequentially forming a stacked first electrode 131, a light-emitting functional layer 120 and a second electrode 132 in a direction perpendicular to the base substrate 110; forming an organic material layer 020 on the base substrate 110; forming an inorganic non-metallic material layer 030 on the organic material layer 020, and the inorganic non-metal material layer 030 includes at least two film layers, such as film layer 031 (that is, the first material layer) and film layer 032 (that is, the second material layer); patterning the inorganic non-metal material layer 030 to form the isolation structure 140. The isolation structure 140 includes a first sub-isolation structure 741 and a second sub-isolation structure 742, and the first sub-isolation structure 741 is located between the second sub-isolation structure 742 and the base substrate 110; along an arrangement direction of adjacent sub-pixels 200, an edge of the second sub-isolation structure 742 in the isolation structure 140 between the adjacent sub-pixels 200 protrudes relative to an edge of the first sub-isolation structure 741 to form an isolation protruding part 7420; the light-emitting functional layer 120 is formed after the isolation structure 140 is formed, the light-emitting functional layer 120 includes a plurality of film layers, and at least one of the plurality of film layers is disconnected at the isolation protruding part 7420.

For example, the manufacturing method for forming the base substrate 110, sub-pixels 200, and pixel defining layer 150 and other structures in the display substrate shown in FIG. 19 can be the same as the manufacturing method for forming the base substrate 110, the sub-pixel 200, the pixel defining layer 150 and other structures in the display substrate as illustrated by FIGS. 18A to 18D, which will not be described in detail herein.

For example, as illustrated by FIGS. 20A and 20B, after forming the inorganic non-metal material layer 030, patterning the inorganic non-metal material layer 030. For example, the inorganic non-metal material layer 030 may include two film layers, such as a first inorganic non-metal material layer 031 and a second inorganic non-metal material layer 032, patterning the inorganic non-metallic material layer 030 includes etching the two film layers included in the inorganic non-metallic material layer 030 using a wet etching process, an etching selectivity ratio of the etching liquid or etching gas to the first inorganic non-metal material layer 031 is greater than an etching selectivity ratio to the second inorganic non-metal material layer 032, so that an edge of the first sub-isolation structure 741 formed by etching the first inorganic non-metal material layer 031 is retracted relative to an edge of the second sub-isolation structure 742 formed by etching the second inorganic non-metal material layer 032, to form an undercut structure, that is, the isolation protruding part 7420 is formed.

For example, as illustrated by FIG. 20C, after forming the isolation structure 140, the first electrode 131 of the organic light-emitting element 210 of the sub-pixel is patterned on the planarization layer 180. The method and materials for forming the first electrode 131 in this example may be the same as the method and materials for forming the first electrode 131 shown in FIG. 18C, which will not be described in detail here.

For example, as illustrated by FIG. 20D, after forming the first electrode 131, the pixel defining layer 150 may be formed. The method and materials used to form the pixel defining layer 150 in this example may be the same as the method and materials used to form the pixel defining layer 150 shown in FIG. 18D, which will not be described in detail herein. For example, the steps after forming the pixel defining layer in this example may be the same as the steps after forming the pixel defining layer on the display substrate shown in FIG. 15, which will not be described in detail herein.

For example, FIG. 21 is a schematic diagram of a partial cross-sectional structure of a display substrate provided according to another example of an embodiment of the present disclosure. Difference between the display substrate in the example shown in FIG. 21 and the display substrate in the example shown in FIG. 19 is that the isolation structure 140 further includes a third sub-isolation structure 743. The sub-pixels 200, the base substrate 110 and the pixel defining layer 150 in the display substrate shown in FIG. 21 may have the same characteristics as the sub-pixel 200, the base substrate 110 and the pixel defining layer 150 in the display substrate in any example shown in FIGS. 15 to 17B and FIG. 19, which will not be described in detail herein. The material, shape and dimensional relationship of the first sub-isolation structure 741 and the second sub-isolation structure 742 in the display substrate shown in FIG. 21 may be the same as the material, shape and dimensional relationship between the first sub-isolation structure 741 and the second sub-isolation structure 742 in the display substrate shown in FIG. 5, which will not be described in detail herein.

For example, as illustrated by FIG. 21, the third sub-isolation structure 743 is located between the first sub-isolation structure 741 and the base substrate 110, along the arrangement direction of adjacent sub-pixels 200, in the isolation structure 140 located between the adjacent sub-pixels 200, an edge of the first sub-isolation structure 741 protrudes relative to an edge of the third sub-isolation structure 743, and the third sub-isolation structure 743 and the organic layer 180 are integrated structures.

For example, as illustrated by FIG. 21, the third sub-isolation structure 743 may be a part of the organic layer 180. For example, the third sub-isolation structure 743 may be a part of the organic layer 180 that protrudes toward a side away from the base substrate 110. For example, the first sub-isolation structure 741 may be located on a part of the organic layer 180 that protrudes away from the base substrate 110.

For example, as illustrated by FIG. 21, material of the third sub-isolation structure 743 includes photoresist, polyimide (PI) resin, acrylic resin, silicon compound or polyacrylic resin.

For example, as illustrated by FIG. 21, a thickness of the third sub-isolation structure 743 may be from 100 Å to 10,000 Å. For example, the thickness of the third sub-isolation structure 743 may be from 200 Å to 2000 Å.

For example, the cross section of the third sub-isolation structure 743 taken along the arrangement direction of the adjacent sub-pixels 200 and perpendicular to the plane of the base substrate 110 includes a rectangle. For example, the cross section of the third sub-isolation structure 743 taken along the arrangement direction of the adjacent sub-pixels 200 and perpendicular to the plane of the base substrate 110 includes a trapezoid, and an angle between the side of the trapezoid and the bottom of the side of the trapezoid close to the base substrate 110 is not greater than 90 degrees.

For example, as illustrated by FIG. 21, a length of the upper bottom of the trapezoidal cross-section of the third sub-isolation structure 743 is less than a length of the side of the cross-section of the first sub-isolation structure 741 close to the base substrate 110.

For example, the side of the third sub-isolation structure 743 can be a straight side or a curved side. For example, the curved edge is bent toward a side away from the center of the third sub-isolation structure 743 where it is located, or, the curved edge is bent toward a side close to the center of the third sub-isolation structure 743 where it is located, at this time, an angle between the curved edge of the third sub-isolation structure 743 and the lower bottom can refer to an angle between the tangent line at the midpoint of the curved edge and the lower bottom, can also refer to an angle between the tangent line at the intersection point of the curved edge and the lower base and the lower base.

For example, the difference between forming the isolation structure shown in FIG. 21 and forming the isolation structure shown in FIG. 19 is that: while dry etching is used to etch the inorganic non-metallic material layer 030 to form the first sub-isolation structure 741 and the second sub-isolation structure 742, a part of the organic material layer 180 located directly below the first sub-isolation structure 741 is dry etched to form a third sub-isolation structure 743. For example, a mask plate can be used to shield the inorganic non-metallic material layer 030 at the position where the first sub-isolation structure 741 and the second sub-isolation structure 742 are to be formed, so that the inorganic non-metallic material layer 030 at other locations than the locations where the first sub-isolation structure 741 and the second sub-isolation structure 742 are to be formed are etched, during the dry etching process of the inorganic non-metallic material layer 030, the etching gas will etch the part of the organic material layer 180 that is not blocked by the mask, so that an organic material layer with a certain thickness (that is, the third sub-isolation structure 743) remains directly below the inorganic non-metallic material layer (that is, the first sub-isolation structure 741 and the second sub-isolation structure 742) retained after etching, so that the side of the organic material layer 180 away from the base substrate 110 forms a protruding part located directly below the first sub-isolation structure 741 and the second sub-isolation structure 742, and the protruding part is the third sub-isolation structure 743. This example is not limited thereto, a wet etching process may also be used to form the first sub-isolation structure 741 and the second sub-isolation structure 742, then a dry etching process is used to form the third sub-isolation structure 743; alternatively, the first sub-isolation structure 741, the second sub-isolation structure 742 and the third sub-isolation structure 743 may be formed using a process of first dry etching and then wet etching.

For example, as illustrated by FIGS. 20A and 20B, during the dry etching process of the inorganic non-metal material layer 030, an etched thickness of the organic material layer 180 may be from 100 Å to 10,000 Å, then a thickness of the third sub-isolation structure 743 formed may be from 100 Å to 10000 Å. For example, during the dry etching process of the inorganic non-metal material layer 030, the etched thickness of the organic material layer 180 may be from 200 Å to 2000 Å, then the thickness of the third sub-isolation structure 743 formed may be from 200 Å to 2000 Å.

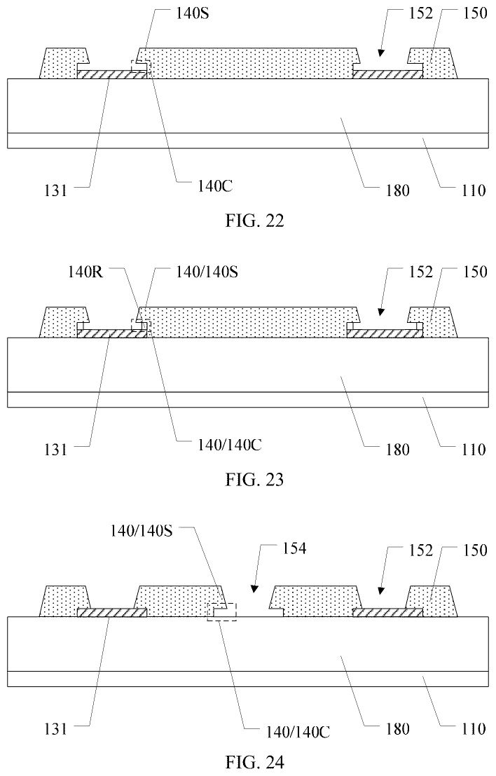

At least one embodiment of the present disclosure also provides a display substrate. FIG. 22 is a structural schematic diagram of still another display substrate provided by an embodiment of the present disclosure. As illustrated by FIG. 22, the display substrate 100 includes a base substrate 110 and a plurality of sub-pixels (not shown); the plurality of sub-pixels are located on the base substrate 110, and each of the plurality of sub-pixel includes a light-emitting element; each of the light-emitting elements includes a light-emitting functional layer and first electrodes 131 and a second electrode (not shown) located on two sides of the light-emitting functional layer respectively, the first electrodes 131 are located between the light-emitting functional layer and the base substrate 110; the second electrode is at least partially located on a side of the light-emitting functional layer away from the first electrodes 131. It should be noted that specific structures of sub-pixels, light-emitting elements and light-emitting functional layers can be seen in FIGS. 1 and 2, the present disclosure will not be repeated herein.

As illustrated by FIGS. 22, the display substrate 100 also includes a pixel isolation structure 140, the pixel isolation structure 140 is located on the base substrate 110 and between adjacent sub-pixels; at least one of the plurality of sub-functional film layers in the light-emitting functional layer is disconnected at the position where the pixel isolation structure 140 is located. The display substrate 100 further includes a pixel defining layer 150; the pixel defining layer 150 is partially located on a side of the first electrode 131 away from the base substrate 110; the pixel defining layer 150 includes a plurality of pixel openings 152; the plurality of pixel openings 152 correspond to the plurality of sub-pixels 200 one-to-one to define effective light-emitting areas of the plurality of sub-pixels 200; and the pixel opening 152 is configured to expose the first electrode 131, so that the first electrode 131 is in contact with the subsequently formed light-emitting functional layer 120.

As illustrated by FIG. 22, the pixel isolation structure 140 includes a concave structure 140C and a shielding part 140S, the concave structure 140C is located at an edge of a first electrodes 131 and is recessed toward the pixel defining layer 150, the shielding part 140S is located on a side of the concave structure 140C away from the base substrate 110 and is a part of the pixel defining layer 150. In this way, a conductive sub-layer of the light-emitting functional layer is disconnected at a position where the shielding part is located. In this way, by arranging the above-mentioned pixel isolation structure between adjacent sub-pixels, the display substrate can avoid crosstalk among adjacent sub-pixels caused by the highly conductive sub-functional layer in the light-emitting functional layer.

On the other hand, because the display substrate can avoid crosstalk among adjacent sub-pixels through the pixel isolation structure, the display substrate can increase pixel density while adopting a dual-layer light-emitting (Tandem EL) design. Therefore, the display substrate can have the advantages of long life, low power consumption, high brightness, and high resolution.

In some examples, as illustrated by FIG. 22, an orthographic projection of the concave structure 140C on the base substrate 110 is overlapped with an orthographic projection of the shielding part 140S on the base substrate 110.

FIG. 23 is a structural schematic diagram of still another display substrate provided by an embodiment of the present disclosure. As illustrated by FIG. 23, the concave structure 140C includes a residual structure 140R located at a position where the concave structure 140C is close to the pixel defining layer 150.

In some examples, as illustrated by FIG. 23, the material of the residual structure 140R includes metal, such as silver.

An embodiment of the present disclosure also provides a display substrate. FIG. 24 is a schematic structural diagram of still another display substrate according to an embodiment of the present disclosure. The display substrate shown in FIG. 24 provides another pixel isolation structure. As illustrated by FIG. 24, the display substrate 100 further includes a pixel defining layer 150 located on the base substrate 110; the pixel defining layer 150 is partially located on a side of the first electrode 131 away from the base substrate 110; the pixel defining layer 150 includes a plurality of pixel openings 152 and pixel spacing openings 154; the plurality of pixel openings 152 correspond to the plurality of sub-pixels 200 one-to-one to define effective light-emitting areas of the plurality of sub-pixels 200; the plurality of pixel openings 152 are configured to expose the first electrodes 131, so that the first electrodes 131 are in contact with the subsequently formed light-emitting functional layer 120. The pixel spacing openings 154 are located between adjacent first electrodes 131, and at least a part of the isolation structure 140 is located within one of the pixel spacing openings 154.

As illustrated by FIG. 24, the pixel isolation structure 140 includes a concave structure 140C and a shielding part 140S. The concave structure 140C is located at an edge of a pixel spacing opening 154 and is recessed toward the pixel defining layer 150. For example, the concave structure 140C may be recessed toward the pixel defining layer 150 in a direction parallel to the base substrate 110. The shielding part 140S is located on a side of the concave structure 140C away from the base substrate 110 and is a part of the pixel defining layer 150. In this way, a conductive sub-layer of the light-emitting functional layer is disconnected at the position where the shielding part is located. In this way, by arranging the above-mentioned pixel isolation structure between adjacent sub-pixels, the display substrate can avoid crosstalk among adjacent sub-pixels caused by the highly conductive sub-functional layer in the light-emitting functional layer.

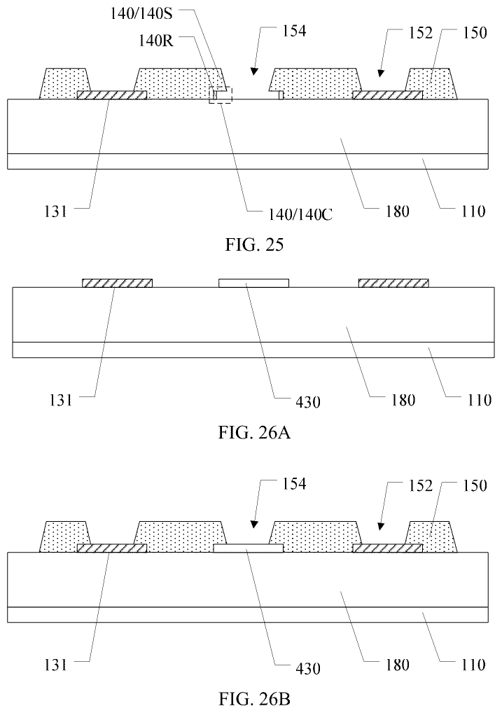

FIG. 25 is a structural schematic diagram of still another display substrate provided by an embodiment of the present disclosure. As illustrated by FIG. 25, the concave structure 140C includes a residual structure 140R located at a position where the concave structure 140C is close to the pixel defining layer 150.

In some examples, as illustrated by FIG. 25, the material of the residual structure 140R includes at least one of metal, metal oxide, and organic matter; the above-mentioned metal may be silver, the above-mentioned metal oxide may be indium zinc oxide, and the above-mentioned organic substance may be a fluorine-based polymer.

In some examples, in a case that the material of the residual structure 140 is a fluorine-based polymer, because the material of the planarization layer includes photoresist, polyimide (PI) resin, acrylic resin, silicon compound or polyacrylic resin, a solvent of the planarization layer uses non-fluorinated organic solvent as a main component, although these photoresists may contain small amounts of fluoride, they are not substantially soluble in fluorinated liquids or perfluorinated solvents, so their orthogonal properties can be exploited (solutions and solvents do not react with each other), and an etching process can be used to form the above-mentioned pixel isolation structure.

For example, the above-mentioned fluorine-based polymer can be a photosensitive fluorine-based polymer, the photosensitive fluorine-based polymer is a polymer similar to a negative photoresist, compared with conventional photoresists, this polymer contains 40 to 70% fluorine, and perfluorinated solvents must be used to dissolve such as HFE7100, and HFE7500. While perfluorinated solvents cannot dissolve PLN (insufficient fluorine content), and fluorine-based polymers are not soluble in PLN solvents. These two types of photoresists and their solvents are orthogonal.

For example, the chemical formula of the above-mentioned fluorine-based polymer is as follows:

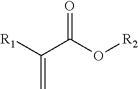

In which, R1 is an alkyl group, H, etc., and R2 is a fluorine-containing group.

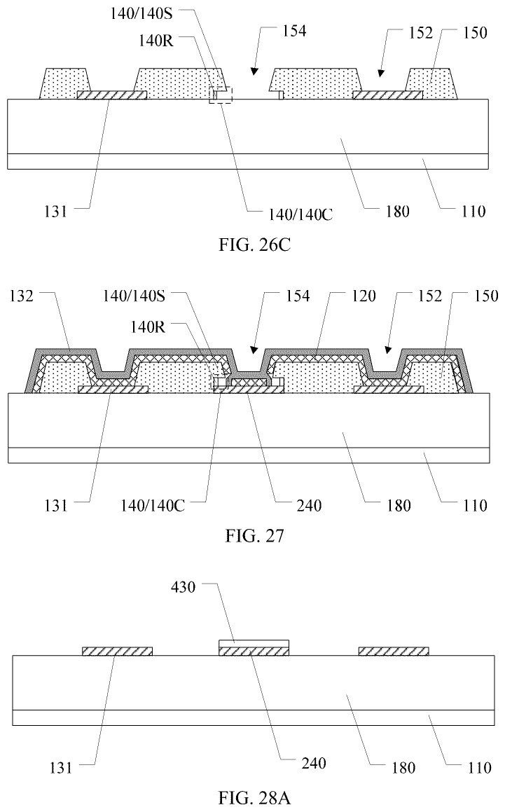

FIGS. 26A to 26C are schematic diagrams of steps of another manufacturing method of a display substrate provided by an embodiment of the present disclosure, and the manufacturing method of the display substrate includes:

As illustrated by FIG. 26A, forming the first electrodes 131 and a sacrificial structure 430 on a side of the planarization layer 180 away from the base substrate 110. It should be noted that the above-mentioned residual structure may be a part of the sacrificial structure.

As illustrated by FIG. 26B, the pixel defining layer 150 is formed on a side of the first electrode 131 and the sacrificial structure 430 away from the base substrate 110. The pixel defining layer 150 includes a plurality of pixel openings 152 and a pixel spacing opening 154; the plurality of pixel openings 152 are arranged in one-to-one correspondence with the plurality of first electrodes 131; the plurality of pixel openings 152 is configured to expose the first electrodes 131, so that the first electrodes 131 are in contact with the subsequently formed light-emitting functional layer 120. The pixel spacing opening 154 is located between adjacent first electrodes 131, the sacrificial structure 430 is partially exposed by the pixel spacing opening 154.

As illustrated by FIG. 26C, the display substrate is etched by using the pixel defining layer 150 as a mask, so that the sacrificial structure 430 is removed, to form the above-mentioned pixel isolation structure 140.

FIG. 27 is a structural schematic diagram of another display substrate provided by an embodiment of the present disclosure. As illustrated by FIG. 27, the display substrate 100 further includes a protection structure 240 located on the planarization layer 180 and is arranged in a same layer as the first electrodes 131; the pixel isolation structure 140 is arranged on a side of the protection structure 240 away from the base substrate 110, and is located at an edge of the protection structure 240. In this way, the protection structure 240 can protect the planarization layer 180 during the etching process used to manufacture the pixel isolation structure 140, to prevent the planarization layer 180 from being etched.

In some examples, as illustrated by FIG. 27, the display substrate 100 further includes a light-emitting functional layer 120 and a second electrode 132; the light-emitting functional layer 120 is located on a side of the first electrodes 131, the pixel defining layer 150 and the protection structures 240 away from the base substrate 110. Due to the effect of the pixel isolation structure 140, the light-emitting functional layer 120 will be disconnected at the position where the pixel isolation structure 140 is located, and a fracture is formed; at this time, the second electrode 132 formed subsequently can be connected with the protection structure 240 through the fracture, the protection structures 240 can function as auxiliary electrodes.

In the display substrate, the second electrode is an electrode shared by a plurality of sub-pixels, to provide cathode signals to the plurality of sub-pixels; even if a part of the second electrode in the entire display substrate are disconnected due to the pixel isolation structure or other reasons, the protection structures serve as auxiliary electrodes and can connect the disconnected parts of the second electrode to other parts.

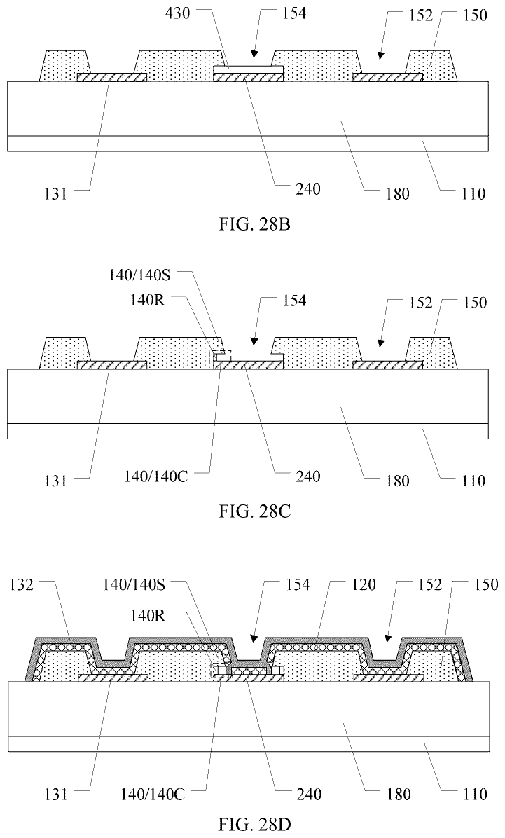

FIGS. 28A to 28D are schematic diagrams of steps of another manufacturing method of a display substrate provided by an embodiment of the present disclosure. The manufacturing method of a display substrate includes:

As illustrated by FIG. 28A, the first electrodes 131, the protection structure 240 and the sacrificial structure 430 are formed on a side of the planarization layer 180 away from the base substrate 110, and the protection structure 240 and the first electrodes 131 are arranged in a same layer. The material of the protection structure 240 is the same as the material of the first electrodes 131, and the material of the protection structure 240 is different from the material of the sacrificial structure 430.

As illustrated by FIG. 28B, the pixel defining layer 150 is formed on a side of the first electrodes 131 and the sacrificial structure 430 away from the base substrate 110. The pixel defining layer 150 includes a plurality of pixel openings 152 and a pixel spacing opening 154; the plurality of pixel openings 152 are arranged in one-to-one correspondence with the plurality of first electrodes 131; the plurality of pixel openings 152 is configured to expose the first electrodes 131, so that the first electrodes 131 is in contact with the subsequently formed light-emitting functional layer 120. The pixel spacing opening 154 is located between adjacent first electrodes 131, the sacrificial structure 430 is partially exposed by the pixel spacing opening 154.

As illustrated by FIG. 28C, the display substrate is etched by using the pixel defining layer 150 as a mask, so that the sacrificial structure 430 is removed, to form the above-mentioned pixel isolation structure 140.

As illustrated by FIG. 28D, the light-emitting functional layer 120 and the second electrode 132 are formed on a side of the first electrodes 131, the pixel defining layer 150 and the protection structures 240 away from the base substrate 110. Due to the effect of the pixel isolation structure 140, the light-emitting functional layer 120 will be disconnected at the position where the pixel isolation structure 140 is located, and a fracture is formed; at this time, the second electrode 132 formed later can be connected with the protection structures 240 through the fracture, the protection structures 240 can function as auxiliary electrodes.

In the display substrate, the second electrode is an electrode shared by the plurality of sub-pixels, to provide cathode signals to the plurality of sub-pixels; even if a part of the second electrode in the entire display substrate is disconnected due to the pixel isolation structure or other reasons, the protection structures serve as auxiliary electrodes and can connect the disconnected parts of the second electrode to other parts.

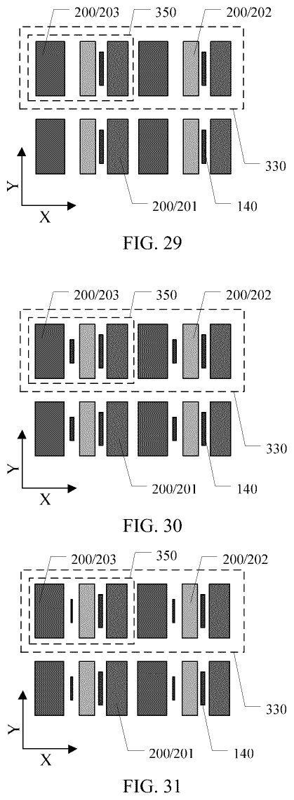

FIG. 29 is a partial planar schematic diagram of a display substrate provided by an embodiment of the present disclosure. As illustrated by FIG. 29, the plurality of sub-pixels 200 include a plurality of first color sub-pixels 201, a plurality of second color sub-pixels 202 and a plurality of third color sub-pixels 203; a third color sub-pixel 203, a second color sub-pixel 202 and a first color sub-pixel 201 are sequentially arranged along the first direction X to form a pixel group 350; a plurality of pixel groups 350 are arranged along the first direction X to form a pixel row 330; a plurality of pixel rows 330 are arranged along the second direction Y to form an array. At this time, the pixel isolation structure 140 is arranged between a first color sub-pixel 201 and a second color sub-pixel 202.

For example, the first color sub-pixels may be red sub-pixels, which is configured to emit red light; the second color sub-pixels may be green sub-pixels, which is configured to emit green light; and the third color sub-pixels may be blue sub-pixels, which is configured to emit blue light.

In a case that the display substrate performs display, the red sub-pixels and blue sub-pixels have small parasitic capacitance and are easier to emit light; the green sub-pixels have a large parasitic capacitance and are not easy to emit light. Moreover, from the perspective of organic light-emitting devices, the red sub-pixels have a narrowest band gap and require lower energy, so the red sub-pixels are most susceptible to the influence of crosstalk voltage. Therefore, crosstalk among sub-pixels mostly occurs between red sub-pixels and green sub-pixels. In this way, in the display substrate, the pixel isolation structures are arranged among the red sub-pixels and the green sub-pixels, which can effectively avoid crosstalk among the red sub-pixels and the green sub-pixels. In addition, the display substrate is among the red sub-pixels and the blue sub-pixels, no pixel isolation structure is provided among the blue sub-pixels and the green sub-pixels, which can reduce the loss of aperture ratio.

FIG. 30 is a partial planar schematic diagram of a display substrate provided by an embodiment of the present disclosure. As illustrated by FIG. 30, the plurality of sub-pixels 200 include a plurality of first color sub-pixels 201, a plurality of second color sub-pixels 202 and a plurality of third color sub-pixels 203; a third color sub-pixel 203, a second color sub-pixel 202 and a first color sub-pixel 201 are sequentially arranged along the first direction X to form a pixel group 350; a plurality of pixel groups 350 are arranged along the first direction X to form a pixel row 330; and a plurality of pixel rows 330 are arranged along the second direction Y to form an array. At this time, the pixel isolation structures 140 can not only be arranged among the first color sub-pixels 201 and the second color sub-pixels 202, and are also arranged among the second color sub-pixels 202 and the third color sub-pixels 203. In this way, the display substrate can effectively avoid crosstalk among sub-pixels.

In some examples, as illustrated by FIG. 30, an area (an area of an orthographic projection of the pixel isolation structure on the substrate) occupied by the pixel isolation structure 140 between a second color sub-pixel 202 and a third color sub-pixel 203 is larger than an area occupied by a pixel isolation structure 140 between a first color sub-pixel 201 and a second color sub-pixel 202. In this way, this display substrate effectively avoids crosstalk among sub-pixels, by reducing the area occupied by the pixel isolation structure between the first color sub-pixel and the second color sub-pixel, and not arranging the pixel isolation structure between the first color sub-pixel and the third color sub-pixel, the loss of the aperture ratio can be reduced.

In some examples, as illustrated by FIG. 30, a size of the pixel isolation structure 140 between the second color sub-pixel 202 and the third color sub-pixel 203 in the second direction is larger than a size of the pixel isolation structure 140 between the first color sub-pixel 201 and the second color sub-pixel 202 in the second direction. In this way, the display substrate can reduce the area occupied by the pixel isolation structure between the first color sub-pixel and the second color sub-pixel by reducing the size of the pixel isolation structure 140 in the second direction.

For example, the first color sub-pixels may be red sub-pixels, which are configured to emit red light; the second color sub-pixels may be green sub-pixels, which are configured to emit green light; and the third color sub-pixels may be blue sub-pixels, which are configured to emit blue light.

FIG. 31 is a partial planar schematic diagram of a display substrate provided by an embodiment of the present disclosure. As illustrated by FIG. 31, the plurality of sub-pixels 200 include a plurality of first color sub-pixels 201, a plurality of second color sub-pixels 202 and a plurality of third color sub-pixels 203; a third color sub-pixel 203, a second color sub-pixel 202 and a first color sub-pixel 201 are sequentially arranged along the first direction X to form a pixel group 350; a plurality of pixel groups 350 are arranged along the first direction X to form a pixel row 330; a plurality of pixel rows 330 are arranged along the second direction Y to form an array. At this time, the pixel isolation structures 140 can not only be arranged among the first color sub-pixels 201 and the second color sub-pixels 202, and are also arranged among the second color sub-pixels 202 and the third color sub-pixels 203. In this way, the display substrate can effectively avoid crosstalk among sub-pixels.

In some examples, as illustrated by FIG. 31, an area (an area of an orthographic projection of the pixel isolation structure on the substrate) occupied by a pixel isolation structure 140 between a second color sub-pixel 202 and a third color sub-pixel 203 is larger than an area occupied by a pixel isolation structure 140 between a first color sub-pixel 201 and a second color sub-pixel 202. In this way, this display substrate effectively avoids crosstalk among sub-pixels, by reducing the area occupied by the pixel isolation structure between the first color sub-pixel and the second color sub-pixel, and not arranging the pixel isolation structure between the first color sub-pixel and the third color sub-pixel, the loss of the aperture ratio can be reduced.

In some examples, as illustrated by FIG. 31, a size of the pixel isolation structure 140 between the second color sub-pixel 202 and the third color sub-pixel 203 in the second direction is larger than a size of the pixel isolation structure 140 between the first color sub-pixel 201 and the second color sub-pixel 202 in the second direction. Moreover, the size of the pixel isolation structure 140 between the second color sub-pixel 202 and the third color sub-pixel 203 in the first direction is larger than the size of the pixel isolation structure 140 between the first color sub-pixel 201 and the second color sub-pixel 202 in the first direction. In this way, the display substrate can reduce the area occupied by the pixel isolation structures among the first color sub-pixels and the second color sub-pixels by reducing the size of the pixel isolation structures 140 in the first direction and the second direction.

For example, the first color sub-pixels may be red sub-pixels, which are configured to emit red light; the second color sub-pixels may be green sub-pixels, which are configured to emit green light; and the third color sub-pixels may be blue sub-pixels, which are configured to emit blue light.

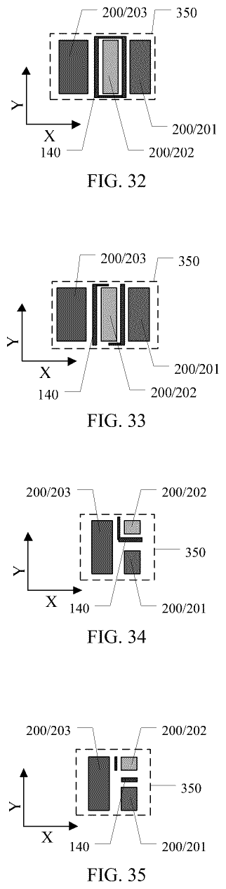

FIG. 32 is a partial planar schematic diagram of a display substrate provided by an embodiment of the present disclosure. As illustrated by FIG. 32, the plurality of sub-pixels 200 include a plurality of first color sub-pixels 201, a plurality of second color sub-pixels 202 and a plurality of third color sub-pixels 203, a third color sub-pixel 203, a second color sub-pixel 202 and a first color sub-pixel 201 are sequentially arranged along the first direction X to form a pixel group 350. At this time, the pixel isolation structure 140 may be arranged around the second color sub-pixel 202. In this way, the pixel isolation structure 140 can separate the second color sub-pixel 202 from other sub-pixels, so that crosstalk among the second color sub-pixel and adjacent sub-pixels can be avoided. It should be noted that although the first annular isolation part shown in FIG. 32 is only arranged around one second color sub-pixel, however, the embodiments of the present disclosure include but are not limited thereto, a first annular isolation part may also surround two or more second color sub-pixels.

FIG. 33 is a partial planar schematic diagram of a display substrate provided by an embodiment of the present disclosure. As illustrated by FIG. 32, the plurality of sub-pixels 200 include a plurality of first color sub-pixels 201, a plurality of second color sub-pixels 202 and a plurality of third color sub-pixels 203, a third color sub-pixel 203, a second color sub-pixel 202 and a first color sub-pixel 201 are sequentially arranged along the first direction X to form a pixel group 350. At this time, a pixel isolation structure 140 may be at least partially arranged around the second color sub-pixel 202. In this way, the pixel isolation structure 140 can separate the second color sub-pixel 202 from other sub-pixels, so that crosstalk among the second color sub-pixel and adjacent sub-pixels can be avoided.

In some examples, as illustrated by FIG. 33, the pixel isolation structure 140 includes two L-shaped sub-parts, two L-shaped sub-parts surround the second color sub-pixel 202.

FIG. 34 is a partial planar schematic diagram of a display substrate provided by an embodiment of the present disclosure. As illustrated by FIG. 34, the plurality of sub-pixels 200 include a plurality of first color sub-pixels 201, a plurality of second color sub-pixels 202 and a plurality of third color sub-pixels 203; a second color sub-pixel 202 and a first color sub-pixel 201 are arranged along the second direction Y to form a sub-pixel pair, and a third color sub-pixel 203 is alternately arranged with the sub-pixel pair along the first direction. At this time, a pixel isolation structure 140 may be arranged at least partially around the second color sub-pixel 202, and is set between the first color sub-pixel 201 and the second color sub-pixel 202, and between the second color sub-pixel 202 and the third color sub-pixel 203. In this way, the pixel isolation structure can effectively avoid crosstalk among sub-pixels, and reduce the loss of aperture ratio.

In some examples, as illustrated by FIG. 34, an orthographic projection of the pixel isolation structure 140 on the base substrate is formed into an L shape, two sides of the L shape are respectively located between the first color sub-pixel 201 and the second color sub-pixel 202, and between the second color sub-pixel 202 and the third color sub-pixel 203.

FIG. 35 is a partial planar schematic diagram of a display substrate provided by an embodiment of the present disclosure. As illustrated by FIG. 35, the plurality of sub-pixels 200 include a plurality of first color sub-pixels 201, a plurality of second color sub-pixels 202 and a plurality of third color sub-pixels 203; a second color sub-pixel 202 and a first color sub-pixel 201 are arranged along the second direction Y to form a sub-pixel pair, and a third color sub-pixel 203 is alternately arranged with the sub-pixel pair along the first direction. At this time, the pixel isolation structure 140 is arranged between the first color sub-pixel 201 and the second color sub-pixel 202, between the second color sub-pixel 202 and the third color sub-pixel 203, and between the first color sub-pixel 201 and the third color sub-pixel 203. In this way, the pixel isolation structure can effectively avoid crosstalk among sub-pixels.

In some examples, as illustrated by FIG. 35, the pixel isolation structure 140 includes three strip parts 140P, which are respectively arranged between the first color sub-pixel 201 and the second color sub-pixel 202, between the second color sub-pixel 202 and the third color sub-pixel 203, and between the first color sub-pixel 201 and the third color sub-pixel 203.

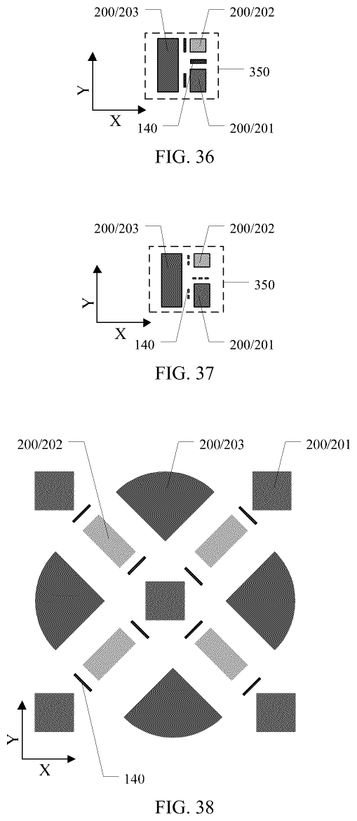

FIG. 36 is a partial planar schematic diagram of a display substrate provided by an embodiment of the present disclosure. The plurality of sub-pixels 200 include a plurality of first color sub-pixels 201, a plurality of second color sub-pixels 202 and a plurality of third color sub-pixels 203; a second color sub-pixel 202 and a first color sub-pixel 201 are arranged along the second direction Y to form a sub-pixel pair, and a third color sub-pixel 203 is alternately arranged with the sub-pixel pair along the first direction. At this time, the pixel isolation structure 140 is arranged between the first color sub-pixel 201 and the second color sub-pixel 202 and between the second color sub-pixel 202 and the third color sub-pixel 203. In this way, this pixel isolation structure can effectively avoid crosstalk among sub-pixels, and reduce the loss of aperture ratio.

In some examples, as illustrated by FIG. 36, the pixel isolation structure 140 includes two strips, which are respectively arranged between the first color sub-pixel 201 and the second color sub-pixel 202 and between the second color sub-pixel 202 and the third color sub-pixel 203.

FIG. 37 is a partial planar schematic diagram of a display substrate provided by an embodiment of the present disclosure. As illustrated by FIG. 37, the plurality of sub-pixels 200 include a plurality of first color sub-pixels 201, a plurality of second color sub-pixels 202 and a plurality of third color sub-pixels 203; a second color sub-pixel 202 and a first color sub-pixel 201 are arranged along the second direction Y to form a sub-pixel pair, and a third color sub-pixel 203 is alternately arranged with the sub-pixel pair along the first direction. At this time, the pixel isolation structure 140 is arranged between the first color sub-pixel 201 and the second color sub-pixel 202, between the second color sub-pixel 202 and the third color sub-pixel 203, and between the first color sub-pixel 201 and the third color sub-pixel 203. In this way, this pixel isolation structure can effectively avoid crosstalk among sub-pixels.

In some examples, as illustrated by FIG. 37, the pixel isolation structure 140 includes three strips 140P, which are respectively arranged between the first color sub-pixel 201 and the second color sub-pixel 202, between the second color sub-pixel 202 and the third color sub-pixel 203, and between the first color sub-pixel 201 and the third color sub-pixel 203; and each of the strips 140P may include a plurality of notches 140N, to form a channel to ensure that a second electrode is connected.

FIG. 38 is a partial planar schematic diagram of a display substrate provided by an embodiment of the present disclosure. As illustrated by FIG. 38, the plurality of sub-pixels 200 include a plurality of first color sub-pixels 201, a plurality of second color sub-pixels 202 and a plurality of third color sub-pixels 203; with a first color sub-pixel 201 as a center, four second color sub-pixels 202 are arranged along diagonal lines of the first color sub-pixel 201; the four first color sub-pixels 201 are respectively arranged on the sides of the four second color sub-pixels 202 away from the first color sub-pixel 201 in the center to form an X-shaped structure; the four third color sub-pixels 203 are arranged in four regions divided by the X-shaped structure. At this time, the pixel isolation structures 140 are disposed between the first color sub-pixel 201 and the second color sub-pixels 202. In this way, this pixel isolation structures can effectively avoid crosstalk among sub-pixels, and reduce the loss of aperture ratio.

In some examples, as illustrated by FIG. 38, a shape of an orthographic projection of the first color sub-pixel 201 on the base substrate may be a rectangle, a shape of an orthographic projection of a second color sub-pixel 202 on the base substrate may be a rectangle, and a shape of an orthographic projection of a third color sub-pixel 203 on the base substrate may be a fan shape.

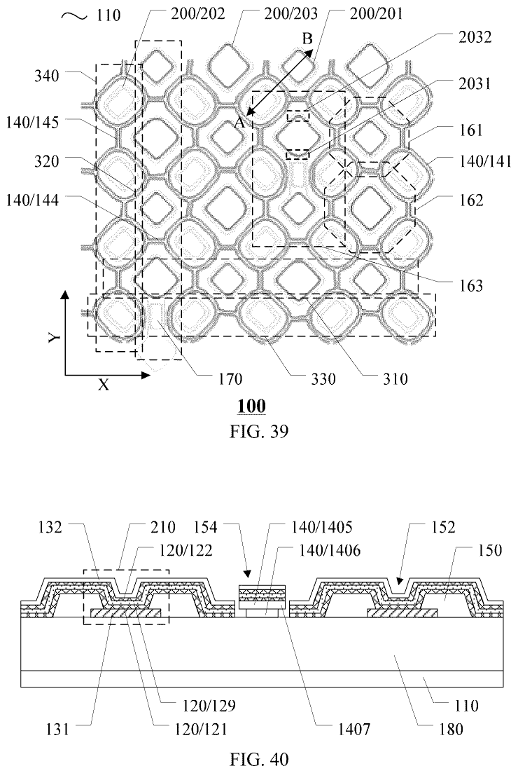

An embodiment of the present disclosure provides a display substrate. FIG. 39 is a planar schematic diagram of a display substrate provided by an embodiment of the present disclosure; and FIG. 40 is a cross-sectional schematic diagram of a display substrate along an AB direction in FIG. 39 provided by an embodiment of the present disclosure.

As illustrated by FIGS. 39 and 40, the display substrate 100 includes a base substrate 110 and a plurality of sub-pixels 200; the plurality of sub-pixels 200 are located on the base substrate 110, and each of the plurality of sub-pixel 200 includes a light-emitting element 210; each of the light-emitting elements 210 includes a light-emitting functional layer 120 and a first electrode 131 and a second electrode 132 located on two sides of the light-emitting functional layer 120 respectively. The first electrodes 131 are located between the light-emitting functional layer 120 and the base substrate 110; the second electrode 132 is at least partially located on the side of the light-emitting functional layer 120 away from the first electrodes 131; that is, the first electrodes 131 and the second electrode 132 are located on two sides in a direction perpendicular to the light-emitting functional layer 120 respectively. The light-emitting functional layer 120 includes a plurality of sub-functional layers, and the plurality of sub-functional layers include a conductive sub-layer 129 with relatively high conductivity. It should be noted that the above-mentioned light-emitting functional layer does not only include film layers that directly emit light, also includes functional film layers used to assist light emitting, such as a hole transport layer, an electron transport layer, etc.

For example, the conductive sub-layer 129 may be a charge generation layer. For example, the first electrodes 131 may be anodes, and the second electrode 132 may be a cathode. For example, the cathodes may be formed from a material with high conductivity and low work function, for example, the cathodes may be made of a metallic material. For example, the anodes may be formed from a transparent conductive material with a high work function.

As illustrated by FIGS. 39 and 40, the display substrate 100 further includes an isolation structure 140, the isolation structure 140 is located on the base substrate 110 and between adjacent sub-pixels 200; the charge generation layer 129 in the light-emitting functional layer 120 is disconnected at the position where the isolation structure 140 is located. It should be noted that the charge generation layer in the light-emitting functional layer has a discontinuous structure or a non-integrated structure at the disconnected position.

In the display substrate provided by the embodiment of the present disclosure, by arranging an isolation structure between adjacent sub-pixels and causing the charge generation layer in the light-emitting functional layer to be disconnected at the location of the isolation structure, so that crosstalk among adjacent sub-pixels caused by the charge generation layer with higher conductivity is avoided. On the other hand, because the display substrate can avoid crosstalk among adjacent sub-pixels through the isolation structure, the display substrate can increase pixel density while adopting a double-layer light-emitting (Tandem EL) design. Therefore, the display substrate can have the advantages of long life, low power consumption, high brightness, and high resolution.

In some examples, “adjacent sub-pixels” refers to two sub-pixels with no other sub-pixels arranged between them.

In some examples, as illustrated by FIGS. 39 and 40, a line connecting brightness centers of two adjacent sub-pixels 200 passes through the isolation structure 140. because the size of the charge generation layer in the extension direction of the connection line is smaller, the resistance of the charge generation layer in the extension direction of the connection line is also smaller. Charges are easily transferred from one of the two adjacent sub-pixels to the other of the two adjacent sub-pixels through the charge generation layer along the extending direction of the connection line. Therefore, the display substrate allows the connection line to pass through the isolation structure, which allows the isolation structure to effectively block the shortest propagation path of charges, so that crosstalk among adjacent sub-pixels can be effectively avoided. It should be noted that the brightness center of each of the sub-pixels may be a geometric center of the effective light-emitting region of the sub-pixel. Of course, embodiments of the present disclosure include but are not limited thereto, the brightness center of each of the sub-pixels can also be a position where the maximum value of the light-emitting brightness of the sub-pixel is located.

In some examples, as illustrated by FIGS. 39 and 40, the display substrate 100 further includes a pixel defining layer 150 located on the base substrate 110; the pixel defining layer 150 is partially located on a side of the first electrodes 131 away from the base substrate 110; the pixel defining layer 150 includes a plurality of pixel openings 152 and a pixel spacing opening 154; the plurality of pixel openings 152 correspond to the plurality of sub-pixels 200 one-to-one to define effective light-emitting areas of the plurality of sub-pixels 200; the pixel openings 152 are configured to expose the first electrodes 131, so that the first electrodes 131 are in contact with the subsequently formed light-emitting functional layer 120. The pixel spacing opening 154 is located between adjacent first electrodes 131, at least a part of the isolation structure 140 is located within the pixel spacing opening 154. In this way, the display substrate can avoid forming an isolation structure on the pixel defining layer, so that increasing the thickness of the display substrate is avoided. Of course, embodiments of the present disclosure include but are not limited thereto, the pixel defining layer does not need to be arranged with the above-mentioned pixel spacing opening, so that the isolation structure can be directly arranged on the pixel defining layer, or the isolation structure can be made using the pixel defining layer.

For example, the material of the pixel defining layer may include organic materials, such as polyimide, acrylic, or polyethylene terephthalate.

In some examples, as illustrated by FIG. 40, the isolation structure 140 may be an isolation column; at this time, the isolation structure 140 includes a first isolation part 1405 and a second isolation part 1406 that are stacked, the first isolation part 1405 is located on a side of the second isolation part 1406 close to the base substrate 110; the second isolation part 1406 has a protruding part 1407 beyond the first isolation part 1405 in an arrangement direction of two adjacent sub-pixels 200, and a conductive sub-layer 129 of the light emitting functional layer 120 is disconnected at the protruding part 1407. In this way, the isolation structure can disconnect the conductive sub-layer of the light-emitting functional layer. It should be noted that the isolation structure provided by the embodiment of the present disclosure is not limited to the form of the above-mentioned isolation column, and the isolation structure can also adopt other structures that can disconnect the conductive sub-layer of the light-emitting functional layer; in addition, the above arrangement direction may be an extending direction of a line connecting brightness centers of two adjacent sub-pixels.

In some examples, as illustrated by FIG. 40, a plurality of sub-pixels 200 share the second electrode 132, and the second electrode 132 is disconnected at the position where the isolation structure 140 is located. However, embodiments of the present disclosure include but are not limited thereto, the second electrode may not be disconnected at the position of the isolation structure.

In some examples, as illustrated by FIG. 40, the light-emitting functional layer 120 includes a first light-emitting layer 121 and a second light-emitting layer 122 located on two sides of the conductive sublayer 129 in the direction perpendicular to the base substrate 110 respectively, and the conductive sublayer 129 is a charge generation layer. In this way, the display substrate can realize a double-layer light emitting (Tandem EL) design, so the display substrate has the advantages of long life, low power consumption, and high brightness.

In some examples, as illustrated by FIG. 40, the first light-emitting layer 121 and the second light-emitting layer 122 in the light-emitting functional layer 120 are also disconnected at the position where the isolation structure 140 is located. However, embodiments of the present disclosure include but are not limited thereto, the first light-emitting layer and the second light-emitting layer in the light-emitting functional layer may not be disconnected at the location of the isolation structure, but only the conductive sub-layer may be disconnected at the location of the isolation structure.

In some examples, the conductivity of the conductive sub-layer 129 is greater than the conductivity of the first light emitting layer 121 and the conductivity of the second light emitting layer 122, and is less than conductivity of the second electrode 132.

For example, as illustrated by FIG. 40, the first light-emitting layer 121 is located on a side of the conductive sub-layer 129 close to the base substrate 110; the second light-emitting layer 122 is located on a side of the conductive sublayer 129 away from the base substrate 110.

It should be noted that the light-emitting functional layer may also include other sub-functional layers in addition to the conductive sub-layer, the first light-emitting layer and the second light-emitting layer, for example, a hole injection layer, a hole transport layer, an electron injection layer and an electron transport layer.

For example, materials of the first emitting layer and the second emitting layer may be selected from pyrene derivatives, anthracene derivatives, fluorene derivatives, perylene derivatives, styrylamine derivatives, metal complexes, and the like.

For example, the material of the hole injection layer may include oxides, such as molybdenum oxide, titanium oxide, vanadium oxide, rhenium oxide, ruthenium oxide, chromium oxide, zirconium oxide, hafnium oxide, tantalum oxide, silver oxide, tungsten oxide, and manganese oxide.

For example, the material of the hole injection layer may also include organic materials, such as: hexacyanohexaazatriphenylene, 2,3,5,6-tetrafluoro-7,7,8,8-tetracyanoquinodimethane (F4TCNQ), 1,2,3-tris[(cyano) (4-cyano-2, 3,5,6-tetrafluorophenyl)methylene]cyclopropane.

For example, material of the hole transport layer may include aromatic amines with hole transport properties and dimethyl fluorene or carbazole materials, such as: 4,4′-bis[N-(1-naphthyl)-N-phenylamino]biphenyl (NPB), N,N′-bis(3-methylphenyl)-N,N′-Diphenyl-[1,1′-biphenyl]-4,4′-diamine (TPD), 4-Phenyl-4′-(9-phenylfluoren-9-yl)triphenylamine (BAFLP), 4,4′-bis[N-(9,9-dimethylfluoren-2-yl)-N-phenylamino]biphenyl (DFLDPBi), 4,4′-bis(9-carbazolyl)biphenyl (CBP), and 9-phenyl-3-[4-(10-phenyl-9-Anthryl)phenyl]-9H-carbazole (PCzPA).

For example, material of the electron transport layer may include aromatic heterocyclic compounds, such as: benzimidazole derivatives, imidazole derivatives, pyrimidine derivatives, oxazine derivatives, quinoline derivatives, isoquinoline derivatives, phenanthroline derivatives, etc.

For example, material of the electron injection layer can be alkali metals or metals and their compounds, such as: lithium fluoride (LiF), ytterbium (Yb), magnesium (Mg), and calcium (Ca).

In some examples, the first electrodes 131 may be made of metal material, such as any one or more of magnesium (Mg), silver (Ag), copper (Cu), aluminum (Al), titanium (Ti) and molybdenum (Mo), or alloy materials of the above metals, such as aluminum-neodymium alloy (AlNd) or molybdenum-niobium alloy (MoNb), which can be a single-layer structure or a multi-layer composite structure, such as Ti/Al/Ti, etc, or is a stack structure formed by metal and transparent conductive materials, for example, reflective materials such as ITO/Ag/ITO and Mo/AlNd/ITO.

In some examples, the second electrode 132 may be made of any one or more of magnesium (Mg), silver (Ag), and aluminum (Al), or alloys made of any one or more of the above metals, or use transparent conductive materials, such as indium tin oxide (ITO), or use a multi-layer composite structure of metal and transparent conductive materials.

In some examples, the charge generation layer 129 may be configured to generate carriers, transport carriers, and inject carriers. For example, material of the charge generation layer 129 may include an n-type doped organic layer/inorganic metal oxide, such as Alq₃:Mg/WO₃, Bphen:Li/MoO₃, BCP:Li/V₂O₅ and BCP:Cs/V₂O₅; or, a n-type doped organic layer/organic layer, such as Alq₃:Li/HAT-CN; or, a n-type doped organic layer/p-type doped organic layer, such as BPhen:Cs/NPB:F4-TCNQ, Alq₃:Li/NPB:FeCl₃, TPBi:Li/NPB:FeCl₃ and Alq₃:Mg/m-MTDATA:F4-TCNQ; or a non-doped type, such as Fi₆CuPc/CuPc and Al/WO₃/Au.

In some examples, the base substrate 110 can be made of one or more materials including glass, polyimide, polycarbonate, polyacrylate, polyetherimide, and polyethersulfone, and the embodiment includes but is not limited thereto.

In some examples, the base substrate may be a rigid substrate or a flexible substrate; in a case that the base substrate is a flexible substrate, the base substrate may include a first flexible material layer, a first inorganic material layer, a semiconductor layer, a second flexible material layer and a second inorganic material layer that are stacked in sequence. The first flexible material layer and the second flexible material layer are made of materials such as polyimide (PI), polyethylene terephthalate (PET) or surface-treated polymer soft film. The first inorganic material layer and the second inorganic material layer are made of silicon nitride (SiNx) or silicon oxide (SiOx), which is used to improve the water and oxygen resistance of the base substrate, and the first inorganic material layer and the second inorganic material layer are also called barrier layers. The material of the semiconductor layer is amorphous silicon (a-si).

For example, taking the base substrate as a stacked structure PI1/Barrier1/a-si/PI2/Barrier2 as an example, the manufacturing process of the base substrate includes: first coating a layer of polyimide on the glass carrier, forming the first flexible (PI1) layer after curing into a film; subsequently depositing a barrier film on the first flexible layer, to form a first barrier (Barrier1) layer covering the first flexible layer; then depositing an amorphous silicon film on the first barrier layer, to form an amorphous silicon (a-si) layer covering the first barrier layer; then coating a layer of polyimide on the amorphous silicon layer, forming a second flexible (PI2) layer after curing into a film; then depositing a barrier film on the second flexible layer, to form a second barrier (Barrier2) layer covering the second flexible layer, and finally completing the manufacture of the substrate.

In some examples, as illustrated by FIG. 39, the plurality of sub-pixels 200 includes a plurality of first color sub-pixels 201, a plurality of second color sub-pixels 202 and a plurality of third color sub-pixels 203; the isolation structure 140 includes a plurality of first annular isolation parts 141, each of the plurality of first annular isolation parts 141 is arranged around at least one of the second color sub-pixels 202. In this way, the charge generation layer 129 in the light-emitting functional layer 120 can be disconnected at the first annular isolation parts 141, the first annular isolation parts 141 can separate the second color sub-pixels 202 from other sub-pixels, so that crosstalk among the second color sub-pixels and adjacent sub-pixels can be avoided. It should be noted that although the first annular isolation parts shown in FIG. 40 are only arranged around one second color sub-pixel, however, embodiments of the present disclosure include but are not limited thereto, and each of the first annular isolation parts may also surround two or more second color sub-pixels.

For example, as illustrated by FIG. 39, each of the first annular isolation parts 141 is arranged around one second color sub-pixel 202. In this way, the charge generation layer 129 in the light-emitting functional layer 120 can be disconnected at the first annular isolation parts 141, and the first annular isolation parts 141 may separate all the second color sub-pixels 202 from other sub-pixels.

For example, as illustrated by FIG. 39, in the display substrate 100, a number of second color sub-pixels 202 is greater than a number of first color sub-pixels 201; or the number of second color sub-pixels 202 is greater than a number of third color sub-pixels 203; or the number of second color sub-pixels 202 is greater than the number of first color sub-pixels 201 and the number of third color sub-pixels 203. In this way, by arranging the first annular isolation parts 141 outside the second color sub-pixels 202, most adjacent sub-pixels on the display substrate can be separated, so that crosstalk among adjacent sub-pixels can be effectively avoided.

For example, as illustrated by FIG. 39, in the display substrate 100, the number of the second color sub-pixels 202 is approximately twice the number of the first color sub-pixels 201 or the third color sub-pixels 203.

In some examples, as illustrated by FIG. 39, the isolation structure 140 further includes a plurality of first strip-shaped isolation parts 144 and a plurality of second strip-shaped isolation parts 145; each of the plurality of first strip-shaped isolation parts 144 extends along the first direction, and each of the plurality of second strip-shaped isolation parts 145 extends along the second direction; each of the first strip-shaped isolation parts 144 connects two first annular isolation parts 141 adjacent in the first direction. Each of the second strip-shaped isolation parts 145 connects two first annular isolation parts 141 adjacent in the second direction. A plurality of first strip-shaped isolations 144 and a plurality of second strip-shaped isolations 145 connect a plurality of first annular isolation parts 141, to form a plurality of first mesh structures 161 and a plurality of second mesh structures 162 in regions outside the plurality of first annular isolation parts 141, a first grid structure 161 is arranged around a first color sub-pixel 201, and a second grid structure 162 is arranged around a third color sub-pixel 203. In this way, the first strip-shaped isolation parts can separate the first color sub-pixels and the third color sub-pixels that are adjacent in the second direction, so that the charge generation layer in the light-emitting functional layer is disconnected at the positions where the first strip-shaped isolation parts are located, thus crosstalk among the first color sub-pixel and the third color sub-pixel adjacent in the second direction can be effectively avoided; the second strip-shaped isolation parts can separate the first color sub-pixels and the third color sub-pixels that are adjacent in the first direction, so that the charge generation layer in the light-emitting functional layer is disconnected at the positions where the second strip-shaped isolation parts are located, thus crosstalk among the first color sub-pixels and the third color sub-pixels that are adjacent in the first direction can be effectively avoided.

For example, the first direction intersects the second direction, for example, the first direction and the second direction are perpendicular to each other.

In some examples, as illustrated by FIG. 39, the display substrate 100 further includes spacers 170; a plurality of first strip-shaped isolation parts 144 and a plurality of second strip-shaped isolation parts 145 are connected with a plurality of first annular isolation parts 141 to form a plurality of third grid structures 163, a third grid structures 163 is arranged around a first color sub-pixel 201 and a third color sub-pixel 203 that are adjacent, a spacer 170 is located within the third grid structure 163 and is between the first color sub-pixel 201 and the third color sub-pixel 203. In this way, in a case that space within a first grid structure and a second grid structure is not enough to place a spacer, by arranging the above-mentioned third grid structure, sufficient space can be arranged for a spacer; in addition, because the spacer has a certain height, and is located between the first color sub-pixel and the third color sub-pixel in the third grid structure, therefore, the spacer can also prevent crosstalk among the first color sub-pixel and the third color sub-pixel in the third grid structure. It should be noted that the spacer are used to support an evaporation mask for manufacturing the above-mentioned light-emitting layer.

In some examples, as illustrated by FIG. 39, a plurality of first color sub-pixels 201 and a plurality of third color sub-pixels 203 are alternately arranged along the first direction and the second direction to form a plurality of first pixel rows 310 and a plurality of first pixel columns 320, the plurality of second color sub-pixels 202 are arranged in an array along the first direction and the second direction to form a plurality of second pixel rows 330 and a plurality of second pixel columns 340, the plurality of first pixel rows 310 and the plurality of second pixel rows 330 are alternately arranged along the second direction and are staggered from each other in the first direction, and the plurality of first pixel columns 320 and the plurality of second pixel columns 340 are alternately arranged along the first direction and are staggered from each other in the second direction. An isolation structure 140 is located between a first color sub-pixel 201 and a third color sub-pixel 203 that are adjacent, and/or, an isolation structure 140 is located between a second color sub-pixel 202 and a third color sub-pixel 203 that are adjacent, and/or, an isolation structure 140 is located between a first color sub-pixels 201 and a second color sub-pixels 202 that are adjacent.

In some examples, the light-emitting efficiency of the third color sub-pixels are less than the light-emitting efficiency of the second color sub-pixels.

For example, the first color sub-pixels 201 are configured to emit red light, the second color sub-pixels 202 are configured to emit green light, and the third color sub-pixels 203 are configured to emit blue light. Of course, embodiments of the present disclosure include but are not limited thereto.

In some examples, as illustrated by FIG. 39, a shape of an orthographic projection of an effective light-emitting region of a first color sub-pixel 201 on the base substrate 110 includes a rounded rectangle; a shape of an orthographic projection of an effective light-emitting region of a second color sub-pixel 202 on the base substrate 110 includes a rounded rectangle; and a shape of an orthographic projection of an effective light-emitting region of the third color sub-pixel 203 on the base substrate 110 includes a rounded rectangle. It should be noted that the above-mentioned effective light-emitting region can generally be a region limited by a pixel opening corresponding to the sub-pixel.

In some examples, as illustrated by FIG. 39, a shape of an orthographic projection of an effective light-emitting region of a third color sub-pixel 203 on the base substrate 110 includes a plurality of rounded corner portions, the plurality of rounded corner portions include a first rounded corner portion 2031, and an arc radius of the first rounded corner portion 2031 is larger than an arc radius of other rounded corner portions. At this time, because the arc radius of the first rounded corner portion 2031 is larger, the space occupied by the first rounded corner portion 2031 is smaller. Therefore, a spacer 170 can be arranged near the first rounded portion 2031, so that the area on the display substrate can be fully utilized, and the pixel density can be increased. At this time, the first rounded corner portion 2031 is a rounded corner part with the smallest distance from the first color sub-pixel 201 among the plurality of rounded corner portions of the third color sub-pixel 203.

In some examples, as illustrated by FIG. 39, an orthographic projection of a spacer 170 on the base substrate 110 is located on a line connecting the midpoint of the first rounded corner portion 2031 and a brightness center of the first color sub-pixel 201.

In some examples, as illustrated by FIG. 39, a shape of an orthographic projection of an effective light-emitting region of a third color sub-pixel 203 on the base substrate 110 includes a plurality of rounded corner portions, the plurality of rounded corner portions include a first rounded corner portion 2031 and a second rounded corner portion 2032, an arc radius of the first rounded corner portion 2031 is greater than an arc radius of the second rounded corner portion 2031; furthermore, the shape of the orthographic projection of the effective light-emitting region of the third color sub-pixel 203 on the base substrate 110 is axially symmetrical with respect to the line connecting the first rounded corner portion 2031 and the second rounded corner portion 2032.

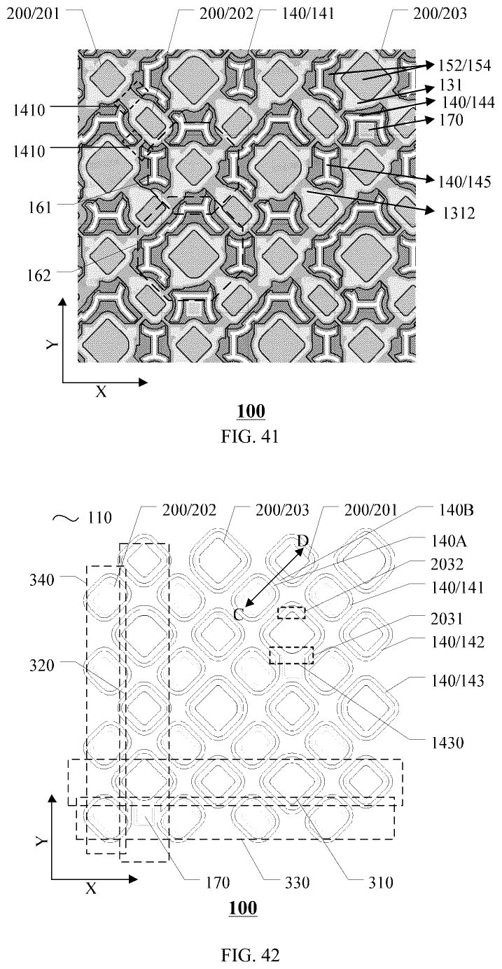

FIG. 41 is a planar schematic diagram of another display substrate provided by an embodiment of the present disclosure. As illustrated by FIG. 41, the first annular isolation parts 141 include at least one notch 1410. In a case that a first annular isolation part is arranged outside a second color sub-pixel, not only will the charge generation layer in the light-emitting functional layer be broken at the first annular isolation part, but a second electrode on the light-emitting functional layer may also be broken at the location of the first annular isolation part, so that a cathode signal cannot be transmitted to the corresponding second color sub-pixel. Therefore, by arranging at least one notch on the first annular isolation part, the display substrate can prevent the first annular isolation part from completely isolating the second color sub-pixels, so that the phenomenon that the cathode signal cannot be transmitted can be avoided.

In some examples, as illustrated by FIG. 41, a second color sub-pixel 202 is surrounded by two first color sub-pixels 201 and two third color sub-pixels 203; at this time, the first annular isolation part 141 includes four notches 1410, which are respectively located between the second color sub-pixel 202 and the four adjacent sub-pixels 200. Therefore, by arranging the above-mentioned gap, the second electrode or the cathode between the second color sub-pixel and the surrounding four sub-pixels will not be disconnected, thus it is easy to transmit the cathode signal. It should be noted that although the first annular isolation part is arranged with the above-mentioned notch, due to a relatively small size of the notch, thus the resistance of the conductive sublayer (such as the charge generation layer) at the notch position can be greatly increased, so that passage of current is effectively blocked, furthermore, crosstalk among adjacent sub-pixels is effectively avoided. Moreover, because the conductivity of the second electrode is greater than the conductivity of the conductive sub-layer, there are a plurality of conductive channels, even if the size of the gap is relatively small, it will not hinder the transmission of cathode signals.

In some examples, as illustrated by FIG. 41, the first electrodes 131 of the second color sub-pixels 202 include an electrode connection part 1312, an orthographic projection of the electrode connection portion 1312 on the base substrate 110 is at least partially overlapped with an orthographic projection of the notch 1410 of the first annular isolation part 141 on the base substrate 110. In this way, the display substrate can use the position of the notch of the first annular isolation to set the electrode connection part, so that layout of the sub-pixels can be made more compact, and the pixel density can be increased. It should be noted that a brightness center of each of the sub-pixels may be the geometric center of the effective light-emitting region of the sub-pixel. Of course, embodiments of the present disclosure include, but are not limited to, the brightness center of each of the sub-pixels may also be a position where the maximum value of the light-emitting brightness of the sub-pixel is located.

In some examples, as illustrated by FIG. 41, the first electrode 131 of the first color sub-pixel 201 also includes an electrode connection portion 1312, the first electrode 131 of the third color sub-pixel 203 also includes an electrode connection portion 1312; an orthographic projection of the electrode connection portions 1312 of the first color sub-pixel 201 and the third color sub-pixel 203 on the base substrate 110 is also at least partially overlapped with an orthographic projection of the notch 1410 of the first annular isolation part 141 on the base substrate 110. In this way, the display substrate can further use the position of the notch of the first annular isolation to set the electrode connection portion of the first color sub-pixel and the third color sub-pixel, so that the layout of the sub-pixels can be made more compact, and the pixel density can be increased.

In some examples, as illustrated by FIG. 41, the isolation structure 140 further includes a plurality of first strip-shaped isolation parts 144 and a plurality of second strip-shaped isolation parts 145; each of the plurality of first strip-shaped isolation parts 144 extends along the first direction, and each of the plurality of second strip-shaped isolation parts 145 extends along the second direction; each of the first strip-shaped isolation parts 144 connects two first annular isolation parts 141 adjacent in the first direction, and each of the second strip-shaped isolation parts 145 connects the two first annular isolation parts 141 adjacent in the second direction. A plurality of first strip-shaped isolations 144 and a plurality of second strip-shaped isolations 145 connect the plurality of first annular isolation parts 141, so that a plurality of first grid structures 161 and a plurality of second grid structures 162 are formed in regions outside the plurality of first annular isolation parts 141, a first grid structure 161 is arranged around a first color sub-pixel 201, a second grid structure 162 is arranged around a third color sub-pixel 203. In this way, a first strip-shaped isolation part can separate a first color sub-pixel and a third color sub-pixel that are adjacent in the second direction, so that the charge generation layer in the light-emitting functional layer is disconnected at the position where the first strip-shaped isolation part is located, thus crosstalk between the first color sub-pixel and the third color sub-pixel adjacent in the second direction can be effectively avoided; the second strip-shaped isolation part can separate the first color sub-pixel and the third color sub-pixel that are adjacent in the first direction, so that the charge generation layer in the light-emitting functional layer is disconnected at the position where the second strip-shaped isolation is located, thus crosstalk between the first color sub-pixel and the third color sub-pixel that are adjacent in the first direction can be effectively avoided.

For example, the first direction intersects the second direction, for example, the first direction and the second direction are perpendicular to each other.

In some examples, as illustrated by FIG. 41, the gaps 1410 of the first annular isolation part 141 also serve as the gaps of the first grid structure 161 and the second grid structure 162. In this way, a second electrode of a first color sub-pixel 201 located in a first grid structure 161 and a second electrode of a third color sub-pixel 203 located in a second grid structure 162 will not be completely disconnected, thus it is easy to transmit a cathode signal.

In some examples, as illustrated by FIG. 41, the display substrate 100 further includes spacers 170; each of the spacers 170 is located within a first grid structure 161, and are located between a first color sub-pixel 201 and a third color sub-pixel 203. In a case that space in the first grid structure is enough to place the spacers, the spacers can be directly placed in the first grid structure. It should be noted that embodiments of the present disclosure include but are not limited thereto, the spacers may also be located within the second grid structure; in addition, the above-mentioned “within the grid structure” refers to the space surrounded by the grid structure, not within the grid structure itself.

FIG. 42 is a planar schematic diagram of another display substrate provided by an embodiment of the present disclosure. As illustrated by FIG. 42, the plurality of sub-pixels 200 include a plurality of first color sub-pixels 201, a plurality of second color sub-pixels 202 and a plurality of third color sub-pixels 203; the isolation structure 140 includes a plurality of first annular isolation parts 141, a plurality of second annular isolation parts 142 and a plurality of third annular isolation parts 143; each of the plurality of first annular isolation parts 141 is arranged around a second color sub-pixels 202; each of the plurality of second annular isolation parts 142 is arranged around a first color sub-pixel 201; and each of the plurality of third annular isolation 143 is arranged around a third color sub-pixel 203.

In the display substrate shown in FIG. 42, a charge generation layer 129 in the light-emitting functional layer 120 can be disconnected at a first annular isolation part 141, a second annular isolation part 142 and a third annular isolation part 143, the first annular isolation part 141 can separate the second color sub-pixel 202 from other sub-pixels, thus crosstalk between the second color sub-pixel and adjacent sub-pixels can be avoided; the second annular isolation part 142 can separate the first color sub-pixel 201 from other sub-pixels, thus crosstalk between the first color sub-pixel and adjacent sub-pixels can be avoided; the third annular isolation part 143 can separate the third color sub-pixel 203 from other sub-pixels, thus crosstalk between the second color sub-pixel and adjacent sub-pixels can be avoided.

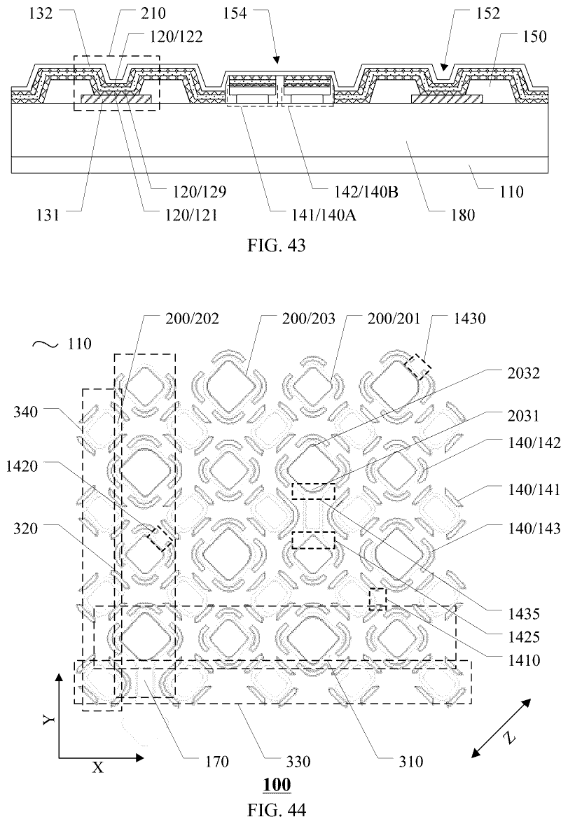

FIG. 43 is a cross-sectional schematic diagram of a display substrate along a CD direction in FIG. 42 provided by an embodiment of the present disclosure. As illustrated by FIG. 43, an isolation structure 140 between a first color sub-pixel 201 and a second color sub-pixel 202 includes a part of a first annular isolation part 141 and a part of a second annular isolation part 142; at this time, the part of the first annular isolation part 141 can be used as a first sub-isolation structure 140A of the isolation structure 140, and the part of the second annular isolation part 142 can serve as a second sub-isolation structure 140B of the isolation structure 140. The first sub-isolation structure 140A and the second sub-isolation structure 140B are arranged sequentially in an arrangement direction of adjacent sub-pixels 200. In a case that the charge layer in the light-emitting functional layer is not disconnected or is completely disconnected at a location of the first sub-isolation structure, the charge layer in the light-emitting functional layer can be disconnected at a position where the second sub-isolation structure is located. In this way, by sequentially arranging the first sub-isolation structure and the second sub-isolation structure in the arrangement direction of the adjacent sub-pixels, the display substrate can better enable the charge generation layer in the light-emitting functional layer to be disconnected at the location of the isolation structure, thus crosstalk among adjacent sub-pixels caused by the charge generation layer with higher conductivity is further avoided. Of course, embodiments of the present disclosure include but are not limited thereto, in a case that distance between adjacent sub-pixels is small, only one sub-isolation structure may be arranged.

In some examples, as illustrated by FIG. 42, both the first annular isolation part 141 and the second annular isolation part 142 are complete annular structures excluding a notch; the third annular isolation part 143 includes a notch 1430, the two ends of the third annular isolation part 143 at the notch 1430 are respectively connected with the two first annular isolation parts 141 adjacent in the first direction or the second direction. In this way, in a case that the pixel density of the display substrate is high and the isolation structure includes the above-mentioned first annular isolation part, second annular isolation part and third annular isolation part, the spacing between adjacent annular isolation parts may not be sufficient to provide spacers; at this time, by setting a notch in the third annular isolation part, the display substrate can be arranged with a spacer at the position of the notch; moreover, because the two ends of the notch of the third annular isolation part are respectively connected with the two first annular isolation parts adjacent in the first direction or the second direction, the display substrate can better avoid crosstalk among adjacent sub-pixels.

It should be noted that although the third annular isolation portion of the display substrate shown in FIG. 42 is arranged with a notch, however, embodiments of the present disclosure include but are not limited thereto, the third annular isolation part can also be a complete annular structure. In addition, in a case that the first annular isolation part, the second annular isolation part or the third annular isolation part is a complete annular structure, the conductive sublayer in the light-emitting functional layer can be disconnected at the position of the annular isolation structure by controlling the height, depth or other parameters of the annular isolation structure, while a second electrode is not disconnected at the location of the annular isolation structure.

In some examples, as illustrated by FIG. 42, a shape of an orthographic projection of an effective light-emitting region of a first color sub-pixel 201 on the base substrate 110 includes a rounded rectangle; a shape of an orthographic projection of an effective light-emitting region of a second color sub-pixel 202 on the base substrate 110 includes a rounded rectangle; and a shape of an orthographic projection of an effective light-emitting area of a third color sub-pixel 203 on the base substrate 110 includes a rounded rectangle.

In some examples, as illustrated by FIG. 42, the shape of the orthographic projection of the effective light-emitting region of the third color sub-pixel 203 on the base substrate 110 includes a plurality of rounded corner portions, the plurality of rounded corner portions include a first rounded corner portion 2031, an arc radius of the first rounded corner portion 2031 is larger than an arc radius of the other rounded corner portions. At this time, because the arc radius of the first rounded corner portion 2031 is larger, space occupied by the first rounded corner portion 2031 is smaller, thus the notch 1430 of the third annular isolation part 143 can be set near the first rounded corner portion 2031, and the spacer 170 is also correspondingly set near the first rounded corner portion 2031, thus the area on the display substrate can be fully utilized, and the pixel density can be increased. At this time, the first rounded corner portion 2031 is a rounded corner portion with the smallest distance from the first color sub-pixel 201 among the plurality of rounded corner portions of the third color sub-pixel 203.

In some examples, as illustrated by FIG. 42, an orthographic projection of the spacer 170 on the base substrate 110 is located on a line connecting the midpoint of the first rounded corner portion 2031 and a brightness center of the first color sub-pixel 201.

In some examples, as illustrated by FIG. 42, the shape of the orthographic projection of the effective light emitting region of the third color sub-pixel 203 on the base substrate 110 includes a plurality of rounded corner portions, the plurality of rounded corner portions include a first rounded corner portion 2031 and a second rounded corner portion 2032, an arc radius of the first rounded corner portion 2031 is greater than an arc radius of the second rounded corner portion 2031; furthermore, the shape of the orthographic projection of the effective light-emitting region of the third color sub-pixel 203 on the base substrate 110 is axially symmetrical about a line connecting the first rounded corner portion 2031 and the second rounded corner portion 2032.

In some examples, as illustrated by FIG. 42, the shape of the orthographic projection of the effective light emitting region of the first color sub-pixel 201 on the base substrate 110 includes a plurality of rounded corner portions, and the arc radii of these rounded corner portions are equal.

In some examples, as illustrated by FIG. 42, the shape of the orthographic projection of the effective light emitting region of the second color sub-pixel 202 on the base substrate 110 includes a plurality of rounded corner portions, and the arc radii of these rounded corner portions are equal.

In some examples, as illustrated by FIG. 42, an area of the orthogonal projection of the effective light emitting region of the third color sub-pixel 203 on the base substrate 110 is larger than an area of the orthogonal projection of the effective light-emitting region of the first color sub-pixel 201 on the base substrate 110; the area of the orthogonal projection of the effective light-emitting region of the first color sub-pixel 201 on the base substrate 110 is greater than an area of the orthogonal projection of the effective light-emitting region of the second color sub-pixel 202 on the base substrate 110. Of course, embodiments of the present disclosure include but are not limited thereto, the area of the effective light-emitting region of each of the sub-pixels can be set according to actual needs.

In some examples, as illustrated by FIG. 42, a plurality of first color sub-pixels 201 and a plurality of third color sub-pixels 203 are alternately arranged along both the first direction and the second direction to form a plurality of first pixel rows 310 and a plurality of first pixel columns 320, the plurality of second color sub-pixels 202 are arranged in an array along the first direction and the second direction to form a plurality of second pixel rows 330 and a plurality of second pixel columns 340, the plurality of first pixel rows 310 and the plurality of second pixel rows 330 are alternately arranged along the second direction and are staggered from each other in the first direction, the plurality of first pixel columns 320 and the plurality of second pixel columns 340 are alternately arranged along the first direction and are staggered from each other in the second direction. An isolation structure 140 is located between a first color sub-pixel 201 and a third color sub-pixel 203 that are adjacent, and/or, an isolation structure 140 is located between a second color sub-pixel 202 and a third color sub-pixel 203 that are adjacent, and/or, an isolation structure 140 is located between a first color sub-pixels 201 and a second color sub-pixels 202 that are adjacent.

In some examples, the light-emitting efficiency of the third color sub-pixel is less than the light-emitting efficiency of the second color sub-pixel.

For example, the first color sub-pixels 201 are configured to emit red light, the second color sub-pixels 202 are configured to emit green light, and the third color sub-pixels 203 are configured to emit blue light. Of course, the embodiments of the present disclosure include but are not limited thereto.

FIG. 44 is a planar schematic diagram of another display substrate provided by an embodiment of the present disclosure. As illustrated by FIG. 44, the plurality of sub-pixels 200 include a plurality of first color sub-pixels 201, a plurality of second color sub-pixels 202 and a plurality of third color sub-pixels 203; a plurality of first color sub-pixels 201 and a plurality of third color sub-pixels 203 are alternately arranged along both the first direction and the second direction to form a plurality of first pixel rows 310 and a plurality of first pixel columns 320, a plurality of second color sub-pixels 202 are arranged in an array along the first direction and the second direction to form a plurality of second pixel rows 330 and a plurality of second pixel columns 340, the plurality of first pixel rows 310 and the plurality of second pixel rows 330 are alternately arranged along the second direction and staggered from each other in the first direction, and the plurality of first pixel columns 320 and the plurality of second pixel columns 340 are alternately arranged along the first direction and are staggered from each other in the second direction. The isolation structure 140 includes a plurality of first annular isolation parts 141, a plurality of second annular isolation parts 142 and a plurality of third annular isolation parts 143; each of the first annular isolation parts 141 is arranged around a second color sub-pixel 202; each of the second annular isolation parts 142 is arranged around a first color sub-pixel 201; and each of the third annular isolation parts 143 is arranged around a third color sub-pixel 203.

In the display substrate shown in FIG. 44, the charge generation layer 129 in the light-emitting functional layer 120 can be disconnected at the first annular isolation part 141, the second annular isolation part 142 and the third annular isolation part 143, the first annular isolation part 141 can separate the second color sub-pixel 202 from other sub-pixels, thus crosstalk between the second color sub-pixel and adjacent sub-pixels can be avoided; the second annular isolation part 142 can separate the first color sub-pixel 201 from other sub-pixels, thus crosstalk between the first color sub-pixel and adjacent sub-pixels can be avoided; the third annular isolation 143 can separate the third color sub-pixel 203 from other sub-pixels, thus crosstalk between the second color sub-pixel and adjacent sub-pixels can be avoided.

In some examples, as illustrated by FIG. 44, the first annular isolation part 141 includes at least one notch 1410, the second annular isolation 142 includes at least one notch 1420, and the third annular isolation 143 includes at least one notch 1430. In a case that the second electrode on the light-emitting functional layer may break at the locations of the first annular isolation part, the second annular isolation part and the third annular isolation part, by arranging at least one notch on the first annular isolation part, at least one notch is arranged on the second annular isolation part, at least one notch is arranged on the third annular isolation part, the display substrate can prevent the first annular isolation part, the second annular isolation part and the third annular isolation part from completely isolating the sub-pixels, thus the phenomenon that the cathode signal cannot be transmitted can be avoided.

In some examples, as illustrated by FIG. 44, the notches of any two adjacent annular isolations among the first annular isolation part 141, the second annular isolation part 142 and the third annular isolation part 143 are arranged in an offset manner, to ensure that there is at least an isolation structure between two adjacent sub-pixels, thus crosstalk among adjacent sub-pixels can be effectively avoided.

In some examples, as illustrated by FIG. 44, between the first color sub-pixel 201 and the second color sub-pixel 202 that are adjacently arranged, the shortest path for the charge to propagate from the first color sub-pixel 201 to the second color sub-pixel 202 is the position where the center line connecting the effective light-emitting region of the first color sub-pixel 201 and the effective light-emitting region of the second color sub-pixel 202 is located. In order to effectively avoid crosstalk between the first color sub-pixel 201 and the second color sub-pixel 202, an isolation structure needs to be arranged on a center connection line between the effective light-emitting region of the first color sub-pixel 201 and the effective light-emitting region of the second color sub-pixel 202. Therefore, the notch 1410 of the first annular isolation part 141 outside the second color sub-pixel 202 and the notch 1420 of the second annular isolation part 142 outside the first color sub-pixel 201 cannot be located simultaneously on the center line connecting the effective light-emitting region of the first color sub-pixel 201 and the effective light-emitting region of the second color sub-pixel 202. It should be noted that in a case that the charge cannot propagate from the first color sub-pixel 201 to the second color sub-pixel 202 along the shortest path and needs to at least bypass the first annular isolation part 141 or the second annular isolation part 142, because the propagation path of charges is long, the resistance of the charge generation layer in the light-emitting functional layer is large, crosstalk among adjacent sub-pixels can also be effectively avoided.

For example, as illustrated by FIG. 44, between the first color sub-pixel 201 and the second color sub-pixel 202 that are adjacently arranged, the notch 1420 of the second annular isolation part 142 is spaced apart from the center line connecting the effective light-emitting region of the first color sub-pixel 201 and the effective light-emitting region of the second color sub-pixel 202. That is, the notch 1420 of the second annular isolation part 142 is not arranged on the center line connecting the effective light-emitting region of the first color sub-pixel 201 and the effective light-emitting region of the second color sub-pixel 202.

In some examples, as illustrated by FIG. 44, similarly, between the third color sub-pixel 203 and the second color sub-pixel 202 that are adjacently arranged, in order to effectively avoid crosstalk between the third color sub-pixel 203 and the second color sub-pixel 202, an isolation structure also needs to be arranged on the center connection line between the effective light-emitting region of the third color sub-pixel 203 and the effective light-emitting region of the second color sub-pixel 202. Therefore, the notch 1410 of the first annular isolation part 141 outside the third color sub-pixel 202 and the notch 1430 of the third annular isolation part 143 outside the third color sub-pixel 203 cannot be located simultaneously on the center line connecting the effective light-emitting region of the third color sub-pixel 203 and the effective light-emitting region of the second color sub-pixel 202.

For example, as illustrated by FIG. 44, between the third color sub-pixel 203 and the second color sub-pixel 202 that are adjacently arranged, the notch 1420 of the second annular isolation part 142 is spaced apart from the center line connecting the effective light-emitting region of the third color sub-pixel 203 and the effective light-emitting region of the second color sub-pixel 202. That is, the notch 1420 of the second annular isolation part 142 is not arranged on the center line connecting the effective light-emitting region of the third color sub-pixel 203 and the effective light-emitting region of the second color sub-pixel 202.

In some examples, as illustrated by FIG. 44, in the first annular isolation part 141 and the second annular isolation part 142 that are adjacently arranged in the third direction Z, a notch closest to the second annular isolation part 142 among the at least one notch 1410 of the first annular isolation parts 141 is offset from a notch 1420 closest to the first annular isolation part 141 among the at least one notch 1410 of second annular isolation parts 142 in the third direction.

It should be noted that the third direction intersects the first direction and the second direction respectively, and intersects the first direction and the second direction on a same plane; for example, the third direction may be an extension direction of a line connecting the centers of the effective light-emitting areas of the first color sub-pixel and the second-color sub-pixel that are adjacent.

In some examples, as illustrated by FIG. 44, in the first annular isolation part 141 and the third annular isolation part 143 that are adjacently arranged in the third direction Z, a notch closest to the third annular isolation part 142 among the at least one notch 1410 of the first annular isolation parts 141 is offset from a notch 1430 closest to the first annular isolation part 141 among the at least one notch 1410 of third annular isolation parts 142 in the third direction.

In some examples, as illustrated by FIG. 44, the shape of the orthographic projection of the effective light-emitting region of the second color sub-pixel 202 on the base substrate 110 includes a rounded rectangle, which includes four rounded corners; at this time, the first annular isolation part 141 includes four notches 1410, and these four notches 1410 are respectively arranged corresponding to the four rounded corners of the effective light-emitting region of the second color sub-pixel 202. The shape of the orthographic projection of the effective light-emitting region of the first color sub-pixel 201 on the base substrate includes a rounded rectangle, which includes four sides; at this time, the second annular isolation part 142 includes four notches 1420, and these four notches 1420 are respectively arranged corresponding to the four sides of the effective light-emitting region of the first color sub-pixel 201. The shape of the orthographic projection of the effective light-emitting region of the first color sub-pixel 203 on the base substrate includes a rounded rectangle, which includes four sides; at this time, the third annular isolation part 143 includes four notches 1430, and these four notches 1430 are respectively arranged corresponding to the four sides of the effective light-emitting region of the third color sub-pixel 203. With this arrangement, the display substrate can ensure that the notches in the annular isolation parts outside the two adjacent sub-pixels are staggered, thus it is ensured that there is at least an isolation structure between two adjacent sub-pixels.

In some examples, as illustrated by FIG. 44, the display substrate 100 further includes spacers 170; at this time, the annular isolation part near the spacer 170 is different from the annular isolation parts at other positions. The spacer 170 is surrounded by one first color sub-pixel 201, two second color sub-pixels 202 and one third color sub-pixel 203; the first color sub-pixel 201 and the third color sub-pixel 203 are respectively arranged on two sides of the spacer 170 along the second direction Y; the two second color sub-pixels 202 are respectively arranged on two sides of the spacer 170 along the first direction X.

In some examples, as illustrated by FIG. 44, the second annular isolation part 142 outside the first color sub-pixel 201 includes a spacer notch 1425 near the spacer 170, the third annular isolation part 143 outside the third color sub-pixel 203 includes a spacer notch 1435 at a position close to the spacer 170. In this way, the display substrate provides sufficient space for placing spacers. Moreover, because the spacers themselves also have a certain isolating effect, the above spacer notch will not cause crosstalk between the first color sub-pixel and the third color sub-pixel.

In some examples, as illustrated by FIG. 44, because the second annular isolation part 142 is arranged with the above-mentioned spacer notch 1425, the third isolation part 143 is arranged in the above-mentioned spacer notch 1435; the two first annular isolation parts 141 located on two sides of the spacer 170 are not arranged with notches close to the spacer 170, thus crosstalk among adjacent sub-pixels can be effectively avoided.

In some examples, as illustrated by FIG. 44, the size of the spacer 170 in the second direction Y is greater than the size of the spacer 170 in the first direction X.

For example, as illustrated by FIG. 44, the shape of the orthographic projection of the effective light-emitting region of the third color sub-pixel 203 on the base substrate 110 includes a plurality of rounded corner portions, the plurality of rounded corner portions include a first rounded corner portion 2031, an arc radius of the first rounded corner portion 2031 is larger than the arc radii of the other rounded corner portions. At this time, because the arc radius of the first rounded corner portion 2031 is relatively large, the space occupied by the first rounded corner portion 2031 is smaller, thus the spacer notch 1435 can be arranged near the rounded corner portion 2031, so that the area on the display substrate can be fully utilized, and the pixel density can be increased. At this time, the first rounded corner portion 2031 is a rounded corner part with the smallest distance from the first color sub-pixel 201 among the plurality of rounded corner portions of the third color sub-pixel 203.

In some examples, as illustrated by FIG. 44, the shape of the orthographic projection of the effective light-emitting region of the third color sub-pixel 203 on the base substrate 110 includes a plurality of rounded corner portions, the plurality of rounded corner portions include a first rounded corner portion 2031 and a second rounded corner portion 2032, an arc radius of the first rounded corner portion 2031 is greater than the arc radius of the second rounded corner portion 2031; furthermore, the shape of the orthographic projection of the effective light-emitting region of the third color sub-pixel 203 on the base substrate 110 is axially symmetrical with respect to the line connecting the first round portion 2031 and the second round portion 2032.

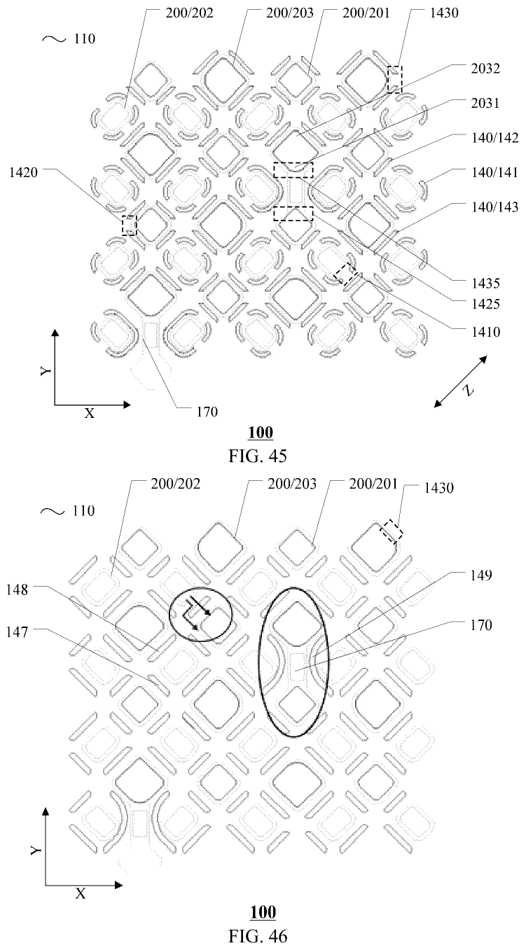

FIG. 45 is a planar schematic diagram of another display substrate provided by an embodiment of the present disclosure. As illustrated by FIG. 45, the display substrate shown in FIG. 45 and the display substrate shown in FIG. 44 adopt a same pixel arrangement. In this case, the isolation structure 140 includes a plurality of first annular isolation parts 141, a plurality of second annular isolation parts 142 and a plurality of third annular isolation parts 143; each of the plurality of first annular isolation parts 141 is arranged around a second color sub-pixel 202; each of the plurality of second annular isolation parts 142 is arranged around a first color sub-pixel 201; each of the plurality of third annular isolation parts 143 is arranged around a third color sub-pixel 203, thus crosstalk between the second color sub-pixel and adjacent sub-pixels can be avoided.

In some examples, as illustrated by FIG. 45, the first annular isolation part 141 includes at least one notch 1410, the second annular isolation part 142 includes at least one notch 1420, and the third annular isolation part 143 includes at least one notch 1430. Moreover, notches of any two adjacent annular isolation parts among the first annular isolation part 141, the second annular isolation part 142 and the third annular isolation part 143 are arranged in an offset manner, to ensure that there is at least an isolation structure between two adjacent sub-pixels, thus crosstalk among adjacent sub-pixels can be effectively avoided.

In some examples, as illustrated by FIG. 45, between the first color sub-pixel 201 and the second color sub-pixel 202 that are adjacently arranged, a notch 1410 of the first annular isolation part 141 is spaced apart from a center line connecting the effective light-emitting region of the first color sub-pixel 201 and the effective light-emitting region of the second color sub-pixel 202. That is, the notch 1410 of the first annular isolation part 141 is not arranged on the center line connecting the effective light-emitting region of the first color sub-pixel 201 and the effective light-emitting region of the second color sub-pixel 202.

In some examples, as illustrated by FIG. 45, between the third color sub-pixel 203 and the second color sub-pixel 202 that are adjacently arranged, a notch 1430 of the third annular isolation part 143 is spaced apart from a center line connecting the effective light-emitting region of the third color sub-pixel 203 and the effective light-emitting region of the second color sub-pixel 202. That is, the notch 1430 of the third annular isolation part 143 is not arranged on the center line connecting the effective light-emitting region of the third color sub-pixel 203 and the effective light-emitting region of the second color sub-pixel 202.

In some examples, as illustrated by FIG. 45, the shape of the orthographic projection of the effective light-emitting region of the second color sub-pixel 202 on the base substrate 110 includes a rounded rectangle, which includes four sides; at this time, the first annular isolation part 141 includes four notches 1410, and these four notches 1410 are respectively arranged corresponding to the four sides of the effective light-emitting region of the second color sub-pixel 202. The shape of the orthographic projection of the effective light-emitting region of the first color sub-pixel 201 on the base substrate includes a rounded rectangle, which includes four rounded corners; at this time, the second annular isolation part 142 includes four notches 1420, and these four notches 1420 are respectively arranged corresponding to the four rounded corners of the effective light-emitting region of the first color sub-pixel 201. The shape of the orthographic projection of the effective light-emitting region of the first color sub-pixel 203 on the base substrate includes a rounded rectangle, which includes four rounded corners; at this time, the third annular isolation part 143 includes four notches 1430, and these four notches 1430 are respectively arranged corresponding to the four rounded corners of the effective light-emitting region of the third color sub-pixel 203. With this arrangement, the display substrate can ensure that the notches in the annular isolation parts outside the two adjacent sub-pixels are staggered, thus it is ensured that there is at least an isolation structure between two adjacent sub-pixels.

In some examples, as illustrated by FIG. 45, the display substrate 100 further includes a spacer 170; at this time, the annular isolation part near the spacer 170 is different from the annular isolation parts at other positions. The spacer 170 is surrounded by one first color sub-pixel 201, two second color sub-pixels 202 and one third color sub-pixel 203; the first color sub-pixel 201 and the third color sub-pixel 203 are respectively arranged on two sides of the spacer 170 along the second direction Y; the two second color sub-pixels 202 are respectively arranged on two sides of the spacer 170 along the first direction X.

In some examples, as illustrated by FIG. 45, a second annular isolation part 142 outside a first color sub-pixel 201 near a spacer 170 includes a spacer notch 1425, no isolation structure is arranged at a location of the spacer notch 1425; the spacer notch 1425 extends from an interval between the first color sub-pixel 201 and a second color sub-pixel 202, through an interval between the first color sub-pixel 201 and the spacer 170, to the interval between the first color sub-pixel 201 and another second color sub-pixel 202. That is, the second annular isolation part 142 outside the first color sub-pixel 201 near the spacer further includes two strip-shaped isolation parts. A third annular isolation part 143 outside a third color sub-pixel 203 near the spacer 170 includes a spacer notch 1435, and no isolation structure is arranged at the location of the spacer notch 1435; the spacer notch 1435 extends from the interval between the third color sub-pixel 203 and a second color sub-pixel 202, through the interval between the third color sub-pixel 203 and the spacer 170, to the interval between the third color sub-pixel 203 and another second color sub-pixel 202. That is, the third annular isolation part 143 outside the third color sub-pixel 203 near the spacer only includes two strip-shaped isolation parts. In this way, the display substrate provides sufficient space for placing spacers. Moreover, because the spacers themselves also have a certain isolating effect, the above spacer notches will not cause crosstalk between the first color sub-pixel and the third color sub-pixel.

In some examples, as illustrated by FIG. 45, because the second annular isolation part 142 is arranged with the above-mentioned spacer notch 1425, the third isolation part 143 is arranged in the above-mentioned spacer notch 1435; the two first annular isolation parts 141 located on two sides of the spacer 170 are not arranged with notches close to the spacer 170, thus crosstalk among adjacent sub-pixels can be effectively avoided.

In some examples, as illustrated by FIG. 45, the size of the spacer 170 in the second direction Y is greater than the size of the spacer 170 in the first direction X.

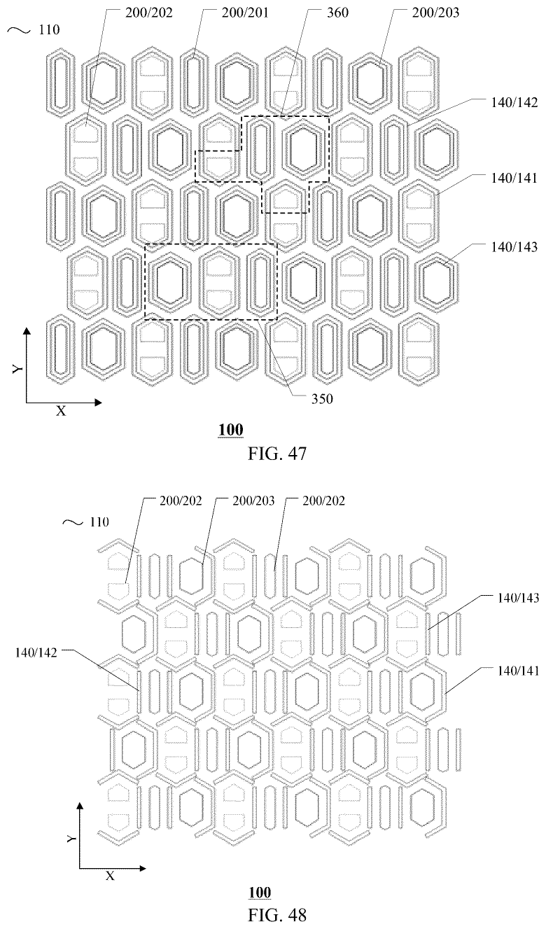

FIG. 46 is a planar schematic diagram of another display substrate provided by an embodiment of the present disclosure; as illustrated by FIG. 46, the plurality of sub-pixels 200 include a plurality of first color sub-pixels 201, a plurality of second color sub-pixels 202 and a plurality of third color sub-pixels 203; the isolation structure 140 includes a third strip-shaped isolation part 147 and a fourth strip-shaped isolation part 148; the third strip-shaped isolation 147 is located between a first color sub-pixel 201 and a second color sub-pixel 202 that are adjacent; the fourth strip-shaped isolation part 148 is located between a third color sub-pixel 203 and a second color sub-pixel 202 that are adjacent.

In some examples, as illustrated by FIG. 46, the extending direction of the third strip-shaped isolation part 147 is perpendicular to a center line connecting the effective light-emitting region of the first color sub-pixel 201 and the effective light-emitting region of the second color sub-pixel 202 that are adjacent; the extending direction of the fourth strip-shaped isolation part 148 is perpendicular to a center line connecting the effective light-emitting region of the third color sub-pixel 203 and the effective light-emitting region of the second color sub-pixel 202 that are adjacent.

In some examples, as illustrated by FIG. 46, an orthographic projection of an effective light-emitting region of a first color sub-pixel 201 on the base substrate 110 is a rounded rectangle, the size (that is, length) of the third strip-shaped isolation part 147 in its extending direction is from 0.8 to 1 time a side length of the effective light-emitting region of the first color sub-pixel 201.

In some examples, as illustrated by FIG. 46, an orthographic projection of an effective light-emitting region of a third color sub-pixel 201 on the base substrate 110 is a rounded rectangle, the size (that is, length) of the fourth strip-shaped isolation part 148 in its extending direction is from 0.8 to 1 time a side length of the effective light-emitting region of the third color sub-pixel 203.

In some examples, as illustrated by FIG. 46, the display substrate 100 further includes a spacer 170; at this time, the isolation structure near the spacer 170 is different from the isolation structures at other positions. The spacer 170 is surrounded by one first color sub-pixel 201, two second color sub-pixels 202 and one third color sub-pixel 203; the first color sub-pixel 201 and the third color sub-pixel 203 are respectively arranged on two sides of the spacer 170 along the second direction Y; and the two second color sub-pixels 202 are respectively arranged on two sides of the spacer 170 along the first direction X.

In some examples, as illustrated by FIG. 46, the isolation structure 140 includes an arc-shaped isolation part 149, the arc-shaped isolation part 149 is located between the second color sub-pixel 202 and the spacer 170; furthermore, the arc-shaped isolation part 149 extends from the interval between the second color sub-pixel 202 and the third color sub-pixel 203 to the interval between the second color sub-pixel 202 and the first color sub-pixel 201; that is to say, one end of the arc-shaped isolation part 149 is located between the second color sub-pixel 202 and the third color sub-pixel 203, can play a role of the fourth strip-shaped isolation part 148; the other end of the arc-shaped isolation part 149 is located between the second color sub-pixel 202 and the first color sub-pixel 201, can play a role of the third strip-shaped isolation part 147; and the middle part of the arc-shaped isolation part 149 is located between the second color sub-pixel 202 and the spacer 170.

FIG. 47 is a planar schematic diagram of another display substrate provided by an embodiment of the present disclosure. As illustrated by FIG. 47, the plurality of sub-pixels 200 include a plurality of first color sub-pixels 201, a plurality of second color sub-pixels 202 and a plurality of third color sub-pixels 203; the isolation structure 140 includes a plurality of first annular isolation parts 141, a plurality of second annular isolation parts 142 and a plurality of third annular isolation parts 143; each of the plurality of first annular isolation parts 141 is arranged around two adjacent second color sub-pixels 202; each of the plurality of second annular isolation parts 142 is arranged around a first color sub-pixel 201; each of the plurality of third annular isolation parts 143 is arranged around a third color sub-pixel 203. Therefore, the charge generation layer 129 in the light-emitting functional layer 120 can be disconnected at the first annular isolation parts 141, the second annular isolation parts 142 and the third annular isolation parts 143, each of the first annular isolation parts 141 can separate two adjacent second color sub-pixels 202 from other sub-pixels, thus crosstalk between the second color sub-pixel and adjacent sub-pixels can be avoided; the first annular isolation parts 141 can separate the first color sub-pixel 201 from other sub-pixels, thus crosstalk between the first color sub-pixel and adjacent sub-pixels can be avoided; the third annular isolation parts 143 can separate the third color sub-pixel 203 from other sub-pixels, thus crosstalk between the second color sub-pixel and adjacent sub-pixels can be avoided.

In some examples, as illustrated by FIG. 47, there are two annular isolation parts between any two adjacent sub-pixels 200, thus crosstalk among adjacent sub-pixels can be further avoided.

In some examples, as illustrated by FIG. 47, a plurality of sub-pixels 200 are divided into a plurality of sub-pixel groups 350, each of the plurality of sub-pixel groups 350 includes one first color sub-pixel 201, two second color sub-pixels 202 and one third color sub-pixel 203; in each of the plurality of sub-pixel groups 350, the first color sub-pixel 201 and the third color sub-pixel 203 are arranged along the first direction, the two second color sub-pixels 202 are arranged adjacently in the second direction and are located between the first color sub-pixel 201 and the third color sub-pixel 203. It should be noted that the above concept of pixel group is only used to describe a pixel arrangement structure of a plurality of sub-pixels, and does not limit one pixel group to be used to display one pixel, or to be driven by a same gate line.

For example, as illustrated by FIG. 47, the four sub-pixels in a dashed box 360 may be driven by a same gate line. Of course, the embodiments of the present disclosure include but are not limited thereto, and the driving of sub-pixels can be set according to actual needs.

FIG. 48 is a planar schematic diagram of another display substrate provided by an embodiment of the present disclosure. As illustrated by FIG. 48, the plurality of sub-pixels 200 include a plurality of first-color sub-pixels 201, a plurality of second-color sub-pixels 202 and a plurality of third-color sub-pixels 203. The isolation structure 140 includes a plurality of first annular isolation parts 141, a plurality of second annular isolation parts 142 and a plurality of third annular isolation parts 143; each of the plurality of first annular isolation parts 141 is arranged around two adjacent second color sub-pixels 202; each of the plurality of second annular isolation parts 142 is arranged around a first color sub-pixel 201; each of the plurality of third annular isolation parts 143 is arranged around a third color sub-pixel 203. In this way, the charge generation layer 129 in the light-emitting functional layer 120 can be disconnected at the first annular isolation parts 141, the second annular isolation parts 142 and the third annular isolation parts 143, each of the first annular isolation parts 141 can separate two adjacent second color sub-pixels 202 from other sub-pixels, thus crosstalk between the second color sub-pixel and adjacent sub-pixels can be avoided; each of the first annular isolation parts 141 can separate the first color sub-pixel 201 from other sub-pixels, thus crosstalk between the first color sub-pixel and adjacent sub-pixels can be avoided; the third annular isolation parts 143 can separate the third color sub-pixel 203 from other sub-pixels, thus crosstalk between the second color sub-pixel and adjacent sub-pixels can be avoided.

In some examples, as illustrated by FIG. 48, any two adjacent annular isolation parts among the plurality of first annular isolation parts 141, the plurality of second annular isolation parts 142 and the plurality of third annular isolation parts 143 share an isolation edge. In this way, there is only one isolation structure between two adjacent sub-pixels, thus a width of an interval between two adjacent sub-pixels can be reduced, to increase the pixel density.

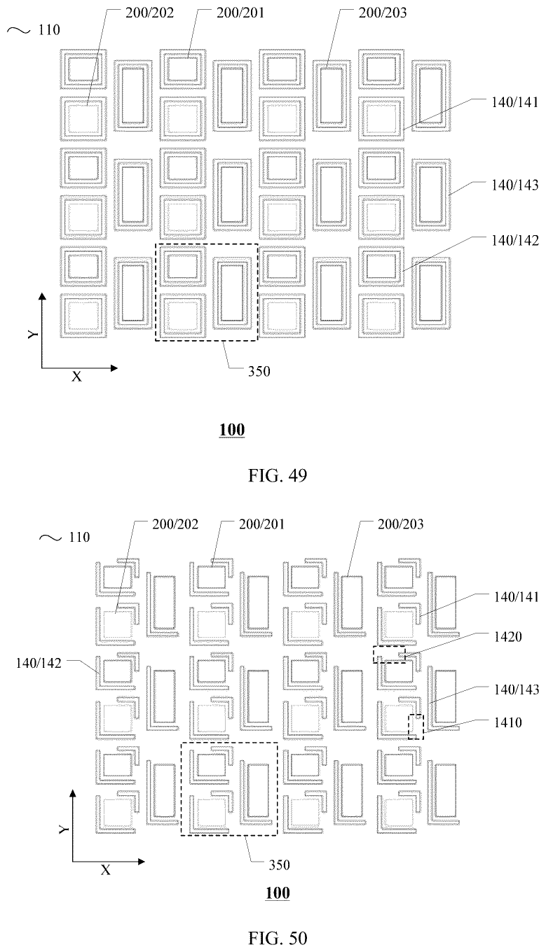

FIG. 49 is a planar schematic diagram of another display substrate provided by an embodiment of the present disclosure. As illustrated by FIG. 49, the plurality of sub-pixels 200 include a plurality of first color sub-pixels 201, a plurality of second color sub-pixels 202 and a plurality of third color sub-pixels 203; the isolation structure 140 includes a plurality of first annular isolation parts 141 and a plurality of second annular isolation parts 142, each of the plurality of first annular isolation parts 141 is arranged around a second color sub-pixel 202, and each of the plurality of second annular isolation parts 142 is arranged around a first color sub-pixel 201.

In some examples, as illustrated by FIG. 49, the isolation structure 140 includes a plurality of first annular isolation parts 141, a plurality of second annular isolation parts 142 and a plurality of third annular isolation parts 143; each of the plurality of first annular isolation parts 141 is arranged around one of the second color sub-pixels 202; each of the plurality of second annular isolation parts 142 is arranged around a first color sub-pixel 201; each of the plurality of third annular isolation parts 143 is arranged around a third color sub-pixel 203. In this way, the charge generation layer 129 in the light-emitting functional layer 120 can be disconnected at the first annular isolation parts 141, the second annular isolation parts 142 and the third annular isolation parts 143, each of the first annular isolation parts 141 can separate the second color sub-pixel 202 from other sub-pixels, thus crosstalk between the second color sub-pixel and adjacent sub-pixels can be avoided; each of the first annular isolation parts 141 can separate the first color sub-pixel 201 from other sub-pixels, thus crosstalk between the first color sub-pixel and adjacent sub-pixels can be avoided; each of the third annular isolation parts 143 can separate the third color sub-pixel 203 from other sub-pixels. Thus, crosstalk between the second color sub-pixel and adjacent sub-pixels can be avoided.

In some examples, as illustrated by FIG. 49, there are two annular isolation parts between any two adjacent sub-pixels 200, thus crosstalk among adjacent sub-pixels can be further avoided.

In some examples, as illustrated by FIG. 49, a plurality of sub-pixels 200 are divided into a plurality of sub-pixel groups 350, each of the plurality of sub-pixel groups 350 includes a first color sub-pixel 201, a second color sub-pixel 202 and a third color sub-pixel 203; in each of the plurality of sub-pixel groups 350, the first color sub-pixel 201 or the second color sub-pixel 202 and the third color sub-pixel 203 are arranged along the first direction, the first color sub-pixel 201 and the second color sub-pixel 202 are arranged along the second direction.

FIG. 50 is a planar schematic diagram of another display substrate provided by an embodiment of the present disclosure. As illustrated by FIG. 50, the plurality of sub-pixels 200 include a plurality of first color sub-pixels 201, a plurality of second color sub-pixels 202 and a plurality of third color sub-pixels 203; the isolation structure 140 includes a plurality of first annular isolation parts 141 and a plurality of second annular isolation parts 142; the plurality of first annular isolation parts 141 are arranged in one-to-one correspondence with the plurality of second color sub-pixels 202, each of the plurality of first annular isolation parts 141 is arranged around one of the second color sub-pixels 202; the plurality of second annular isolation parts 142 are arranged in one-to-one correspondence with the plurality of first color sub-pixels 201, each of the plurality of second annular isolation parts 142 is arranged around one first color sub-pixel 201. In this way, the charge generation layer 129 in the light-emitting functional layer 120 can be disconnected at the first annular isolation parts 141, the second annular isolation parts 142, and the third annular isolation parts 143, each of the first annular isolation parts 141 can separate the second color sub-pixel 202 from other sub-pixels, thus crosstalk between the second color sub-pixel and adjacent sub-pixels can be avoided; each of the first annular isolation parts 141 can separate the first color sub-pixel 201 from other sub-pixels, thus crosstalk between the first color sub-pixel and adjacent sub-pixels can be avoided; each of the third annular isolation parts 143 can separate the third color sub-pixel 203 from other sub-pixels, thus crosstalk between the second color sub-pixel and adjacent sub-pixels can be avoided.

In some examples, as illustrated by FIG. 50, the plurality of sub-pixels 200 are divided into a plurality of sub-pixel groups 350, each of the plurality of sub-pixel groups 350 includes a first color sub-pixel 201, a second color sub-pixel 202 and a third color sub-pixel 203; in each of the plurality of sub-pixel groups 350, the first color sub-pixel 201 or the second color sub-pixel 202 and the third color sub-pixel 203 are arranged along the first direction, and the first color sub-pixel 201 and the second color sub-pixel 202 are arranged along the second direction.

In some examples, as illustrated by FIG. 50, the first annular isolation parts 141 include at least one notch 1410, the second annular isolation parts 142 include at least one notch 1420; at this time, the isolation structure 140 also includes a plurality of L-shaped isolation parts 146, the plurality of L-shaped isolation parts 146 are arranged in one-to-one correspondence with the plurality of third color sub-pixels 203. Each of the plurality of L-shaped isolation parts 146 is arranged around one third color sub-pixel 203. In each of the plurality of pixel groups 350, a L-shaped isolation part 146 is directly opposite to a notch 1410 on a first annular isolation part 141 close to the third color sub-pixel 203 and a notch 1420 on a second annular isolation part 142 close to the third color sub-pixel 203; that is to say, an orthographic projection of the L-shaped isolation 146 on the reference straight line extending along the second direction Y is respectively overlapped with an orthographic projection of the notch 1410 on the first annular isolation part 141 close to the third color sub-pixel 20 on the reference straight line and an orthographic projection of the notch 1420 on the second annular isolation part 142 close to the third color sub-pixel 203 on the reference straight line.

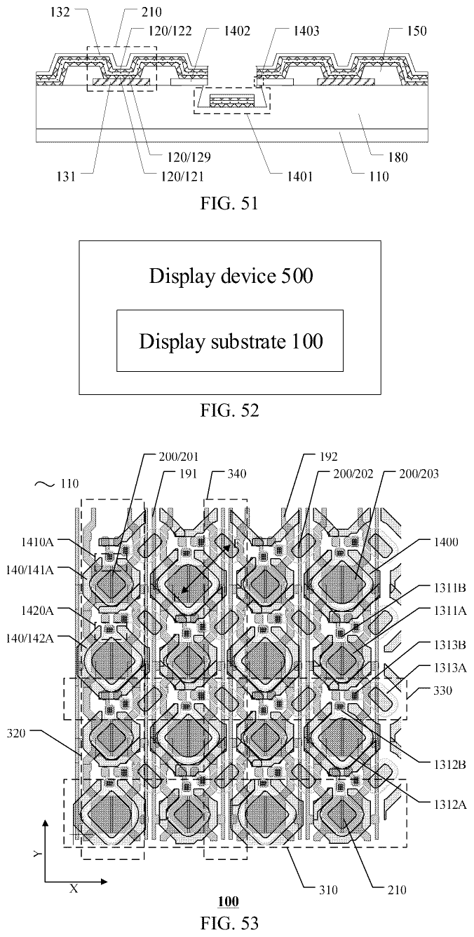

FIG. 51 is a partial cross-sectional schematic diagram of a display substrate provided by an embodiment of the present disclosure. As illustrated by FIG. 51, the isolation structure 140 includes a groove 1401 and a shielding portion 1402; the shielding portion 1402 is located at the edge of the groove 1401 and protrudes into the groove 1401 to form a protruding portion 1403 covering a part of an opening of the groove 1401, and the conductive sub-layer 129 of the light-emitting functional layer 120 is disconnected at the protruding portion 1403 of the shielding portion 1402.

For example, as illustrated by FIG. 51, the shielding portion 1402 protrudes into the groove 1401 relative to the edge of the groove 1401 to form a protruding portion 1403; at this time, the protruding portion 1403 of the shielding portion 1402 is suspended in the air, the protruding part 1403 blocks an edge portion of the opening of the groove 1401.

In some examples, as illustrated by FIG. 51, the groove 1401 is respectively arranged with shielding portions 1402 on two edges of the groove 1401 in the arrangement direction of the two adjacent sub-pixels 200.

In some examples, as illustrated by FIG. 51, the second electrode 132 is disconnected at the position where the isolation structure 140 is located.

In some examples, as illustrated by FIG. 51, the display substrate 100 further includes a planarization layer 180; the groove 1401 is arranged within the planarization layer 180; a portion of the shielding portion 1402 except the protruding part 1403 may be located between the planarization layer 180 and the pixel defining layer 150.

For example, a ratio of a size of the protruding portion 1403 of the shielding portion 1402 protruding into the groove 1401 to a size of the shielding portion 1402 may be from 0.1 to 0.5. For example, the ratio of the size of the protruding portion 310 of the shielding portion 1402 protruding into the groove 1401 to the size of the shielding portion 1402 may be from 0.2 to 0.4. For example, the size of the protruding portion 1403 of the shielding portion 1402 protruding into the groove 1401 is not less than 0.1 microns. For example, the size of the protruding portion 1403 of the shielding portion 1402 protruding into the groove 1401 is not less than 0.2 microns.

For example, a distance between two shielding portions 1402 located between adjacent sub-pixels may be from 2 microns to 15 microns. For example, the distance between two shielding parts 1402 located between adjacent sub-pixels may be from 5 microns to 10 microns. For example, the distance between two shielding portions 1402 located between adjacent sub-pixels may be from 3 microns to 7 microns. For example, the distance between two shielding portions 1402 located between adjacent sub-pixels may be from 4 microns to 12 microns.

For example, as illustrated by FIG. 51, the portion of the shielding portion 1402 except the protruding portion 1403 is in contact with a surface of the planarization layer 180 away from the base substrate 110.

For example, the shielding portion 1402 can be made of a same material as the first electrodes 131, and is located on a same film layer as the first electrodes 131. In this way, the shielding portion 1402 can be formed together in the process of patterning the first electrodes 131, thus a mask process can be saved. Of course, the embodiments of the present disclosure include but are not limited thereto, and the shielding part can also be made of other materials, such as inorganic materials.

For example, the material of the planarization layer 180 may be an organic material, such as one or a combination of resin, acrylic or polyethylene terephthalate, polyimide, polyamide, polycarbonate, epoxy resin, etc.

In some examples, other film layers are disposed between the planarization layer 180 and the base substrate 110, these other film layers may include a gate insulating layer, an interlayer insulating layer, each film layer in the pixel circuit (for example, including thin film transistors, storage capacitors and other structures), data lines, gate lines, power signal lines, reset power signal lines, reset control signal lines, light emission control signal lines and other film layers, or structure.

At least one embodiment of the present disclosure further provides a display device. FIG. 52 is a schematic diagram of a display device provided by an embodiment of the present disclosure. As illustrated by FIG. 52, the display device 500 further includes a display substrate 100. The display substrate sets an isolation structure between adjacent sub-pixels, and so that the charge generation layer in the light-emitting functional layer is disconnected at the location of the isolation structure, thus crosstalk among adjacent sub-pixels caused by the charge generation layer with higher conductivity is avoided. In this way, a display device including the display substrate can therefore also avoid crosstalk among adjacent sub-pixels, so the display device has higher product yield and higher display quality.

On the other hand, the display substrate can increase the pixel density while adopting a dual-layer light emitting (Tandem EL) design, thus a display device including the display substrate has the advantages of long life, low power consumption, high brightness, and high resolution.

For example, the display device may be a display device such as an organic light-emitting diode display device, as well as any product or component with a display function such as a television, a digital camera, a mobile phone, a watch, a tablet computer, a notebook computer, a navigator, etc., and the embodiment is not limited thereto.

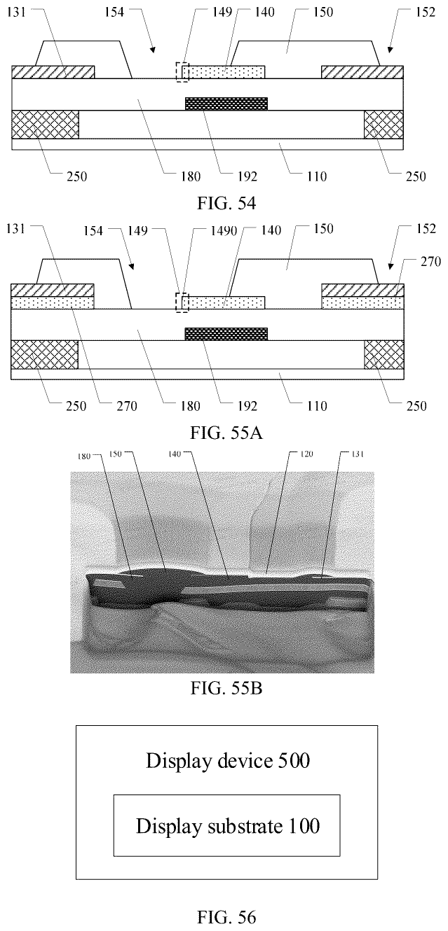

In order to better ensure the continuity of the second electrode while effectively isolating the charge generation layer of adjacent sub-pixels, an embodiment of the present disclosure also provides another display substrate. FIG. 53 is a planar schematic diagram of another display substrate provided by an embodiment of the present disclosure; and FIG. 54 is a cross-sectional schematic diagram of a display substrate along line EF in FIG. 53 according to an embodiment of the present disclosure.

As illustrated by FIGS. 53 and 54, the display substrate 100 includes a base substrate 110 and a plurality of sub-pixels 200 located on the base substrate 110; the plurality of sub-pixels 200 are arranged in an array on the base substrate 110, each of the plurality of sub-pixel 200 includes a light-emitting element 210 and a pixel driving circuit 250 that drives the light-emitting element 210 to emit light. Each of the light-emitting elements 210 includes a light-emitting functional layer, a first electrode and a second electrode; the light-emitting functional layer may include a plurality of sub-functional layers, and the plurality of sub-functional layers may include charge generation layers with higher conductivity. It should be noted that cross-sectional structures of the light-emitting elements can be referred to the relevant description in FIG. 2, which will not be described again herein.

For example, the pixel driving circuit 250 can be electrically connected with the first electrode 131 in the correspondingly arranged light-emitting element 210, thus the light-emitting element 210 can be driven to emit light. The first electrode 131 may be an anode, and the second electrode 132 may be a cathode; a plurality of sub-pixels 200 may share one second electrode 132, that is, a plurality of sub-pixels 200 may share one cathode.

For example, the cathode may be formed from a material with high conductivity and low work function, for example, the cathode may be made of metallic material. For example, the anode may be formed from a transparent conductive material with a high work function.

As illustrated by FIGS. 53 and 54, the display substrate 100 also includes an isolation structure 140, the isolation structure 140 is located on the base substrate 110 and is between adjacent sub-pixels 200; in this way, the charge generation layer 129 in the light-emitting functional layer 120 is disconnected at the position where the isolation structure 140 is located. The plurality of sub-pixels 200 include a plurality of first color sub-pixels 201, a plurality of second color sub-pixels 202 and a plurality of third color sub-pixels 203, the isolation structure 140 includes a plurality of annular isolation parts 1400, each of the annular isolation parts 1400 surrounds one of a first color sub-pixel 201, a second color sub-pixel 202 and a third color sub-pixel 203; that is to say, each of the annular isolation parts 1400 surrounds a first color sub-pixel 201, a second color sub-pixel 202, or a third color sub-pixel 203. In addition, the above-mentioned annular isolation may be a closed annular shape or a non-closed annular shape, such as a ring shape including at least one notch.

In the display substrate provided by the embodiment of the present disclosure, by arranging an isolation structure between adjacent sub-pixels, the charge generation layer in the light-emitting functional layer is disconnected at the position where the isolation structure is located, thus crosstalk among adjacent sub-pixels caused by the charge generation layer with higher conductivity is avoided. Moreover, because the isolation structure includes a plurality of annular isolation parts, and each of the annular isolation parts surrounds a first color sub-pixel, a second color sub-pixel or a third color sub-pixel, this isolation structure can achieve isolating of most adjacent sub-pixels through a simple annular isolation part, thus crosstalk among adjacent sub-pixels is avoided. On the other hand, because the display substrate can avoid crosstalk among adjacent sub-pixels through the isolation structure, the display substrate can increase the pixel density while adopting a dual-layer light-emitting (Tandem EL) design. Therefore, the display substrate can have the advantages of long life, low power consumption, high brightness, and high resolution.

In some examples, as illustrated by FIGS. 53 and 54, in the display substrate 100, a number of second color sub-pixels 202 is greater than a number of first color sub-pixels 201; or, the number of second color sub-pixels 202 is greater than a number of third color sub-pixels 203; or the number of second color sub-pixels 202 is greater than the number of first color sub-pixels 201 and the number of third color sub-pixels 203. In this way, by arranging the first annular pixel isolation part 141A outside the smaller number of first color sub-pixels 201 and arranging the second annular pixel isolation part 142B outside the smaller number of third color sub-pixels 203, most adjacent sub-pixels on the display substrate can be separated, thus crosstalk among adjacent sub-pixels can be effectively avoided.

In some examples, as illustrated by FIGS. 53 and 54, in the display substrate 100, the number of the second color sub-pixels 202 is approximately twice the number of the first color sub-pixels 201 or the third color sub-pixels 203.

In some examples, as illustrated by FIGS. 53 and 54, the isolation structure 140 also does not need to be arranged with a strip-shaped isolation as illustrated by FIG. 1, and can also separate a first color sub-pixel and a third color sub-pixel that are adjacent, and separate adjacent first color sub-pixels and third color sub-pixels.

In some examples, the light-emitting functional layer includes a first light-emitting layer and a second light-emitting layer located on two sides of the conductive sub-layer in a direction perpendicular to the base substrate respectively, and the conductive sub-layer is a charge generation layer. In this way, the display substrate can achieve a double-layer light-emitting (Tandem EL) design, so the display substrate has the advantages of long life, low power consumption, and high brightness. It should be noted that the cross-sectional structure of the light-emitting functional layer can be referred to the relevant description of FIG. 40, which will not be described in detail herein.

In some examples, conductivity of the conductive sub-layer is greater than the conductivity of the first light-emitting layer and the conductivity of the second light-emitting layer, and is less than conductivity of the second electrode.

In some examples, as illustrated by FIGS. 53 and 54, the first light-emitting layer 121 is located on a side of the conductive sublayer 129 close to the base substrate 110; and the second light emitting layer 122 is located on a side of the conductive sub-layer 129 away from the base substrate 110.

In some examples, as illustrated by FIGS. 53 and 54, the plurality of annular isolation parts 1400 includes a plurality of first annular pixel isolation parts 141A and a plurality of second annular pixel isolation parts 142A, a plurality of first annular pixel isolation parts 141A and a plurality of first color sub-pixels 201 are arranged correspondingly, a plurality of second annular pixel isolation parts 142A and a plurality of third color sub-pixels 203 are arranged correspondingly; each of the plurality of first annular pixel isolation parts 141A surrounds a first color sub-pixel 201, each of the plurality of second annular pixel isolation parts 142A surrounds one third color sub-pixel 203. In this way, the plurality of first annular pixel isolation parts 141A can separate the plurality of first color sub-pixels 201 from other adjacent sub-pixels, the plurality of second annular pixel isolation parts 142 can separate the plurality of third color sub-pixels 203 from other adjacent sub-pixels, in this way, the display substrate can effectively avoid crosstalk among adjacent sub-pixels.

In some examples, as illustrated by FIGS. 53 and 54, the isolation structure 140 between the first color sub-pixels 201 and the second color sub-pixels 202 that are adjacent only includes s first annular pixel isolation part 141A, the isolation structure 140 between the third color sub-pixel 203 and the second color sub-pixel 202 that are adjacent only includes a second annular pixel isolation part 142A. At this time, there is no need to set up an annular isolation structure around the second color sub-pixel, and the second electrode may be continuously arranged around the second color sub-pixel. In this way, the display substrate can effectively isolate the charge generation layers of adjacent sub-pixels through the above-mentioned isolation structure, so that the continuity of the second electrode is maximized, thus the second electrode is easy to transmit cathode signals.

In some examples, as illustrated by FIGS. 53 and 54, the first annular pixel isolation part 141A includes a notch 1410A, the notch 1410A is located on a diagonal extension of the effective light-emitting region of the first color sub-pixel 201. The first electrode 131 of the first color sub-pixel 201 includes a first body part 1311A and a first connection part 1311B, the first connection part 1311B is connected with the first main body part 1311A, and is configured to be connected with the pixel driving circuit 250; and the first connection part 1311B is located at the position of the notch 1410A of the first annular pixel isolation part 141A.

In this case, the notch of the first annular pixel isolation part can be used to set the first connection part, the first connection part is used to connect with the corresponding pixel driving circuit. In a case that the pixel density of the display substrate is high, and the sub-pixels are arranged closely, space between opposite edges of the effective light-emitting areas of adjacent sub-pixels is smaller, while space between opposite corners of the effective light-emitting areas of adjacent sub-pixels is larger, by arranging the notch of the first annular pixel isolation part on the diagonal extension of the effective light-emitting area of the first color sub-pixel, the display substrate can fully utilize the space between opposite corners of the effective light-emitting areas of adjacent sub-pixels. On the other hand, the display substrate can increase the density of pixel arrangement while avoiding crosstalk among adjacent sub-pixels through the above arrangement.

In some examples, as illustrated by FIGS. 53 and 54, the first connection portion 1311B is located on the diagonal extension of the first body portion 1311A, that is, the first connection portion 1311B protrudes outward from a corner portion of the first main body portion 1311A.

In some examples, as illustrated by FIG. 53, the first notches 1410A are arranged in an array, forming a first notch row and a first notch column along the first direction X and the second direction Y; the first notch row extends along the first direction, and the first notch column extends along the second direction; the second notches 1420A are arranged in an array, forming a second gap row and a second gap column along the first direction X and the second direction Y; the first notch row extends along the first direction X, and the first notch column extends along the second direction Y; the first notch row and the second notch row are generally parallel, and the first notch column and the second notch column are generally parallel.

In some examples, as illustrated by FIGS. 53 and 54, a shape of an orthographic projection of a first main body portion 1311A on the base substrate 110 includes a rounded rectangle, the first connection portion 1311B protrudes outward from a rounded corner of the first main body portion 1311A along a diagonal extension direction of the rounded rectangle.

In some examples, as illustrated by FIGS. 53 and 54, the second annular pixel isolation 142A includes a notch 1420A, the notch 1420A is located on a diagonal extension of the effective light emitting region of the third color sub-pixel 203. A first electrode 131 of the third color sub-pixel 203 includes a second main body part 1312A and a second connection part 1312B, the second connection part 1312B is connected with the second main body part 1312A, and is configured to be connected with the pixel driving circuit 250; the first connection part 1312B is located at the position of the notch 1420A of the first annular pixel isolation part 142A.

In this case, the notch of the second annular pixel isolation part can be used to arrange the second connection portion, and the second connection part is used to connect with the corresponding pixel driving circuit. In a case that the pixel density of the display substrate is high, and the sub-pixels are arranged closely, space between opposite edges of the effective light-emitting areas of adjacent sub-pixels is smaller, while space between opposite corners of the effective light-emitting areas of the adjacent sub-pixels is larger, by arranging the notch of the second ring-shaped pixel isolation part on the diagonal extension of the effective light-emitting region of the third color sub-pixel, the display substrate can fully utilize the space between opposite corners of the effective light-emitting areas of adjacent sub-pixels. On the other hand, the display substrate can increase the density of pixel arrangement while avoiding crosstalk among adjacent sub-pixels through the above arrangement.

In some examples, as illustrated by FIGS. 53 and 54, the second connection portion 1312B is located on the diagonal extension of the second main body portion 1312A, that is, the second connection portion 1312B protrudes outward from a corner portion of the second main body portion 1312A.

In some examples, as illustrated by FIGS. 53 and 54, the shape of the orthographic projection of the second main body portion 1312A on the base substrate 110 includes a rounded rectangle, the second connection portion 1312B protrudes outward from a rounded corner of the second main body portion 1312A along the diagonal extension direction of the rounded rectangle.

In some examples, as illustrated by FIGS. 53 and 54, a direction in which the first connection portion 1311B protrudes from the first main body portion 1311A is the same as a direction in which the second connection portion 1312B protrudes from the second main body portion 1312A.

In some examples, as illustrated by FIGS. 53 and 54, the first electrode 131 of the second color sub-pixel 202 includes a third main body part 1313A and a third connection part 1313B, the third connection part 1313B is connected with the third main body part 1313A, and is configured to be connected with the pixel driving circuit 250.

In some examples, as illustrated by FIGS. 53 and 54, the third connection portion 1313B is located on the diagonal extension of the third main body portion 1313A, that is, the third connection portion 1313B protrudes outward from a corner portion of the third main body portion 1313A.

In some examples, as illustrated by FIGS. 53 and 54, the display substrate 100 further includes a pixel defining layer 150 located on the base substrate 110; the pixel defining layer 150 is partially located on a side of the first electrodes 131 away from the base substrate 110; the pixel defining layer 150 includes a plurality of pixel openings 152 and a pixel spacing opening 154; the plurality of pixel openings 152 correspond to the plurality of sub-pixels 200 one-to-one to define the effective light-emitting areas of the plurality of sub-pixels 200; the plurality of pixel openings 152 is configured to expose the first electrodes 131, so that the first electrodes 131 are in contact with the subsequently formed light-emitting functional layer 120. The pixel spacing opening 154 is located between adjacent first electrodes 131, at least a part of the isolation structure 140 is located between the pixel defining layer 150 and the base substrate 110, that is, at least a part of the isolation structure 140 is covered by the pixel defining layer 150.

In an arrangement direction of adjacent sub-pixels, because at least a part of the isolation structure is located between the pixel defining layer and the base substrate, the charge generation layer in the light-emitting functional layer is only disconnected once at a position where the isolation structure is located outside the pixel defining layer; similarly, the second electrode is only disconnected once at the position where the isolation structure is located outside the pixel defining layer, instead of being disconnected twice on two sides of the isolation structure in the arrangement direction of adjacent sub-pixels. Therefore, the second electrode maintains better continuity, and thus the cathode quotes can be conveyed better. In addition, the second electrode is only disconnected once at a position where the isolation structure is located outside the pixel defining layer, the second electrode can also reduce or even avoid the formation of tip structures, thus the tip discharge phenomenon can be avoided. It should be noted that the arrangement direction of the adjacent sub-pixels may be the extending direction of the line connecting the brightness centers of the effective light-emitting areas of the adjacent sub-pixels.

In some examples, as illustrated by FIGS. 53 and 54, in the arrangement direction of the adjacent sub-pixels, one edge of the isolation structure 140 in the arrangement direction is located between the pixel defining layer 150 and the base substrate 110, while the other edge is located in the pixel spacing opening 154. At this time, the second electrode is only disconnected once at an edge of the isolation structure located in the pixel space opening, instead of being disconnected twice on two sides of the isolation structure in the arrangement direction of adjacent sub-pixels. Therefore, the second electrode maintains continuity better, and thus the cathode quotes can be conveyed better.

In some examples, as illustrated by FIGS. 53 and 54, in the arrangement direction of the adjacent sub-pixels, one side of the isolation structure 140 in the arrangement direction includes an isolation surface 149, an angle between the isolation surface 149 and a plane where the base substrate 110 is located ranges from 80 to 100 degrees. In this way, the isolation surface can effectively disconnect the charge generation layer. Of course, the isolation structure provided by the embodiment of the present disclosure can also adopt other structures, as long as the charge generation layer can be disconnected.

In some examples, as illustrated by FIGS. 53 and 54, a size of the isolation structure 140 in the direction perpendicular to the base substrate 110 ranges from 500 Å to 1500 Å. Of course, embodiments of the present disclosure include but are not limited thereto, the size of the isolation structure in the direction perpendicular to the base substrate can be set according to actual conditions.

For example, material of the pixel defining layer may include organic materials, such as polyimide, acrylic or polyethylene terephthalate, etc.

In some examples, as illustrated by FIG. 53, a plurality of first color sub-pixels 201 and a plurality of third color sub-pixels 203 are alternately arranged along both the first direction and the second direction to form a plurality of first pixel rows 310 and a plurality of first pixel columns 320, the plurality of second color sub-pixels 202 are arranged in an array along the first direction and the second direction to form a plurality of second pixel rows 330 and a plurality of second pixel columns 340, the plurality of first pixel rows 310 and the plurality of second pixel rows 330 are alternately arranged along the second direction and staggered from each other in the first direction, and the plurality of first pixel columns 320 and the plurality of second pixel columns 340 are alternately arranged along the first direction and are staggered from each other in the second direction. The isolation structure 140 is located between a first color sub-pixel 201 and a third color sub-pixel 203 that are adjacent, and/or, the isolation structure 140 is located between a second color sub-pixel 202 and a third color sub-pixel 203 that are adjacent, and/or, the isolation structure 140 is located between a first color sub-pixels 201 and a second color sub-pixels 202 that are adjacent.

In some examples, the light-emitting efficiency of the third color sub-pixel is less than the light-emitting efficiency of the second color sub-pixel.

For example, the first color sub-pixel 201 is configured to emit red light, the second color sub-pixel 202 is configured to emit green light, and the third color sub-pixel 203 is configured to emit blue light. Of course, embodiments of the present disclosure include but are not limited thereto.

In some examples, as illustrated by FIG. 53, an area of an orthogonal projection of the effective light-emitting region of the third color sub-pixel 203 on the base substrate 110 is larger than an area of an orthogonal projection of the effective light-emitting region of the first color sub-pixel 201 on the base substrate 110; the area of the orthogonal projection of the effective light-emitting region of the first color sub-pixel 201 on the base substrate 110 is larger than an area of an orthogonal projection of the effective light-emitting region of the second color sub-pixel 202 on the base substrate 110. Of course, embodiments of the present disclosure include but are not limited thereto, and the area of the effective light-emitting region of each of the sub-pixels can be set according to actual needs.

In some examples, as illustrated by FIGS. 53 and 54, the display substrate 100 further includes a planarization layer 180, a plurality of data lines 191 and a plurality of power lines 192; the planarization layer 180 is located on a side of the first electrodes 131 close to the base substrate 110, that is, the first electrodes 131 are arranged on a side of the planarization layer 180 away from the base substrate 110; the plurality of data lines 191 are located between the planarization layer 180 and the base substrate 110, the plurality of data lines 191 extend along the first direction and are arranged along the second direction, the first direction intersects the second direction; the plurality of power lines 192 are located between the planarization layer 180 and the base substrate 110, the plurality of power lines 192 extend along the first direction and are arranged along the second direction; along a direction perpendicular to the base substrate 110, the isolation structure 140 is overlapped with at least one of the data lines 191 and the power lines 192.

In some examples, as illustrated by FIG. 53, a plurality of data lines 191 and a plurality of power lines 192 are arranged alternately.

FIG. 55A is a partial cross-sectional schematic diagram of another display substrate provided by an embodiment of the present disclosure. As illustrated by FIG. 55A, the display substrate 100 also includes a planarization layer 180 and a protection structure 270; the planarization layer 180 is located between the base substrate 110 and a first electrode 131; and the protection structure 270 is located between the planarization layer 180 and the first electrode 131.

In the manufacturing process of the display substrate, the isolation structure is formed after the planarization layer is formed, and an etching process is required; although the etching process is selective, the etching process will still adversely affect the planarizationness of the planarization layer. so that the first electrode formed on the planarization layer have poor planarizationness, thereby affecting the display effect. The display substrate shown in FIG. 55A forms a protection structure between the planarization layer and the first electrode, and protects the planarization layer under the first electrode during the etching process of the isolation structure, to avoid being etched, thus planarizationness of the planarization layer under the first electrode can be ensured, furthermore, planarizationness of the first electrode can be ensured, and the display quality can be improved.

In some examples, as illustrated by FIG. 55A, the protection structure 270 and the isolation structure 140 are arranged on a same layer, therefore, while the protection structure 270 is formed, the protection structure 270 can protect the planarization layer under the first electrode, to avoid being etched. In addition, the protection structure does not need to add additional film layers or mask processes, thus costs can also be reduced.

In some examples, the protection structure and the isolation structure are made of a same material and formed through a same patterning process.

In some examples, as illustrated by FIG. 55A, an orthographic projection of the first electrode 131 on the base substrate 110 falls within an orthographic projection of the protection structure 270 on the base substrate 110. In this way, the protection structure 270 can fully protect the planarization layer under the first electrode, thus the planarizationness of the entire first electrode is ensured.

FIG. 55B is a cross-sectional electron microscope diagram of a display substrate provided by an embodiment of the present disclosure. As illustrated by FIG. 55B, in an arrangement direction of adjacent sub-pixels 200, one edge of the isolation structure 140 in the arrangement direction is located between the pixel defining layer 150 and the base substrate 110, while the other edge is located in the pixel spacing opening. At this time, one edge of the isolation structure can function as an isolation, while the other edge is covered by the pixel defining layer. The second electrode is also only disconnected once at an edge of the isolation structure located in the pixel spacing opening, rather than being disconnected twice on two sides of the isolation structure in the arrangement direction of adjacent sub-pixels. Therefore, the second electrode maintains continuity better, and thus the cathode signal can be better transmitted.

At least one embodiment of the present disclosure also provides a display device. FIG. 56 is a schematic diagram of a display device provided by an embodiment of the present disclosure. As illustrated by FIG. 56, the display device 500 further includes a display substrate 100. The display substrate sets an isolation structure between adjacent sub-pixels, so that the charge generation layer in the light-emitting functional layer is disconnected at the location of the isolation structure, therefore, crosstalk among adjacent sub-pixels caused by the charge generation layer with higher conductivity is avoided. In this way, the display device including the display substrate can also avoid crosstalk among adjacent sub-pixels, and therefore has higher product yield and higher display quality.

On the other hand, the display substrate can increase the pixel density while adopting a dual-layer light emitting (Tandem EL) design, the display device including the display substrate has the advantages of long life, low power consumption, high brightness, high resolution, etc.

For example, the display device may be a display device such as an organic light-emitting diode display device, and as well as any product or component with a display function such as a television, a digital camera, a mobile phone, a watch, a tablet computer, a notebook computer, and a navigator that include the display device, and the embodiments are not limited thereto.

It is to be noted that:
(1) In the drawings of the embodiments of the present disclosure, only the structures related to the embodiments of the present disclosure are involved, and other structures may refer to the common design(s).
(2) In case of no conflict, features in one embodiment or in different embodiments of the present disclosure can be combined.

The above is only the specific embodiment of this disclosure, but the protection scope of this disclosure is not limited thereto. Any person familiar with the technical field can easily think of changes or substitutions within the technical scope disclosed in this disclosure, and they should be included in the protection scope of this disclosure. Therefore, the scope of protection of this disclosure should be based on the scope of protection of the claims.

1: A display substrate, comprising:
a base substrate;
a plurality of sub-pixels, located on the base substrate, wherein each of the plurality of sub-pixels comprises a light-emitting element, the light-emitting element comprises a light-emitting functional layer, a first electrode and a second electrode located on two sides of the light-emitting functional layer respectively, the first electrode is located between the light-emitting functional layer and the base substrate, and the light-emitting functional layer comprises a plurality of sub-functional film layers; and
a pixel isolation structure, located between adjacent sub-pixels of the plurality of sub-pixels, at least one of the plurality of sub-functional film layers in the light-emitting functional layer is disconnected at a position where the pixel isolation structure is located,
wherein the pixel isolation structure comprises a first sub-pixel isolation part, a second sub-pixel isolation part and a third sub-pixel isolation part that are stacked in a direction perpendicular to the base substrate, the second sub-pixel isolation part is located on a side of the first sub-pixel isolation part away from the base substrate, and the third sub-pixel isolation part is located on a side of the second sub-pixel isolation part away from the first sub-pixel isolation part, and
the second sub-pixel isolation part comprises a plurality of sub-isolation layers stacked in the direction perpendicular to the base substrate, the first sub-pixel isolation part has a first protruding part beyond at least one of the plurality of sub-isolation layers in an arrangement direction of two adjacent sub-pixels of the plurality of sub-pixels, and the third sub-pixel isolation part has a second protruding part beyond at least one of the plurality of sub-isolation layers in the arrangement direction of the two adjacent sub-pixels.

2: The display substrate according to claim 1, wherein an orthographic projection of at least one of the plurality of sub-isolation layers on the base substrate respectively falls within an orthographic projection of the first sub-pixel isolation part and an orthographic projection of the third sub-pixel isolation part on the base substrate.

3: The display substrate according to claim 2, wherein an orthographic projection of the second sub-pixel isolation part on the base substrate respectively falls within the orthographic projection of the first sub-pixel isolation part and the orthographic projection of the third sub-pixel isolation part on the base substrate.

4: The display substrate according to claim 2, wherein the plurality of sub-isolation layers of the second sub-pixel isolation part comprise a first sub-isolation layer, a second sub-isolation layer and a third sub-isolation layer that are stacked in the direction perpendicular to the base substrate, and an orthographic projection of the second sub-isolation layer on the base substrate respectively falls within an orthographic projection of the first sub-isolation layer and an orthographic projection of the third sub-isolation layer on the base substrate.

5: The display substrate according to claim 1, wherein the plurality of sub-functional layers comprise a charge generation layer and a first light emitting layer and a second light emitting layer located on two sides of the charge generation layer respectively, the charge generation layer is disconnected at the position where the pixel isolation structure is located.

6. (canceled)

7: The display substrate according to claim 1, wherein a material of the third sub-pixel isolation part comprises a first metal, and a material of the second sub-pixel isolation part comprises a second metal.

8. (canceled)

9: The display substrate according to claim 1, wherein materials of the first sub-pixel isolation part and the third sub-pixel isolation part comprise a first inorganic non-metal material, and a material of the second sub-pixel isolation part comprises a second inorganic non-metal material.

10-11. (canceled)

12: The display substrate according to claim 1, further comprising:
a pixel defining layer, located on the base substrate,
wherein the pixel defining layer is partially located on a side of the first electrode away from the base substrate, the pixel defining layer comprises a plurality of pixel openings, the plurality of pixel openings are in one-to-one correspondence with the plurality of sub-pixels to define light-emitting areas of the plurality of sub-pixels, and each of the plurality of pixel openings is configured to expose the first electrode, and
the pixel isolation structure is located between adjacent pixel openings of the plurality of pixel openings, and is located on a side of the pixel defining layer away from the base substrate.

13: The display substrate according to claim 1, further comprising:
a pixel defining layer, located on the base substrate,
wherein the pixel defining layer is partially located on a side of the first electrode away from the base substrate, the pixel defining layer comprises a plurality of pixel openings and a pixel spacing opening, the plurality of pixel openings are in one-to-one correspondence with the plurality of sub-pixels to define light-emitting areas of the plurality of sub-pixels, and each of the plurality of pixel openings is configured to expose the first electrode,
the pixel spacing opening is located between adjacent first electrodes, and the pixel isolation structure is at least partially located in the pixel spacing opening.

14: The display substrate according to claim 13, further comprising:
a planarization layer, located between the base substrate and the first electrode,
wherein the pixel isolation structure is in direct contact with the planarization layer.

15: The display substrate according to claim 13, further comprising:
a planarization layer, located between the base substrate and the first electrode; and
a protection structure, located on the planarization layer and arranged in a same layer as the first electrode,
wherein the pixel isolation structure is located on a side of the protection structure away from the base substrate, and is in direct contact with the protection structure.

16: The display substrate according to claim 1, further comprising:
a pixel defining layer, located on the base substrate,
wherein the pixel defining layer is partially located on a side of the first electrode away from the base substrate, the pixel defining layer comprises a plurality of pixel openings, the plurality of pixel openings are in one-to-one correspondence with the plurality of sub-pixels to define light-emitting areas of the plurality of sub-pixels, each of the plurality of pixel openings is configured to expose the first electrode, and
at least a part of the pixel isolation structure is located in the plurality of pixel openings.

17: The display substrate according to claim 16, wherein the pixel isolation structure is located at an edge of the first electrode, a surface of the pixel isolation structure away from the base substrate is at least partially covered by a material of the first electrode, an orthographic projection of the pixel isolation structure on the base substrate is at least partially overlapped with an orthographic projection of the pixel defining layer on the base substrate.

18: The display substrate according to claim 1, wherein the base substrate comprises a display region and a peripheral region surrounding the display region, the display region comprises an opening region, and an opening isolation structure is arranged at an edge of the opening region, a cross-sectional structure of the opening isolation structure in the direction perpendicular to the base substrate is the same as a cross-sectional structure of the pixel isolation structure, and a material of the opening isolation structure is the same as a material of the pixel isolation structure.

19: The display substrate according to claim 1, wherein the second electrode is disconnected at a position where the pixel isolation structure is located.

20: A display device, comprising the display substrate according to claim 1.

21: A manufacturing method of a display substrate, comprising:
forming a plurality of first electrodes on the base substrate;
forming a pixel isolation structure on the base substrate;
forming a light-emitting functional layer on a side of the pixel isolation structure and the plurality of first electrodes away from the base substrate, the light-emitting functional layer comprises a plurality of sub-functional layers; and
forming a second electrode on a side of the light-emitting functional layer away from the base substrate, the second electrode, the light-emitting functional layer and the plurality of first electrodes form light-emitting elements of a plurality of sub-pixels,
wherein the pixel isolation structure is located between adjacent sub-pixels of the plurality of sub-pixels, the pixel isolation structure comprises a first sub-pixel isolation part, a second sub-pixel isolation part and a third sub-pixel isolation part that are stacked, the second sub-pixel isolation part is located on a side of the first sub-pixel isolation part away from the base substrate, the third sub-pixel isolation part is located on a side of the second sub-pixel isolation part away from the first sub-pixel isolation part, and
the second sub-pixel isolation part comprises a plurality of sub-isolation layers stacked in a direction perpendicular to the base substrate, the first sub-pixel isolation part has a first protruding part beyond at least one of the plurality of sub-isolation layers in an arrangement direction of two adjacent sub-pixels of the plurality of sub-pixels, and the third sub-pixel isolation part has a second protruding part beyond at least one of the plurality of sub-isolation layers in the arrangement direction of the two adjacent sub-pixels.

22-24. (canceled)

25: The manufacturing method of the display substrate according to claim 21, wherein the forming an isolation structure on the base substrate comprises:
forming a stacked structure on the base substrate before forming the plurality of first electrodes on the base substrate, the stacked structure comprises a first sub-layer, a second sub-layer and a third sub-layer that are stacked; and
etching the stacked structure to remove a part of the second sub-layer, so that the stacked structure forms the pixel isolation structure, the first sub-layer forms a first sub-pixel isolation part, the second sub-layer forms a second sub-pixel isolation part, and the third sub-layer forms a third sub-pixel isolation part.

26: The manufacturing method of the display substrate according to claim 21, further comprising:
before forming the plurality of first electrodes on the base substrate, forming a stacked structure on the base substrate, wherein the stacked structure comprises a first sub-layer, a second sub-layer and a third sub-layer that are stacked;
after forming the plurality of first electrodes on the base substrate, forming a pixel defining layer on a side of the stacked structure and the plurality of first electrodes away from the base substrate;
patterning the pixel defining layer to form a plurality of pixel openings and a pixel spacing opening on the pixel defining layer; and
etching the stacked structure to remove a part of the second sub-layer, so that the stacked structure forms the pixel isolation structure, the first sub-layer forms a first sub-pixel isolation part, the second sub-layer forms a second sub-pixel isolation part, and the third sub-layer forms a third sub-pixel isolation part,
wherein the plurality of pixel openings are arranged corresponding to the plurality of first electrodes, and are configured to expose the plurality of first electrodes, the pixel spacing opening is located between adjacent first electrodes, and at least a part of the stacked structure is located in the pixel spacing opening.

27: The manufacturing method of the display substrate according to claim 21, further comprising:
before forming the plurality of first electrodes on the base substrate, forming a stacked structure on the base substrate, the stacked structure comprises a first sub-layer, a second sub-layer and a third sub-layer that are stacked;
etching the stacked structure to remove a part of the second sub-layer, so that the stacked structure forms the pixel isolation structure, the first sub-layer forms a first sub-pixel isolation part, the second sub-layer forms a second sub-pixel isolation part, and the third sub-layer forms a third sub-pixel isolation part;
after forming the plurality of first electrodes on the base substrate, forming a pixel defining layer on a side of the stacked structure and the first electrodes away from the base substrate; and
patterning the pixel defining layer to form a plurality of pixel openings on the pixel defining layer,
wherein the plurality of pixel openings are arranged corresponding to the plurality of first electrodes, and are configured to expose the plurality of first electrodes, and the pixel isolation structure is at least partially located in the plurality of pixel openings.
